(19) United States
(12) Patent Application Publication
(10) Pub. No.: US 2022/0109119 A1
(43) Pub. Date: Apr. 7, 2022

(54) Light-Emitting Device, Energy Donor Material, Light-Emitting Apparatus, Display Device, Lighting Device, and Electronic Device

(71) Applicant: Semiconductor Energy Laboratory Co., Ltd., Kanagawa-ken (JP)

(72) Inventors: Nobuharu Ohsawa, Zama (JP); Satoshi Seo, Sagamihara (JP); Yui Yoshiyasu, Atsugi (JP); Hideko Yoshizumi, Atsugi (JP)

(73) Assignee: Semiconductor Energy Laboratory Co., Ltd., Kanagawa-ken (JP)

(21) Appl. No.: 17/485,802

(22) Filed: Sep. 27, 2021

(30) Foreign Application Priority Data
Oct. 2, 2020 (JP) 2020-167444

(51) Int. Cl. H01L 51/00; C07F 15/00; C09K 11/06

(52) U.S. Cl. CPC H01L 51/0085; H01L 51/5016; C09K 11/06; C07F 15/0033

(57) ABSTRACT

A novel light-emitting device is provided. The light-emitting device includes a first electrode, a second electrode, and a light-emitting layer between the first electrode and the second electrode. The light-emitting layer includes an organometallic complex emitting phosphorescence at room temperature and a light-emitting material emitting fluorescence. The organometallic complex includes a ligand with at least one first substituent selected from a branched alkyl group having 3 to 12 carbon atoms, a substituted or unsubstituted cycloalkyl group having 3 to 10 carbon atoms in a ring, and a trialkylsilyl group having 3 to 12 carbon atoms. An absorption spectrum of the light-emitting material has the longest-wavelength edge at a first wavelength λabs (nm), and a phosphorescence spectrum of the organometallic complex has the shortest-wavelength edge at a second wavelength λp (nm). The first wavelength λabs (nm) is longer than the second wavelength λp (nm).

### BACKGROUND OF THE INVENTION

### 1. Field of the Invention

One embodiment of the present invention relates to a light-emitting device an energy donor material, a light-emitting apparatus, a display device, a lighting device, an electronic device, and a semiconductor device.

Note that one embodiment of the present invention is not limited to the above technical field. The technical field of one embodiment of the invention disclosed in this specification and the like relates to an object, a method, or a manufacturing method. One embodiment of the present invention relates to a process, a machine, manufacture, or a composition of matter. Specific examples of the technical field of one embodiment of the present invention disclosed in this specification include a semiconductor device, a display device, a liquid crystal display device, a light-emitting apparatus, a lighting apparatus, a power storage device, a memory device, a method of driving any of them, and a method of manufacturing any of them.

### 2. Description of the Related Art

In recent years, light-emitting devices using electroluminescence (EL) have been actively researched and developed. In the basic structure of such a light-emitting device, a layer containing a light-emitting substance (an EL layer) is provided between a pair of electrodes. Voltage application between the electrodes of a light-emitting device can cause light emission from the light-emitting substance.

Since the above light-emitting device is a self-luminous device, a display device using this light-emitting device has advantages such as high visibility, no necessity of a backlight, and low power consumption. Furthermore, such a light-emitting device also has advantages in that the device can be formed to be thin and lightweight and has high response speed, for example.

In a light-emitting device where an EL layer containing an organic compound as the light-emitting substance is provided between a pair of electrodes (e.g., an organic EL device), by voltage application between the pair of electrodes, electrons from a cathode and holes from an anode are injected into the EL layer having a light-emitting property; thus, current flows. By recombination of the injected electrons and holes, the light-emitting organic compound can be brought into an excited state to provide light emission.

Excited states that can be formed by an organic compound are a singlet excited state (S*) and a triplet excited state (T*). Light emission from the singlet excited state is referred to as fluorescence, and light emission from the triplet excited state is referred to as phosphorescence. The statistical generation ratio of S* to T* in a light-emitting device is 1:3. Thus, a light-emitting device including a compound that emits phosphorescence (a phosphorescent material) has higher luminous efficiency than a light-emitting device including a compound that emits fluorescence (a fluorescent material). Therefore, light-emitting devices including phosphorescent materials capable of converting triplet excitation energy into luminescence have been actively developed in recent years.

Among light-emitting devices including phosphorescent materials, a light-emitting device that emits blue light in particular has not yet been put into practical use because it is difficult to develop a stable compound having a high triplet excitation energy level. For this reason, the development of a light-emitting device including a more stable fluorescent material has been conducted and a technique for increasing the luminous efficiency of a light-emitting device including a fluorescent material (a fluorescent light-emitting device) has been searched.

As a material capable of partly or entirely converting triplet excitation energy into luminescence, a thermally activated delayed fluorescent (TADF) material is known in addition to a phosphorescent compound. In a thermally activated delayed fluorescent material, a singlet excited state is generated from a triplet excited state by reverse intersystem crossing, and the singlet excitation energy is converted into light emission.

In order to increase the luminous efficiency of a light-emitting device using a thermally activated delayed fluorescent material, not only efficient generation of a singlet excited state from a triplet excited state but also efficient light emission from a singlet excited state, that is, high fluorescence quantum yield is important in a thermally activated delayed fluorescent material. It is, however, difficult to design a light-emitting material that meets these two.

A method in which in a light-emitting device containing a thermally activated delayed fluorescent material and a fluorescent material, singlet excitation energy of the thermally activated delayed fluorescent material is transferred to the fluorescent material and light emission is obtained from the fluorescent material has been proposed (see Patent Document 1).

A light-emitting device in which a light-emitting layer includes a host material and a guest material is known (see Patent Document 2). The host material has a function of converting triplet excitation energy into luminescence, and the guest material emits fluorescence. The molecular structure of the guest material includes a luminophore and protecting groups, where one molecule includes five or more protecting groups. The protecting groups included in the molecule can prevent the transfer of triplet excitation energy from the host material to the guest material by the Dexter mechanism. As the protecting groups, alkyl groups or branched-chain alkyl groups can be used.

### REFERENCES

[Patent Document 1] Japanese Published Patent Application No. 2014-045179
[Patent Document 1] PCT International Publication No. 2019/171197

### SUMMARY OF THE INVENTION

As described above, the efficiency of a fluorescent light-emitting device is increased as follows, for example: triplet excitons of the host material are converted into singlet excitons, and then, singlet excitation energy is transferred to a fluorescent material used as the guest material. However, in the light-emitting layer of the light-emitting device where a fluorescent material is used as the guest material, the lowest triplet excitation energy level (T₁ level) of the fluorescent material does not contribute to light emission and might be a deactivation pathway of the triplet excitation energy. Thus, the efficiency of fluorescent light-emitting devices has been difficult to increase. When the concentration of the guest material is reduced, the deactivation pathway can be prevented to a certain extent and at the same time the energy transfer from the host material to the singlet excited state of the guest material slows down. This is likely to cause quenching due to a degraded material and an impurity, leading to lower reliability.

In order to increase the luminous efficiency and reliability of a fluorescent light-emitting device, it is preferred that triplet excitation energy in the light-emitting layer be efficiently converted into singlet excitation energy and be efficiently transferred as singlet excitation energy to a fluorescent material. Hence, it is required to develop a method for generating a singlet excited state of a guest material from a triplet excited state of a host material to further increase the luminous efficiency and reliability of the light-emitting device.

An object of one embodiment of the present invention is to provide a novel light-emitting device that is highly convenient, useful, or reliable. Another object is to provide a novel energy donor material that is highly convenient, useful, or reliable. Another object is to provide a novel light-emitting apparatus that is highly convenient, useful, or reliable. Another object is to provide a novel display device that is highly convenient, useful, or reliable. Another object is to provide a novel lighting device that is highly convenient, useful, or reliable. Another object is to provide a novel electronic device that is highly convenient, useful, or reliable. Another object is to provide a novel light-emitting device, a novel energy donor material, a novel light-emitting apparatus, a novel display device, a novel lighting device, or a novel electronic device.

Note that the description of these objects does not preclude the existence of other objects. In one embodiment of the present invention, there is no need to achieve all these objects. Other objects will be apparent from and can be derived from the description of the specification, the drawings, the claims, and the like.

(1) One embodiment of the present invention is a light-emitting device including a first electrode, a second electrode, and a light-emitting layer positioned between the first electrode and the second electrode.

The light-emitting layer includes an organometallic complex having a function of emitting phosphorescence at room temperature and a light-emitting material having a function of emitting fluorescence.

The organometallic complex includes a ligand with at least one first substituent R¹ selected from a branched alkyl group having 3 to 12 carbon atoms, a substituted or unsubstituted cycloalkyl group having 3 to 10 carbon atoms in a ring, and a trialkylsilyl group having 3 to 12 carbon atoms.

An absorption spectrum of the light-emitting material has the longest-wavelength edge at a first wavelength λabs (nm). A phosphorescence spectrum of the organometallic complex has the shortest-wavelength edge at a second wavelength λp (nm). The first wavelength λabs (nm) is longer than the second wavelength λp (nm).

(2) Another embodiment of the present invention is the above light-emitting device in which the organometallic complex includes a transition metal, and the ligand includes a first ring that is a six-membered ring including an atom covalently bonded to the transition metal as a constituent atom and a second ring that is a five-membered ring or a six-membered ring including an atom coordinated to the transition metal as a constituent atom.

The at least one first substituent R¹ is bonded to at least one of the first ring and the second ring.

(3) Another embodiment of the present invention is the above light-emitting device in which the ligand is a phenylpyridine skeleton and the first substituent R¹ is bonded to carbon of the phenylpyridine skeleton.

(4) Another embodiment of the present invention is the above light-emitting device in which the organometallic complex does not include an n-alkyl group having two or more carbon atoms.

(5) Another embodiment of the present invention is the above light-emitting device in which a relationship between the first wavelength λabs (nm) and the second wavelength λp (nm) is represented by Formula (1).

$$\begin{matrix}[ Formula 1 ] & \\ 0.05 < 1240 \times ( \frac{1}{{λ}_{p}} - \frac{1}{{λ}_{abs}} ) \leq 0.30 & ( 1 )\end{matrix}$$

(6) Another embodiment of the present invention is the above light-emitting device in which a fluorescence spectrum of the light-emitting material includes the shortest-wavelength edge at a third wavelength λf (nm), and a relationship between the third wavelength λf (nm) and the second wavelength λp (nm) is represented by Formula (2).

$$\begin{matrix}[ Formula 2 ] & \\ 0 \leq 1240 \times ( \frac{1}{{λ}_{p}} - \frac{1}{{λ}_{f}} ) \leq 0.1 & ( 2 )\end{matrix}$$

Thus, the organometallic complex can be used as the energy donor material to allow the transfer of the energy, particularly triplet excited energy, of the energy donor material to the light-emitting material. The first substituent R¹ is interposed between the energy donor material and the light-emitting material that are close to each other. The energy transfer by the Dexter mechanism can be inhibited. The energy transfer by the Förster mechanism can be dominant. The light-emitting material can be brought into a singlet excited state. The probability of generating the singlet excited state of the light-emitting material can be increased. Alternatively, emission efficiency can be increased. As a result, a novel light-emitting device that is highly convenient, useful, or reliable can be provided.

(7) Another embodiment of the present invention is a light-emitting device including a first electrode, a second electrode, and a light-emitting layer positioned between the first electrode and the second electrode

The light-emitting layer includes an organometallic complex having a function of emitting phosphorescence at room temperature and a light-emitting material having a function of emitting fluorescence.

The organometallic complex includes a ligand with at least one first substituent R¹ selected from a branched alkyl group having 3 to 12 carbon atoms, a substituted or unsubstituted cycloalkyl group having 3 to 10 carbon atoms in a ring, and a trialkylsilyl group having 3 to 12 carbon atoms. The organometallic complex does not include an n-alkyl group having two or more carbon atoms.

The light-emitting material includes a ligand with at least one second substituent R² selected from a methyl group, a branched alkyl group having 3 to 12 carbon atoms, a substituted or unsubstituted cycloalkyl group having 3 to 10 carbon atoms in a ring, and a trialkylsilyl group having 3 to 12 carbon atoms.

The phosphorescent spectrum of the organometallic complex overlaps with the absorption spectrum of the light-emitting material.

(8) Another embodiment of the present invention is the above light-emitting device in which the organometallic complex includes a transition metal, the ligand includes a first ring that is a six-membered ring including an atom covalently bonded to the transition metal as a constituent atom and a second ring that is a five-membered ring or a six-membered ring including an atom coordinated to the transition metal as a constituent atom, and the at least one first substituent R¹ is bonded to at least one of the first ring and the second ring.

(9) Another embodiment of the present invention is the above light-emitting device in which the light-emitting material includes a condensed aromatic ring or a condensed heteroaromatic ring including 3 to 10 rings and the five or more second substituents R².

At least five second substituents R² of the five or more second substituents R² each independently include any of a branched alkyl group having 3 to 12 carbon atoms, a substituted or unsubstituted cycloalkyl group having 3 to 10 carbon atoms in a ring, and a trialkylsilyl group having 3 to 12 carbon atoms.

(10) Another embodiment of the present invention is the above light-emitting device in which the light-emitting material includes a condensed aromatic ring or a condensed heteroaromatic ring including 3 to 10 rings and the three or more second substituents R².

At least three second substituents R² of the three or more second substituents R² are not directly bonded to the condensed aromatic ring or the condensed heteroaromatic ring and each independently include any of a branched alkyl group having 3 to 12 carbon atoms, a substituted or unsubstituted cycloalkyl group having 3 to 10 carbon atoms in a ring, and a trialkylsilyl group having 3 to 12 carbon atoms.

(11) Another embodiment of the present invention is the above light-emitting device in which the light-emitting material includes a condensed aromatic ring or a condensed heteroaromatic ring including 3 to 10 rings and a diarylamino group.

The condensed aromatic ring or condensed heteroaromatic ring including 3 to 10 rings is bonded to a nitrogen atom of the diarylamino group. The second substituent R² is bonded to an aryl group of the diarylamino group.

(12) Another embodiment of the present invention is the above light-emitting device in which the branched alkyl group of the second substituent R² is a secondary or tertiary alkyl group.

(13) Another embodiment of the present invention is the above light-emitting device in which the branched alkyl group of the second substituent R² includes 3 or 4 carbon atoms.

(14) Another embodiment of the present invention is the above light-emitting device in which the cycloalkyl group of the second substituent R² includes 3 to 6 carbon atoms.

(15) Another embodiment of the present invention is the above light-emitting device in which the trialkylsilyl group in the second substituent R² is a trimethylsilyl group.

(16) Another embodiment of the present invention is the above light-emitting device in which the second substituent R² includes deuterium.

(17) Another embodiment of the present invention is the above light-emitting device in which the organometallic complex includes two or three ligands as the ligand. Note that the ligands may be the same or different from each other.

(18) Another embodiment of the present invention is the above light-emitting device in which the branched alkyl group of the first substituent R¹ is a secondary or tertiary alkyl group.

(19) Another embodiment of the present invention is the above light-emitting device in which the branched alkyl group of the first substituent R¹ includes 3 or 4 carbon atoms.

(20) Another embodiment of the present invention is the above light-emitting device in which the cycloalkyl group of the first substituent R¹ includes 3 to 6 carbon atoms.

(21) Another embodiment of the present invention is the above light-emitting device in which the trialkylsilyl group in the first substituent R¹ is a trimethylsilyl group.

(22) Another embodiment of the present invention is the above light-emitting device in which the first substituent R¹ includes deuterium.

(23) Another embodiment of the present invention is the above light-emitting device in which the ligand further includes a methyl group.

(24) Another embodiment of the present invention is the above light-emitting device in which the methyl group includes deuterium.

(25) Another embodiment of the present invention is the above light-emitting device in which the light-emitting layer further includes a host material and the light-emitting material is a guest material.

Thus, the organometallic complex can be used as the energy donor material to allow the transfer of the energy, particularly triplet excited energy, of the energy donor material to the light-emitting material. The first substituent R¹ and the second substituent R² are interposed between the energy donor material and the light-emitting material that are close to each other. The energy transfer by the Dexter mechanism can be inhibited. The energy transfer by the Förster mechanism can be dominant. The light-emitting material can be brought into a singlet excited state. The probability of generating the singlet excited state of the light-emitting material can be increased. Alternatively, emission efficiency can be increased. The concentration of the light-emitting material can be increased. As a result, a novel light-emitting device that is highly convenient, useful, or reliable can be provided.

(26) Another embodiment of the present invention is an energy donor material represented by General Formula (G0) below.

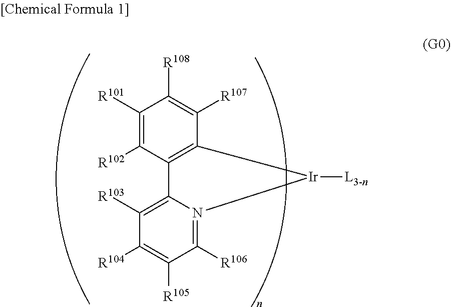

Note that in the general formula, L is a ligand; n is an integer greater than or equal to 1 and less than or equal to 3; R¹⁰¹ to R¹⁰⁸ are each independently hydrogen or a substituent; and R¹⁰¹ to R¹⁰⁸ each independently include any one or more of a secondary or tertiary alkyl group having 3 to 12 carbon atoms, a cycloalkyl group having 3 to 10 carbon atoms and a trialkylsilyl group having 3 to 12 carbon atoms.

Accordingly, the light emission efficiency can be increased. As a result, a novel light-emitting device that is highly convenient, useful, or reliable can be provided.

(27) Another embodiment of the present invention is a light-emitting apparatus including the above light-emitting device and a transistor or a substrate.

(28) Another embodiment of the present invention is a display device including the above light-emitting device and a transistor or a substrate.

(29) Another embodiment of the present invention is a lighting device including the light-emitting apparatus and a housing.

(30) Another embodiment of the present invention is an electronic device including the display device and at least one of a sensor, an operation button, a speaker, and a microphone.

According to one embodiment of the present invention, a novel light-emitting device that is highly convenient, useful, or reliable can be provided. A novel energy donor material that is highly convenient, useful, or reliable can be provided. A novel light-emitting apparatus that is highly convenient, useful, or reliable can be provided. A novel display device that is highly convenient, useful, or reliable can be provided. A novel lighting device that is highly convenient, useful, or reliable can be provided. A novel electronic device that is highly convenient, useful, or reliable can be provided. A novel light-emitting device, a novel display device, a novel light-emitting apparatus, a novel lighting device, or a novel electronic device can be provided.

Note that the description of these effects does not preclude the existence of other effects. One embodiment of the present invention does not necessarily have all the effects listed above. Other effects will be apparent from and can be derived from the description of the specification, the drawings, the claims, and the like.

### BRIEF DESCRIPTION OF THE DRAWINGS

FIGS. 1A to 1C illustrate a structure of a light-emitting device according to Embodiments 1 to 4.

FIGS. 2A and 2B each illustrate a structure of a light-emitting device according to Embodiments 5 and 6.

FIG. 3 illustrates a structure of a light-emitting panel of Embodiment 7.

FIGS. 4A and 4B are conceptual diagrams of an active matrix light-emitting apparatus.

FIGS. 5A and 5B are conceptual diagrams of an active matrix light-emitting apparatus.

FIG. 6 is a conceptual diagram of an active matrix light-emitting apparatus.

FIGS. 7A and 7B are conceptual diagrams of a passive matrix light-emitting apparatus.

FIGS. 8A and 8B illustrate a lighting device.

FIGS. 9A to 9D illustrate electronic devices.

FIGS. 10A to 10C each illustrate an electronic device.

FIG. 11 illustrates a lighting device.

FIG. 12 illustrates a lighting device.

FIG. 13 illustrates in-vehicle display devices and lighting devices.

FIGS. 14A to 14C illustrate an electronic device.

FIGS. 15A and 15B illustrate a structure of a light-emitting device according to Example 1.

FIG. 16 shows absorption spectra and an emission spectrum of materials used for comparative devices according to Example 1.

FIG. 17 shows absorption spectra and an emission spectrum of materials used for comparative devices according to Example 1.

FIG. 18 shows an absorption spectrum and emission spectra of materials used for light-emitting devices according to Example 1.

FIG. 19 shows luminance versus current density characteristics of light-emitting devices according to Example 1.

FIG. 20 shows current efficiency versus luminance characteristics of the light-emitting devices according to Example 1.

FIG. 21 shows luminance versus voltage characteristics of the light-emitting devices according to Example 1.

FIG. 22 shows current versus voltage characteristics of the light-emitting devices according to Example 1.

FIG. 23 shows external quantum efficiency versus luminance characteristics of the light-emitting device according to Example 1.

FIG. 24 shows emission spectra of the light-emitting devices according to Example 1.

FIG. 25 shows time dependence of normalized luminance characteristics of the light-emitting devices according to Example 1.

FIG. 26 shows luminance versus current density characteristics of light-emitting devices according to Example 1.

FIG. 27 shows current efficiency versus luminance characteristics of the light-emitting devices according to Example 1.

FIG. 28 shows luminance versus voltage characteristics of the light-emitting devices according to Example 1.

FIG. 29 shows current versus voltage characteristics of the light-emitting devices according to Example 1.

FIG. 30 shows external quantum efficiency versus luminance characteristics of the light-emitting devices according to Example 1.

FIG. 31 shows emission spectra of the light-emitting devices according to Example 1.

FIG. 32 shows time dependence of normalized luminance characteristics of the light-emitting devices according to Example 1.

FIG. 33 shows luminance versus current density characteristics of light-emitting devices according to Example 1.

FIG. 34 shows current efficiency versus luminance characteristics of the light-emitting devices according to Example 1.

FIG. 35 shows luminance versus voltage characteristics of the light-emitting devices according to Example 1.

FIG. 36 shows current versus voltage characteristics of the light-emitting devices according to Example 1.

FIG. 37 shows external quantum efficiency versus luminance characteristics of the light-emitting devices according to Example 1.

FIG. 38 shows emission spectra of the light-emitting devices according to Example 1.

FIG. 39 shows time dependence of normalized luminance characteristics of the light-emitting devices according to Example 1.

FIG. 40 shows luminance versus current density characteristics of light-emitting devices according to Example 1.

FIG. 41 shows current efficiency versus luminance characteristics of the light-emitting devices according to Example 1.

FIG. 42 shows luminance versus voltage characteristics of the light-emitting devices according to Example 1.

FIG. 43 shows current versus voltage characteristics of the light-emitting devices according to Example 1.

FIG. 44 shows external quantum efficiency versus luminance characteristics of the light-emitting devices according to Example 1.

FIG. 45 shows emission spectra of the light-emitting devices according to Example 1.

FIG. 46 shows time dependence of normalized luminance characteristics of the light-emitting devices according to Example 1.

FIG. 47 shows external quantum efficiency versus fluorescent dopant concentration characteristics of light-emitting devices according to Example 1.

FIG. 48 shows LT90 versus fluorescent dopant concentration characteristics of the light-emitting devices according to Example 1.

FIG. 49 shows external quantum efficiency versus fluorescent dopant concentration characteristics of light-emitting devices according to Example 1.

FIG. 50 shows LT90 versus fluorescent dopant concentration characteristics of the light-emitting devices according to Example 1.

FIG. 51 shows luminance versus current density characteristics of comparative devices according to Example 1.

FIG. 52 shows current efficiency versus luminance characteristics of the comparative devices according to Example 1.

FIG. 53 shows luminance versus voltage characteristics of the comparative devices according to Example 1.

FIG. 54 shows current versus voltage characteristics of the comparative devices according to Example 1.

FIG. 55 shows external quantum efficiency versus luminance characteristics of the comparative devices according to Example 1.

FIG. 56 shows emission spectra of the comparative devices according to Example 1.

FIG. 57 shows time dependence of normalized luminance characteristics of the light-emitting devices according to Example 1.

### DETAILED DESCRIPTION OF THE INVENTION

One embodiment of the present invention is a light-emitting device including a first electrode, a second electrode, and a light-emitting layer positioned between the first electrode and the second electrode. The light-emitting layer includes an organometallic complex having a function of emitting phosphorescence at room temperature and a light-emitting material having a function of emitting fluorescence. The organometallic complex includes a ligand with at least one first substituent selected from a branched alkyl group having 3 to 12 carbon atoms, a substituted or unsubstituted cycloalkyl group having 3 to 10 carbon atoms in a ring, and a trialkylsilyl group having 3 to 12 carbon atoms. An absorption spectrum of the light-emitting material has the longest-wavelength edge at a first wavelength λabs (nm), and a phosphorescence spectrum of the organometallic complex has the shortest-wavelength edge at a second wavelength λp (nm). The first wavelength λabs (nm) is longer than the second wavelength λp (nm).

Thus, the organometallic complex can be used as the energy donor material to allow the transfer of the energy, particularly triplet excited energy, of the energy donor material to the light-emitting material. A first substituent R¹ is interposed between the energy donor material and the light-emitting material that are close to each other. The energy transfer by the Dexter mechanism can be inhibited. The energy transfer by the Förster mechanism can be dominant. The light-emitting material can be brought into a singlet excited state. The probability of generating the singlet excited state of the light-emitting material can be increased. Alternatively, emission efficiency can be increased. As a result, a novel light-emitting device that is highly convenient, useful, or reliable can be provided.

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Therefore, the present invention should not be construed as being limited to the description in the following embodiments. Note that in structures of the present invention described below, the same portions or portions having similar functions are denoted by the same reference numerals in different drawings, and the description thereof is not repeated.

### Embodiment 1

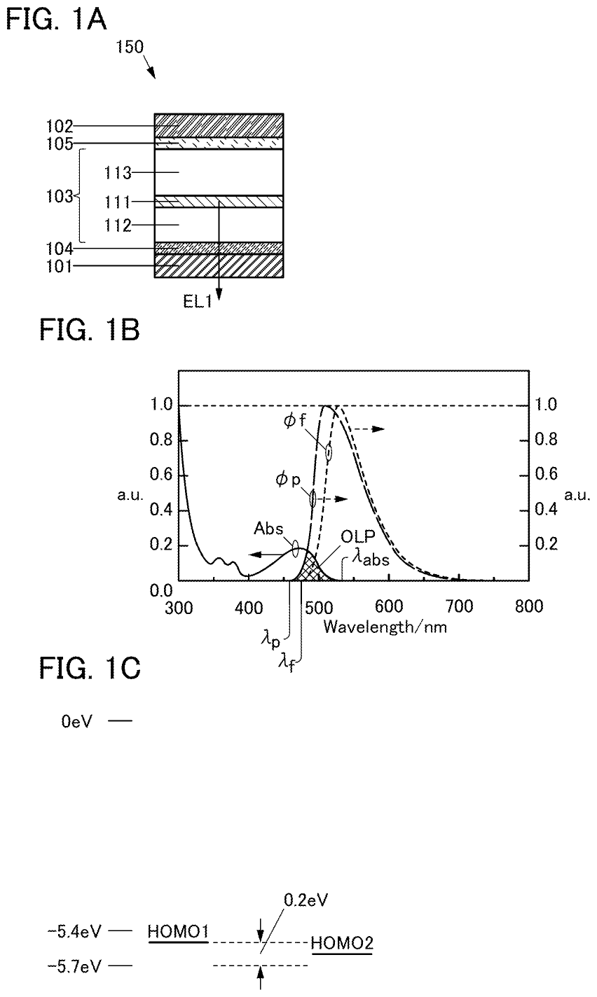

In this embodiment, a structure of the light-emitting device 150 of one embodiment of the present invention is described with reference to FIGS. 1A to 1C.

FIG. 1A illustrates a structure of the light-emitting device of one embodiment of the present invention, and FIGS. 1B and 1C illustrate a structure of a layer 111 of the light-emitting device of one embodiment of the present invention.

### <Structure Example of Light-Emitting Device 150>

The light-emitting device 150 described in this embodiment includes an electrode 101, an electrode 102, and a unit 103. The electrode 102 includes a region overlapping with the electrode 101, and the unit 103 includes a region interposed between the electrode 101 and the electrode 102 (see FIG. 1A).

### <Structure Example of Unit 103>

The unit 103 has a single-layer structure or a stacked-layer structure. For example, the unit 103 includes the layer 111, a layer 112, and a layer 113.

The layer 111 is positioned between the electrode 101 and the electrode 102, the layer 112 is positioned between the electrode 101 and the layer 111, and the layer 113 is positioned between the electrode 102 and the layer 111.

For example, a layer selected from functional layers such as a light-emitting layer, a hole-transport layer, an electron-transport layer, a carrier-blocking layer, and the like can be used for the unit 103. A layer selected from functional layers such as a hole-injection layer, an electron-injection layer, an exciton-blocking layer, a charge-generation layer, and the like can also be used for the unit 103.

<<Structure Example 1 of Layer 111>>

The layer 111 includes an energy donor material ED and a light-emitting material FM. For example, an organometallic complex can be used as the energy donor material ED. The layer 111 can be referred to as a light-emitting layer. Note that the layer 111 can include a host material and the light-emitting material FM can serve as a guest material. Light emission from the light-emitting material FM can thus be obtained. Light emission from the guest material can be obtained.

The layer 111 is preferably placed in a region where holes and electrons recombine. Thus, energy generated by the recombination of carriers can be efficiently converted into light and emitted. Furthermore, the layer 111 is preferably placed to be distanced from a metal used for the electrode or the like. Thus, a quenching phenomenon caused by the metal used for the electrode or the like can be inhibited.

### Example 1 of Exciplex Donor Material ED

For example, the organometallic complex can be used as the energy donor material ED. The organometallic complex includes a ligand.

The ligand has a substituent R¹, and the substituent R¹ is selected from a branched alkyl group, a substituted or unsubstituted cycloalkyl group, and a trialkylsilyl group. The ligand can have a methyl group in addition to the substituent R¹.

When the substituent R¹ is a branched alkyl group, the number of carbon atoms of the branched alkyl group is 3 to 12. When the substituent R¹ is a cycloalkyl group, the number of carbon atoms in a ring of the cycloalkyl group is 3 to 10. When the substituent R¹ is a trialkylsilyl group, the number of carbon atoms of the trialkylsilyl group is 3 to 12.

When R¹ is a branched alkyl group, for example, a secondary alkyl group or a tertiary alkyl group can be used as the substituent R¹. Specifically, as the substituent R¹, an alkyl group in which carbon bonded to the mother skeleton is branched can be used. This can reduce the number of α-hydrogen atoms. The reliability of the light-emitting device can be increased.

When R¹ is a branched alkyl group, for example, an alkyl group having 3 or 4 carbon atoms can be used as the substituent R¹. Thus, the center distance between the energy donor material ED and the light-emitting material FM that are close to each other can be set suitable. The energy transfer by the Dexter mechanism can be inhibited. The energy transfer by the Förster mechanism can be promoted. The reliability of the light-emitting device can be increased.

When R¹ is a cycloalkyl alkyl group, for example, a cycloalkyl group having 3 to 6 carbon atoms, can be used as the substituent R¹. Thus, the center distance between the energy donor material ED and the light-emitting material FM that are close to each other can be set suitable. The energy transfer by the Dexter mechanism can be inhibited. The energy transfer by the Förster mechanism can be promoted. The reliability of the light-emitting device can be increased.

When R¹ is a trialkylsilyl alkyl group, for example, a trimethylsilyl group can be used as the substituent R¹. Thus, the center distance between the energy donor material ED and the light-emitting material FM that are close to each other can be set suitable. The energy transfer by the Dexter mechanism can be inhibited. The energy transfer by the Förster mechanism can be promoted. The reliability of the light-emitting device can be increased.

The substituent R¹ can include, for example, deuterium instead of hydrogen. This can inhibit release of hydrogen. The reliability of the light-emitting device can be increased.

The organometallic complex has a function of emitting phosphorescence at room temperature. The phosphorescence spectrum of the organometallic complex has the shortest-wavelength edge at the wavelength λp (nm) (see FIG. 1). The wavelength λp (nm) can be calculated as a wavelength at the intersection of the horizontal axis and a tangent to the wavelength in the shortest wavelength range at the point where the slope of the tangent of the phosphorescence spectrum has a maximum value. That is, the wavelength λp (nm) is the wavelength of the rising portion (onset) on the shorter wavelength side of the phosphorescence spectrum.

Examples of a secondary or tertiary alkyl group having 3 to 12 carbon atoms, are branched-chain alkyl groups such as an isopropyl group and a tert-butyl group. The branched-chain alkyl group is not limited to these examples. Examples of a cycloalkyl group having 3 to 10 carbon atoms are a cyclopropyl group, a cyclobutyl group, a cyclohexyl group, a norbornyl group, an adamantyl group, and the like. The cycloalkyl group is not limited to these examples. When the cycloalkyl group has a substituent, examples of the substituent are an alkyl group having 1 to 7 carbon atoms such as a methyl group, an isopropyl group, or a tert-butyl group, a cycloalkyl group having 5 to 7 carbon atoms such as a cyclopentyl group, a cyclohexyl group, a cycloheptyl group, or a 8,9,10-trinorbornanyl group, an aryl group having 6 to 12 carbon atoms such as a phenyl group, a naphthyl group, or a biphenyl group, and the like. Examples of a trialkylsilyl group having 3 to 12 carbon atoms, are a trimethylsilyl group, a triethylsilyl group, a tert-butyl dimethylsilyl group, and the like. The trialkylsilyl group is not limited to these examples.

The organometallic complex used in the light-emitting device of one embodiment of the present invention does not include an n-alkyl group having 2 or more carbon atoms. For example, when the organometallic complex includes an alkyl group in addition to the substituent R¹, the alkyl group is preferably a methyl group. Thus, the reliability of the light-emitting device can be increased.

### Example 2 of Energy Donor Material ED

For example, the organometallic complex can be used as the energy donor material ED. The organometallic complex includes a ligand and a transition metal. For example, the transition metal can be used as the central metal. In particular, an organometallic complex having iridium or platinum as the central metal is preferably used. Thus, a radiative triplet excited state can be obtained. The organometallic complex can be chemically stabilized. Since a ligand around the central metal is likely to form a three-dimensionally bulky structure, which can easily prevent the Dexter transfer, trivalent iridium is particularly preferred as the central metal.

The ligand includes a first ring and a second ring and at least one substituent R¹ is bonded to at least one of the first and second rings.

The first ring is a six-membered ring and includes an atom that is covalently bonded to the transition metal as a constituent atom. The second ring is a five-membered ring or a six-membered ring and includes an atom that is coordinated to the transition metal as a constituent atom. Note that the first ring is preferably a benzene ring. The constituent atom coordinated to the transition metal may be N as in a pyridine ring or C as in carbene.

### Example 3 of Energy Donor Material ED

For example, the organometallic complex can be used as the energy donor material ED. The organometallic complex includes a ligand.

The ligand has a phenylpyridine skeleton and at least one substituent R¹ is bonded to carbon of the phenylpyridine skeleton.

### Example 4 of Energy Donor Material ED

For example, an organometallic complex represented by General Formula (G0) below can be used as the energy donor material ED.

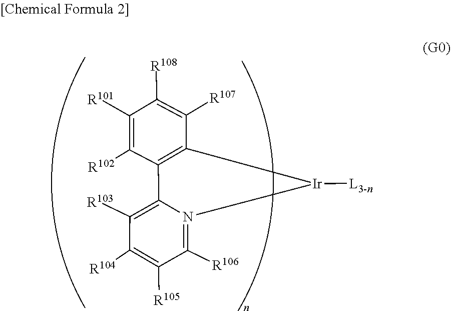

In the above general formula, L is a ligand, and n is an integer greater than or equal to 1 and less than or equal to 3. Note that n is preferably an integer greater than or equal to 2. Thus, the energy transfer by the Dexter mechanism can be inhibited. The energy transfer by the Förster mechanism can be dominant.

Furthermore, R¹⁰¹ to R¹⁰⁸ each independently represent hydrogen or a substituent and include any one or more of an alkyl group, a substituted or unsubstituted cycloalkyl group, and a trialkylsilyl group. Note that the alkyl group is preferably a secondary or tertiary alkyl group having 3 to 12 carbon atoms, the cycloalkyl group preferably has 3 to 10 carbon atoms and the trialkylsilyl group preferably has 3 to 12 carbon atoms. In other words, the above substituent R¹ is included in R¹⁰¹ to R¹⁰⁸.

Accordingly, the light emission efficiency can be increased. As a result, a novel light-emitting device that is highly convenient, useful, or reliable can be provided.

### Example 5 of Energy Donor Material ED

For example, two ligands have a phenylpyridine skeleton and a substituent bonded to carbon of the phenylpyridine skeleton. As the substituent, a secondary or tertiary alkyl group having 3 to 12 carbon atoms, a cycloalkyl group having 3 to 12 carbon atoms, or a trialkylsilyl group having 3 to 12 carbon atoms, can be used, for example.

Specific examples of the organic compound having the above-described structure are shown below.

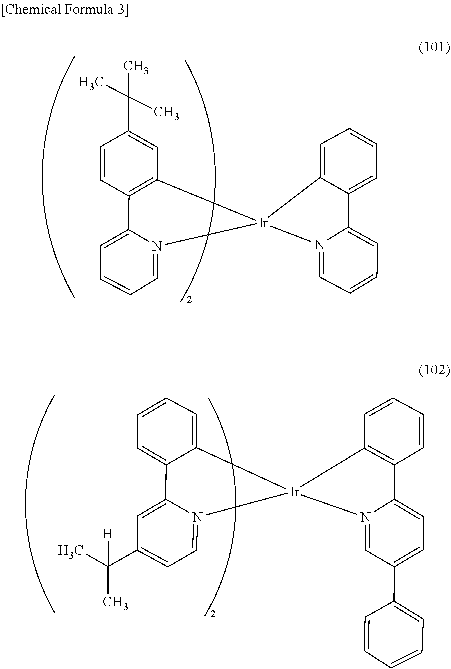

### Example 6 of Energy Donor Material ED

For example, three ligands have a phenylpyridine skeleton and one or more substituents bonded to carbon of the phenylpyridine skeleton. As the substituent, a secondary or tertiary alkyl group having 3 to 12 carbon atoms, a cycloalkyl group having 3 to 12 carbon atoms, or a trialkylsilyl group having 3 to 12 carbon atoms, can be used, for example. The ligands having the same structure can be used as two of the three ligands.

Specific examples of the organic compound having the above-described structure are shown below.

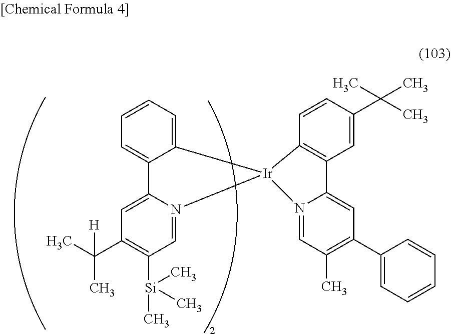

### Example 7 of Energy Donor Material ED

For example, three ligands have a phenylpyridine skeleton and a substituent bonded to carbon of the phenylpyridine skeleton. As the substituent, a secondary or tertiary alkyl group having 3 to 12 carbon atoms, a cycloalkyl group having 3 to 12 carbon atoms, or a trialkylsilyl group having 3 to 12 carbon atoms, can be used, for example. The ligands having the same structure can be used as the three ligands.

Specific examples of the organic compound having the above-described structure are shown below.

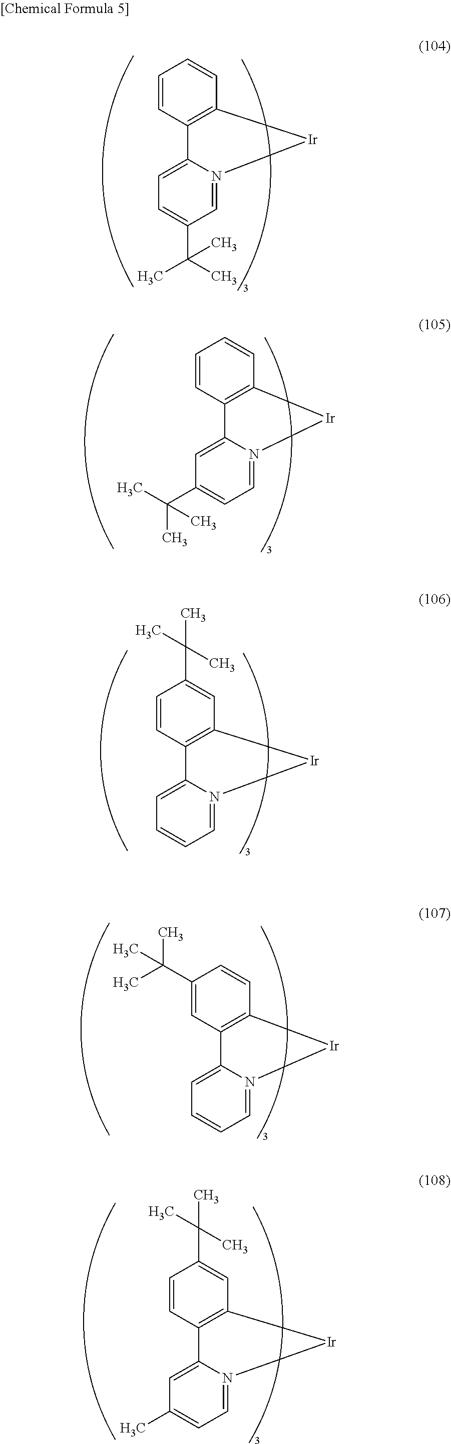

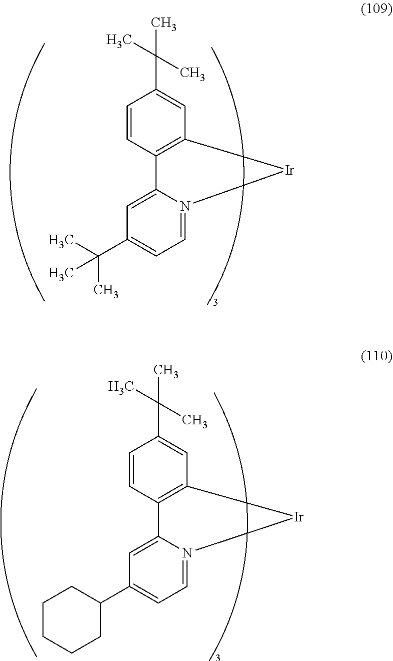

### Example 8 of Energy Donor Material ED

For example, two ligands have a phenylpyridine skeleton and a substituent bonded to carbon of the phenylpyridine skeleton. As the substituent, a secondary or tertiary alkyl group having 3 to 12 carbon atoms, a cycloalkyl group having 3 to 12 carbon atoms, or a trialkylsilyl group having 3 to 12 carbon atoms, can be used, for example. As the substituent, a substituent in which one or more of hydrogen atoms is/are substituted by deuterium atoms can be used. This can increase the reliability.

Specific examples of the organic compound having the above-described structure are shown below.

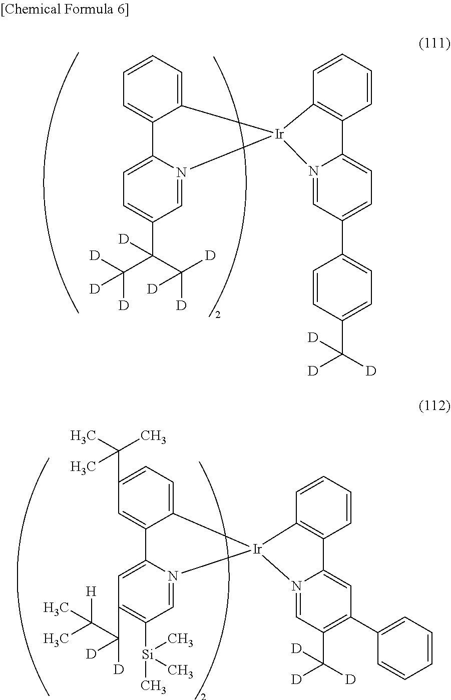

### Example 1 of Light-Emitting Material FM

The light-emitting material FM has a function of emitting fluorescence and has an absorption spectrum Abs (see FIG. 1i). The light-emitting material FM can be referred to as a fluorescent substance.

The absorption spectrum Abs of the light-emitting material FM has the longest-wavelength edge at the wavelength λabs (nm). The wavelength λabs (nm) is longer than the wavelength λp (nm). The wavelength λabs (nm) can be calculated as a wavelength at the intersection of the horizontal axis and a tangent to the wavelength in the longest wavelength range at the point where the slope of the tangent of the absorption spectrum has a minimum value. In other words, the wavelength λabs (nm) is an absorption edge of the absorption spectrum. Note that the wavelength λp (nm) is the shortest-wavelength edge of the phosphorescence spectrum ϕp of the energy donor material ED, as described above.

More preferably, the relationship between the wavelength λabs (nm) and the wavelength λp (nm) is represented by Formula (1) below. Thus, the absorption band of the light-emitting material FM that is positioned in the longest wavelength range overlaps better with the phosphorescence spectrum of the organometallic complex.

$$\begin{matrix}[ Formula 1 ] & \\ 0.05 < 1240 \times ( \frac{1}{{λ}_{p}} - \frac{1}{{λ}_{abs}} ) \leq 0.30 & ( 1 )\end{matrix}$$

### Example 2 of Light-Emitting Material FM

Fluorescence emitted by the light-emitting material FM has a fluorescence spectrum ϕf, and the fluorescence spectrum ϕf has the shortest-wavelength edge at a wavelength λf (nm) (see FIG. 1i). The wavelength λf (nm) can be calculated as a wavelength at the intersection of the horizontal axis and a tangent to the wavelength in the shortest wavelength range at the point where the slope of the tangent of the fluorescence spectrum has a maximum value. That is, the wavelength λf (nm) is the wavelength of the rising portion (onset) on the shorter wavelength side of the fluorescence spectrum. The relationship between the wavelength λf (nm) and the wavelength λp (nm) is represented by the following formula.

$$\begin{matrix}[ Formula 2 ] & \\ 0 \leq 1240 \times ( \frac{1}{{λ}_{p}} - \frac{1}{{λ}_{f}} ) \leq 0.1 & ( 2 )\end{matrix}$$

Thus, the organometallic complex can be used as the energy donor material ED to allow the transfer of the energy, particularly triplet excited energy, of the energy donor material ED to the light-emitting material FM. The first substituent R¹ is interposed between the energy donor material ED and the light-emitting material FM that are close to each other. The energy transfer by the Dexter mechanism can be inhibited. The energy transfer by the Förster mechanism can be dominant. The light-emitting material FM can be brought into a singlet excited state. The probability of generating the singlet excited state of the light-emitting material FM can be increased. Alternatively, emission efficiency can be increased. As a result, a novel light-emitting device that is highly convenient, useful, or reliable can be provided.

### Example 3 of Light-Emitting Material FM

For example, fluorescent substances given below can be used for the layer 111. Note that the fluorescent substance that can be used for the layer 111 is not limited to the following, but a variety of known fluorescent substances can be used.

Specifically, N,N,N′,N′-tetrakis(4-methylphenyl)-9,10-anthracenediamine (abbreviation: TTPA), N,N′-diphenylquinacridone (abbreviation: DPQd), or the like can be used.

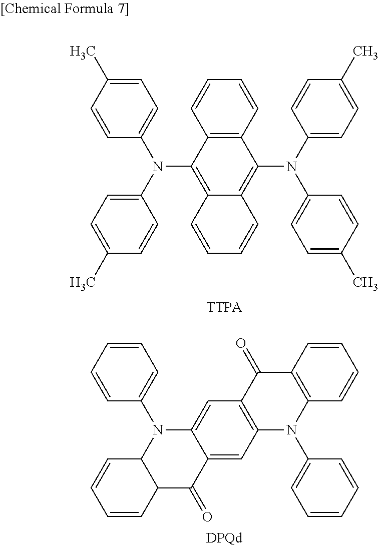 [SMILES: Cc1ccc(N(c2ccc(C)cc2)c2c3ccccc3c(N(c3ccc(C)cc3)c3ccc(C)cc3)c3ccccc23)cc1 ; O=C1c2cc3c(cc2N(c2ccccc2)C2C=CC=CC12)c(=O)c1ccccc1n3-c1ccccc1]

### Example 4 of Light-Emitting Material FM

The light-emitting material FM that can be preferably used for the light-emitting device of one embodiment of the present invention has at least one substituent R².

The substituent R² is selected from a methyl group, a branched alkyl group, a substituted or unsubstituted cycloalkyl group, and a trialkylsilyl group. When the substituent R² is a branched alkyl group, the number of carbon atoms of the branched alkyl group is 3 to 12. When the substituent R² is a cycloalkyl group, the number of carbon atoms in a ring of the cycloalkyl group is 3 to 10. When the substituent R² is a trialkylsilyl group, the number of carbon atoms of the trialkylsilyl group is 3 to 12.

When R² is a branched alkyl group, for example, a secondary alkyl group or a tertiary alkyl group can be used as the substituent R². Specifically, as the substituent R², an alkyl group in which carbon bonded to the mother skeleton is branched can be used. This can reduce the number of α-hydrogen atoms. The reliability of the light-emitting device can be increased.

When R² is a branched alkyl group, for example, an alkyl group having 3 or 4 carbon atoms can be used as the substituent R². Thus, the center distance between the energy donor material ED and the light-emitting material FM that are close to each other can be set suitable. The energy transfer by the Dexter mechanism can be inhibited. The energy transfer by the Förster mechanism can be promoted. The reliability of the light-emitting device can be increased.

When R² is a cycloalkyl alkyl group, for example, a cycloalkyl group having 3 to 6 carbon atoms, can be used as the substituent R². Thus, the center distance between the energy donor material ED and the light-emitting material FM that are close to each other can be set suitable. The energy transfer by the Dexter mechanism can be inhibited. The energy transfer by the Förster mechanism can be promoted. The reliability of the light-emitting device can be increased.

When R² is a trialkylsilyl alkyl group, for example, a trimethylsilyl group can be used as the substituent R². Thus, the center distance between the energy donor material ED and the light-emitting material FM that are close to each other can be set suitable. The energy transfer by the Dexter mechanism can be inhibited. The energy transfer by the Förster mechanism can be promoted. The reliability of the light-emitting device can be increased.

The substituent R² can include, for example, deuterium instead of hydrogen. This can inhibit release of hydrogen. The reliability of the light-emitting device can be increased.

The absorption spectrum Abs of the light-emitting material FM has a region OLP overlapping with the phosphorescence spectrum ϕp of the energy donor material ED (see FIG. 1). The region OLP is in the absorption band in the longest wavelength range of the absorption spectrum Abs of the light-emitting material FM.

### Example 5 of Light-Emitting Material FM

The light-emitting material FM that can be used for the light-emitting device of one embodiment of the present invention has five or more substituents R² and a condensed aromatic ring or a condensed heteroaromatic ring.

The condensed aromatic ring or the condensed heteroaromatic ring includes 3 to 10 rings. The five or more substituents R² each independently include a branched alkyl group, a substituted or unsubstituted cycloalkyl group, or a trialkylsilyl group. In other words, the five or more substituents R² are groups other than a methyl group. When the substituent R² is a branched alkyl group, the number of carbon atoms of the branched alkyl group is 3 to 12. When the substituent R² is a cycloalkyl group, the number of carbon atoms in a ring of the cycloalkyl group is 3 to 10. When the substituent R² is a trialkylsilyl group, the number of carbon atoms of the trialkylsilyl group is 3 to 12.

### Example 6 of Light-Emitting Material FM

The light-emitting material FM that can be used for the light-emitting device of one embodiment of the present invention has three or more substituents R² and a condensed aromatic ring or a condensed heteroaromatic ring.

The condensed aromatic ring or the condensed heteroaromatic ring includes 3 to 10 rings. The three or more substituents R² are not directly bonded to the condensed aromatic ring or the condensed heteroaromatic ring. The three or more substituents R² each independently include an alkyl group, a substituted or unsubstituted cycloalkyl group, or a trialkylsilyl group. When the substituent R² is an alkyl group, the number of carbon atoms of the alkyl group is 3 to 12. When the substituent R² is a cycloalkyl group, the number of carbon atoms in a ring of the cycloalkyl group is 3 to 10. When the substituent R² is a trialkylsilyl group, the number of carbon atoms of the trialkylsilyl group is 3 to 12.

### Example 7 of Light-Emitting Material FM

The light-emitting material FM that can be used for the light-emitting device of one embodiment of the present invention has a diarylamino group and a condensed aromatic ring or a condensed heteroaromatic ring.

The condensed aromatic ring or the condensed heteroaromatic ring includes 3 to 10 rings. A nitrogen atom of the diarylamino group is bonded to the condensed aromatic ring or the condensed heteroaromatic ring, and an aryl group of the diarylamino group is bonded to the substituent R².

### Example 8 of Light-Emitting Material FM

For example, an organic compound represented by General Formula (G1) below can be used as the light-emitting material FM.

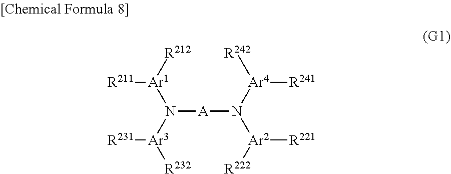

In the above general formula, A is a π-conjugated system, and for example, a condensed aromatic ring or a condensed heteroaromatic ring can be used for A. Specifically, a condensed aromatic ring including 3 to 10 rings or a condensed heteroaromatic ring including 3 to 10 rings can be used for A.

Furthermore, R²¹¹ to R²⁴² each independently represent hydrogen or a substituent and include any one or more of a branched alkyl group, a substituted or unsubstituted cycloalkyl group, and a trialkylsilyl group. Note that the branched alkyl group is preferably a secondary or tertiary alkyl group having 3 to 12 carbon atoms, the cycloalkyl group preferably has 3 to 10 carbon atoms and the trialkylsilyl group preferably has 3 to 12 carbon atoms. In other words, the above substituent R² is included in R²¹¹ to R²⁴².

Furthermore, N is a nitrogen atom and Ar¹ to Ar⁴ are aryl groups. In other words, the light-emitting material FM includes a diarylamino group. A nitrogen atom of the diarylamino group is bonded to A, and an aryl group of the diarylamino group is bonded to the substituent R². Note that the light-emitting material FM preferably includes two or more diarylamino groups.

### Example 9 of Light-Emitting Material FM

For example, an organic compound represented by General Formula (G2) or General Formula (G3) below can be used as the light-emitting material FM.

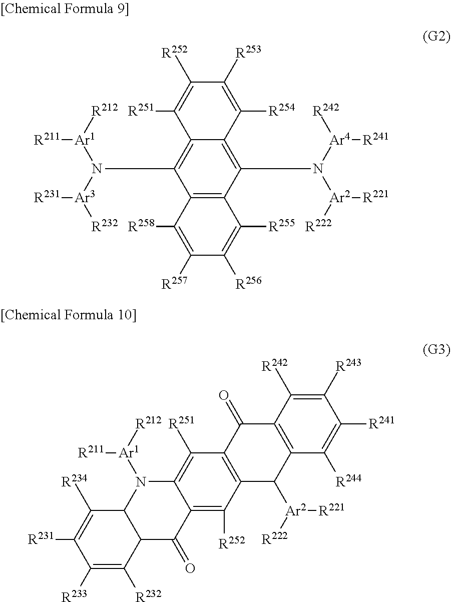

In the above general formulae, R²¹¹ to R²⁵⁸ each independently represent hydrogen or a substituent and include any one or more of a branched alkyl group, a substituted or unsubstituted cycloalkyl group, and a trialkylsilyl group. Note that the branched alkyl group is preferably a secondary or tertiary alkyl group having 3 to 12 carbon atoms, the cycloalkyl group preferably has 3 to 10 carbon atoms and the trialkylsilyl group preferably has 3 to 12 carbon atoms. In other words, the above substituent R² is included in R²¹¹ to R²⁵⁸.

### Example 10 of Light-Emitting Material FM

For example, an organic compound represented by General Formula (G4) or General Formula (G5) below can be used as the light-emitting material FM.

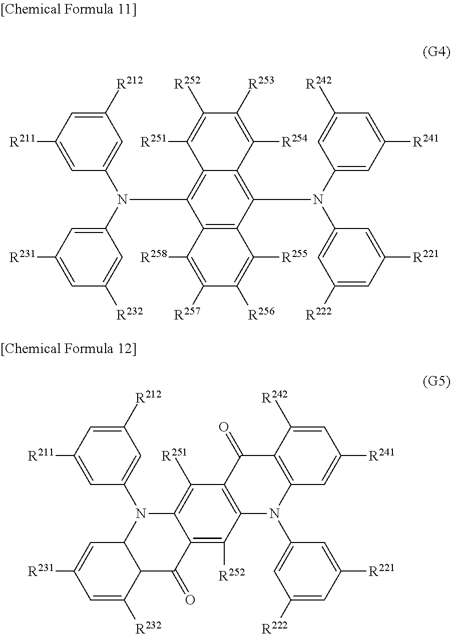

In the above general formulae, R²¹¹ to R²⁵⁸ each independently represent hydrogen or a substituent and include any one or more of a branched alkyl group, a substituted or unsubstituted cycloalkyl group, and a trialkylsilyl group. Note that the branched alkyl group is preferably a secondary or tertiary alkyl group having 3 to 12 carbon atoms, the cycloalkyl group preferably has 3 to 10 carbon atoms and the trialkylsilyl group preferably has 3 to 12 carbon atoms. In other words, the above substituent R² is included in R²¹¹ to R²⁵⁸, and the substituent R² is bonded to the carbon atom in the meta-position of a benzene ring bonded to the nitrogen atom in the diarylamino group.

Thus, the organometallic complex can be used as the energy donor material ED to allow the transfer of the energy, particularly triplet excited energy, of the energy donor material ED to the light-emitting material FM. The first substituent R¹ and the second substituent R² are interposed between the energy donor material ED and the light-emitting material FM that are close to each other. The energy transfer by the Dexter mechanism can be inhibited. The energy transfer by the Förster mechanism can be dominant. The light-emitting material FM can be brought into a singlet excited state. The probability of generating the singlet excited state of the light-emitting material FM can be increased. Alternatively, emission efficiency can be increased. The concentration of the light-emitting material FM can be increased. As a result, a novel light-emitting device that is highly convenient, useful, or reliable can be provided.

Specific examples of the organic compound having the above-described structure are shown below.

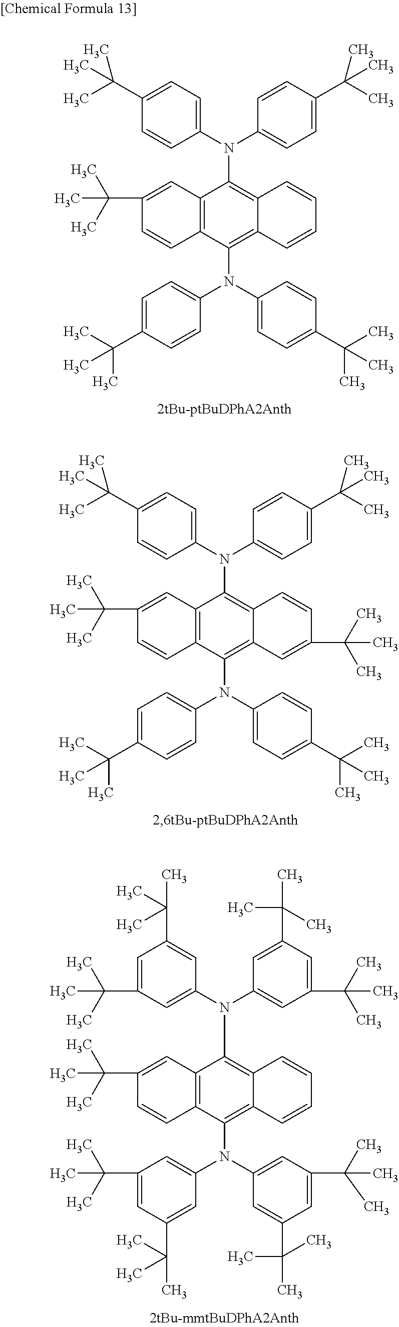

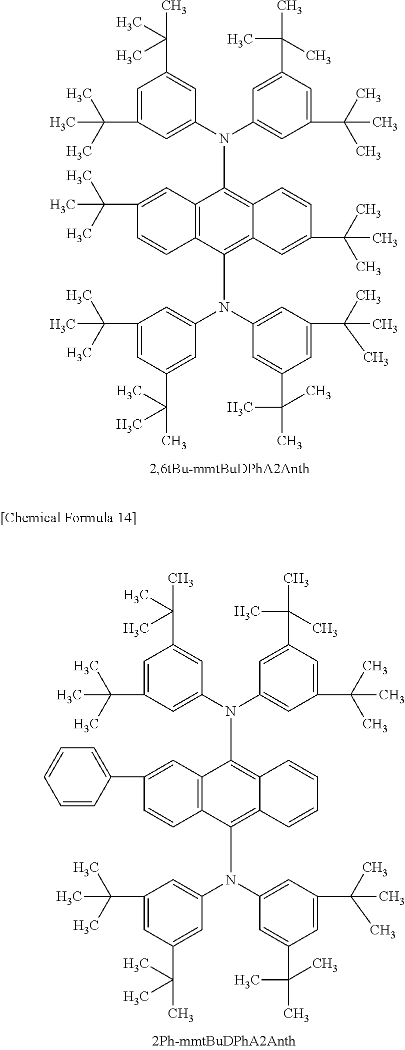 [SMILES: CC(C)(C)c1cc(N(c2cc(C(C)(C)C)cc(C(C)(C)C)c2)c2c3ccc(C(C)(C)C)cc3c(N(c3cc(C(C)(C)C)cc(C(C)(C)C)c3)c3cc(C(C)(C)C)cc(C(C)(C)C)c3)c3ccc(C(C)(C)C)cc23)cc(C(C)(C)C)c1 ; CC(C)(C)c1cc(N(c2cc(C(C)(C)C)cc(C(C)(C)C)c2)c2c3ccccc3c(N(c3cc(C(C)(C)C)cc(C(C)(C)C)c3)c3cc(C(C)(C)C)cc(C(C)(C)C)c3)c3cc(-c4ccccc4)ccc23)cc(C(C)(C)C)c1]

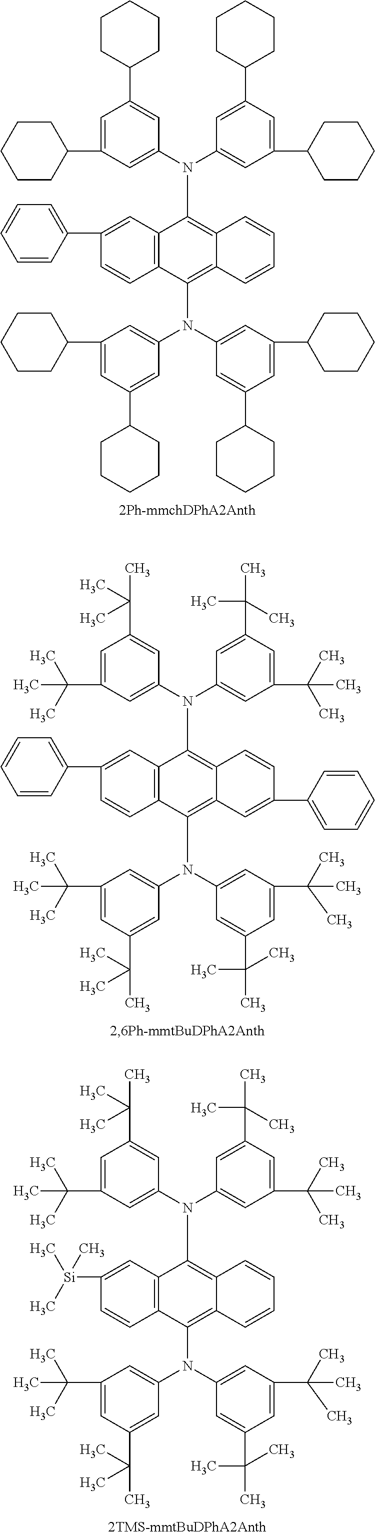 [SMILES: c1ccc(-c2ccc3c(N(c4cc(C5CCCCC5)cc(C5CCCCC5)c4)c4cc(C5CCCCC5)cc(C5CCCCC5)c4)c4ccccc4c(N(c4cc(C5CCCCC5)cc(C5CCCCC5)c4)c4cc(C5CCCCC5)cc(C5CCCCC5)c4)c3c2)cc1 ; CC(C)(C)c1cc(N(c2cc(C(C)(C)C)cc(C(C)(C)C)c2)c2c3ccc(-c4ccccc4)cc3c(N(c3cc(C(C)(C)C)cc(C(C)(C)C)c3)c3cc(C(C)(C)C)cc(C(C)(C)C)c3)c3ccc(-c4ccccc4)cc23)cc(C(C)(C)C)c1 ; CC(C)(C)c1cc(N(c2cc(C(C)(C)C)cc(C(C)(C)C)c2)c2c3ccccc3c(N(c3cc(C(C)(C)C)cc(C(C)(C)C)c3)c3cc(C(C)(C)C)cc(C(C)(C)C)c3)c3cc([Si](C)(C)C)ccc23)cc(C(C)(C)C)c1]

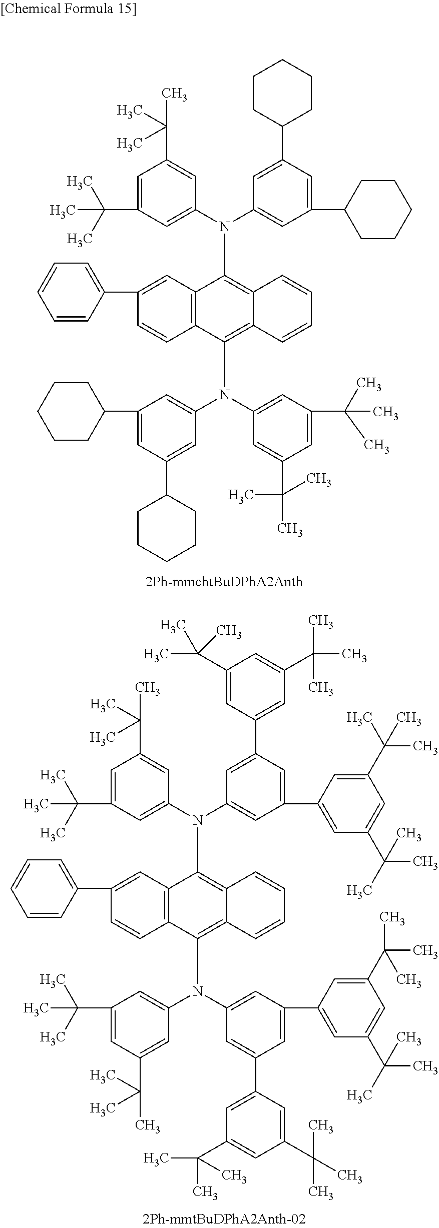 [SMILES: CC(C)(C)c1cc(N(c2cc(C3CCCCC3)cc(C3CCCCC3)c2)c2c3ccccc3c(N(c3cc(C4CCCCC4)cc(C4CCCCC4)c3)c3cc(C(C)(C)C)cc(C(C)(C)C)c3)c3cc(-c4ccccc4)ccc23)cc(C(C)(C)C)c1 ; CC(C)(C)c1cc(-c2cc(-c3cc(C(C)(C)C)cc(C(C)(C)C)c3)cc(N(c3cc(C(C)(C)C)cc(C(C)(C)C)c3)c3c4ccccc4c(N(c4cc(-c5cc(C(C)(C)C)cc(C(C)(C)C)c5)cc(-c5cc(C(C)(C)C)cc(C(C)(C)C)c5)c4)c4cc(C(C)(C)C)cc(C(C)(C)C)c4)c4cc(-c5ccccc5)ccc34)c2)cc(C(C)(C)C)c1]

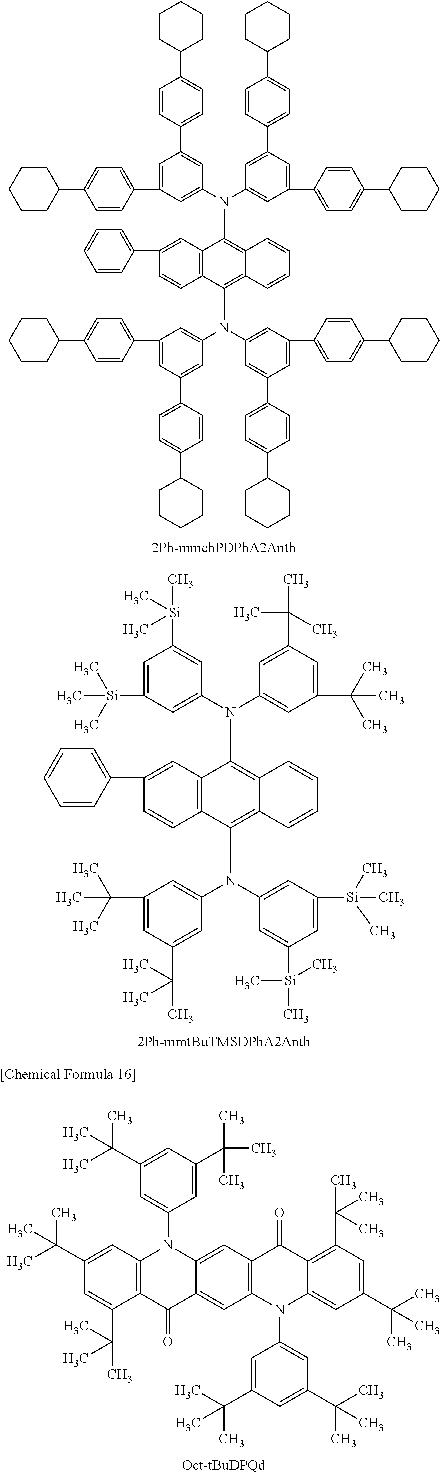

### <<Structure Example 2 of Layer 111>>

For example, the host material can be used for the layer 111. Specifically, a material having a carrier-transport property (also referred to as a carrier-transport material) can be used as the host material. For example, a material having a hole-transport property (also referred to as a hole-transport material), a material having an electron-transport property (also referred to as an electron-transport material), a material having an anthracene skeleton, a mixed material, or the like can be used as the host material. Thus, energy generated by recombination of carriers can be released as light EL1 from the light-emitting material FM (see FIG. 1A).

### [Hole-Transport Material]

A material having a hole mobility of 1×10⁻⁶ cm²/Vs or higher can be suitably used for the hole-transport material.

For example, an amine compound or an organic compound having a π-electron rich heteroaromatic ring skeleton can be used as the hole-transport material. Specifically, a compound having an aromatic amine skeleton, a compound having a carbazole skeleton, a compound having a thiophene skeleton, a compound having a furan skeleton, or the like can be used. In particular, the compound having an aromatic amine skeleton or the compound having a carbazole skeleton is preferable because these compounds are highly reliable and have high hole-transport properties to contribute to a reduction in driving voltage.

The following are examples that can be used as the compound having an aromatic amine skeleton: 4,4′-bis[N-(1-naphthyl)-N-phenylamino]biphenyl (abbreviation: NPB), N,N′-bis(3-methylphenyl)-N,N′-diphenyl-[1,1′-biphenyl]-4,4′-diamine (abbreviation: TPD), 4,4′-bis[N-(spiro-9,9′-bifluoren-2-yl)-N-phenylamino]biphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), 9,9-dimethyl-N-phenyl-N-[4-(9-phenyl-9H-carbazol-3-yl)phenyl]fluoren-2-amine (abbreviation: PCBAF), or N-phenyl-N-[4-(9-phenyl-9H-carbazol-3-yl)phenyl]spiro-9,9′-bifluoren-2-amine (abbreviation: PCBASF).

As a compound having a carbazole skeleton, for example, 1,3-bis(N-carbazolyl)benzene (abbreviation: mCP), 4,4′-di(N-carbazolyl)biphenyl (abbreviation: CBP), 3,6-bis(3,5-diphenylphenyl)-9-phenylcarbazole (abbreviation: CzTP), 3,3′-bis(9-phenyl-9H-carbazole) (abbreviation: PCCP), or the like can be used.

As a compound having a thiophene skeleton, for example, 4,4′,4″-(benzene-1,3,5-triyl)tri(dibenzothiophene) (abbreviation: DBF3P-II), 2,8-diphenyl-4-[4-(9-phenyl-9H-fluoren-9-yl)phenyl]dibenzothiophene (abbreviation: DBTFLP-III), 4-[4-(9-phenyl-9H-fluoren-9-yl)phenyl]-6-phenyldibenzothiophene (abbreviation: DBTFLP-IV), or the like can be used.

As a compound having a furan skeleton, for example, 4,4′,4″-(benzene-1,3,5-triyl)tri(dibenzofuran) (abbreviation: DBF3P-II), 4-{3-[3-(9-phenyl-9H-fluoren-9-yl)phenyl]phenyl}dibenzofuran (abbreviation: mmDBFFLBi-II), or the like can be used.

### [Electron-Transport Material]

For example, a metal complex or an organic compound having a π-electron deficient heteroaromatic ring skeleton can be used as the electron-transport material.

As the metal complex, bis(10-hydroxybenzo[h]quinolinato)beryllium(II) (abbreviation: BeBq₂), bis(2-methyl-8-quinolinolato)(4-phenylphenolato)aluminum(III) (abbreviation: BAlq), bis(8-quinolinolato)zinc(II) (abbreviation: Znq), bis[2-(2-benzoxazolyl)phenolato]zinc(II) (abbreviation: ZnPBO), bis[2-(2-benzothiazolyl)phenolato]zinc(II) (abbreviation: ZnBTZ), or the like can be used, for example.

As the organic compound having a π-electron deficient heteroaromatic ring skeleton, for example, a heterocyclic compound having a polyazole skeleton, a heterocyclic compound having a diazine skeleton, a heterocyclic compound having a pyridine skeleton, a heterocyclic compound having a triazine skeleton, or the like can be used. In particular, the heterocyclic compound having a diazine skeleton and the heterocyclic compound having a pyridine skeleton have favorable reliability and thus are preferable. In addition, the heterocyclic compound having a diazine (pyrimidine or pyrazine) skeleton has a high electron-transport property to contribute to a reduction in driving voltage.

As the heterocyclic compound having a polyazole skeleton, 2-(4-biphenylyl)-5-(4-tert-butylphenyl)-1,3,4-oxadiazole (abbreviation: PBD), 3-(4-biphenylyl)-4-phenyl-5-(4-tert-butylphenyl)-1,2,4-triazole (abbreviation: TAZ), 1,3-bis[5-(p-tert-butylphenyl)-1,3,4-oxadiazol-2-yl]benzene (abbreviation: OXD-7), 9-[4-(5-phenyl-1,3,4-oxadiazol-2-yl)phenyl]-9H-carbazole (abbreviation: CO11), 2,2′, 2″-(1,3,5-benzenetriyl)tris(1-phenyl-1H-benzimidazole) (abbreviation: TPBI), 2-[3-(dibenzothiophen-4-yl)phenyl]-1-phenyl-1H-benzimidazole (abbreviation: mDBTBIm-II), or the like can be used, for example.

As the heterocyclic compound having a diazine skeleton, for example, 2-[3-(dibenzothiophen-4-yl)phenyl]dibenzo[f,h]quinoxaline (abbreviation: 2mDBTPDBq-II), 2-[3′-(dibenzothiophen-4-yl)biphenyl-3-yl]dibenzo[f,h]quinoxaline (abbreviation: 2mDBTBPDBq-II), 2-[3′-(9H-carbazol-9-yl)biphenyl-3-yl]dibenzo[f,h]quinoxaline (abbreviation: 2mCzBPDBq), 4,6-bis[3-(phenanthren-9-yl)phenyl]pyrimidine (abbreviation: 4,6mPnP2Pm), 4,6-bis[3-(4-dibenzothienyl)phenyl]pyrimidine (abbreviation: 4,6mDBTP2Pm-II), 4,8-bis[3-(dibenzothiophen-4-yl)phenyl]benzo[h]quinazolin (abbreviation: 4,8mDBtP2Bqn), or the like can be used.

As the heterocyclic compound having a pyridine skeleton, for example, 3,5-bis[3-(9H-carbazol-9-yl)phenyl]pyridine (abbreviation: 35DCzPPy), 1,3,5-tri[3-(3-pyridyl)phenyl]benzene (abbreviation: TmPyPB), or the like can be used.

As the heterocyclic compound having a triazine, for example, 2-[3′-(9,9-dimethyl-9H-fluorene-2-yl)-1,1′-biphenyl-3-yl]-4,6-diphenyl-1,3,5-triazine (abbreviation: mFBPTzn), 2-[(1,1′-biphenyl)-4-yl]-4-phenyl-6-[9,9′-spirobi(9H-fluoren)-2-yl]-1,3,5-triazine (abbreviation: BP-SFTzn), 2-{3-[3-(benzo[b]naphtho[1,2-d]furan-8-yl)phenyl]phenyl}-4,6-diphenyl-1,3,5-triazine (abbreviation: mBnfBPTzn), 2-{3-[3-(benzo[b]naphtho[1,2-d]furan-6-yl)phenyl]phenyl}-4,6-diphenyl-1,3,5-triazine (abbreviation: mBnfBPTzn-02), or the like can be used.

### [Material Having Anthracene Skeleton]

An organic compound having an anthracene skeleton can be used as the host material. In particular, when a fluorescent substance is used as the light-emitting substance, an organic compound having an anthracene skeleton can be preferably used. Thus, a light-emitting device with high emission efficiency and high durability can be achieved.

Among the organic compounds having an anthracene skeleton, an organic compound having a diphenylanthracene skeleton, in particular, a substance having a 9,10-diphenylanthracene skeleton, is chemically stable and thus is preferably used. The host material preferably has a carbazole skeleton because the hole-injection and hole-transport properties are improved. In particular, the host material preferably has a dibenzocarbazole skeleton because the HOMO level thereof is shallower than that of carbazole by approximately 0.1 eV so that holes enter the host material easily, the hole-transport property is improved, and the heat resistance is increased. Note that in terms of the hole-injection and hole-transport properties described above, instead of a carbazole skeleton, a benzofluorene skeleton or a dibenzofluorene skeleton may be used.

Thus, a substance having both a 9,10-diphenylanthracene skeleton and a carbazole skeleton, a substance having both a 9,10-diphenylanthracene skeleton and a benzocarbazole skeleton, or a substance having both a 9,10-diphenylanthracene skeleton and a dibenzocarbazole skeleton is preferably used as the host material.

Examples of the substances that can be used are 6-[3-(9,10-diphenyl-2-anthryl)phenyl]-benzo[b]naphtho[1,2-d]furan (abbreviation: 2mBnfPPA), 9-phenyl-10-{4-(9-phenyl-9H-fluoren-9-yl)biphenyl-4′-yl}anthracene (abbreviation: FLPPA), 9-(1-naphthyl)-10-[4-(2-naphthyl)phenyl]anthracene (abbreviation: αN-βNPAnth), 9-phenyl-3-[4-(10-phenyl-9-anthryl)phenyl]-9H-carbazole (abbreviation: PCzPA), 9-[4-(10-phenyl-9-anthracenyl)phenyl]-9H-carbazole (abbreviation: CzPA), 7-[4-(10-phenyl-9-anthryl)phenyl]-7H-dibenzo[c,g]carbazole (abbreviation: cgDBCzPA), 3-[4-(1-naphthyl)-phenyl]-9-phenyl-9H-carbazole (abbreviation: PCPN), and the like.

In particular, CzPA, cgDBCzPA, 2mBnfPPA, and PCzPA have excellent characteristics.

Note that this embodiment can be combined with any of the other embodiments in this specification as appropriate.

### Embodiment 2

In this embodiment, a structure of the light-emitting device 150 of one embodiment of the present invention is described with reference to FIGS. 1A to 1C.

### <Structure Example of Light-Emitting Device 150>

The light-emitting device 150 described in this embodiment includes the electrode 101, the electrode 102, and the unit 103. The electrode 102 includes a region overlapping with the electrode 101, and the unit 103 includes a region interposed between the electrode 101 and the electrode 102.

### <Structure Example of Unit 103>

The unit 103 has a single-layer structure or a stacked-layer structure. For example, the unit 103 includes the layer 111, the layer 112, and the layer 113 (see FIG. 1A).

The layer 112 includes a region interposed between the electrode 101 and the layer 111, and the layer 113 includes a region interposed between the electrode 102 and the layer 111.

For example, a layer selected from functional layers such as a light-emitting layer, a hole-transport layer, an electron-transport layer, a carrier-blocking layer, and the like can be used for the unit 103. A layer selected from functional layers such as a hole-injection layer, an electron-injection layer, an exciton-blocking layer, a charge-generation layer, and the like can also be used for the unit 103. For example, the structure described in Embodiment 1 can be used for the layer 111.

### <<Structure Example of Layer 112>>

For example, a hole-transport material can be used for the layer 112. The layer 112 can be referred to as a hole-transport layer. It is preferable for the layer 112 to use a material having a wider bandgap than the light-emitting material contained in the layer 111. Thus, transfer of energy from excitons generated in the layer 111 to the layer 112 can be suppressed.

### [Hole-Transport Material]

A material having a hole mobility of 1×10⁻⁶ cm²/Vs or higher can be suitably used for the hole-transport material.

For example, a hole-transport material capable of being used for the layer 111 can be used for the layer 112. Specifically, a hole-transport material capable of being used for a host material can be used for the layer 112.

### <<Structure Example of Layer 113>>

For example, a material having an electron-transport property, a material having an anthracene skeleton, a mixed material, or the like can be used for the layer 113. The layer 113 can be referred to as an electron-transport layer. A material having a wider bandgap than the light-emitting material contained in the layer 111 is preferably used for the layer 113. Thus, transfer of energy from excitons generated in the layer 111 to the layer 113 can be inhibited.

### [Electron-Transport Material]

For example, a metal complex or an organic compound having a π-electron deficient heteroaromatic ring skeleton can be used as the electron-transport material.

For example, an electron-transport material capable of being used for the layer 111 can be used for the layer 113. Specifically, an electron-transport material capable of being used as a host material can be used for the layer 113.

### [Material Having Anthracene Skeleton]

An organic compound having an anthracene skeleton can be used for the layer 113. In particular, an organic compound having both an anthracene skeleton and a heterocyclic skeleton can be preferably used.

For example, it is possible to use an organic compound having both an anthracene skeleton and a nitrogen-containing five-membered ring skeleton. Alternatively, it is possible to use an organic compound having both an anthracene skeleton and a nitrogen-containing five-membered ring skeleton where two heteroatoms are included in a ring. Specifically, it is preferable, as the heterocyclic skeleton, to use a pyrazole ring, an imidazole ring, an oxazole ring, a thiazole ring, or the like.

For example, it is possible to use an organic compound having both an anthracene skeleton and a nitrogen-containing six-membered ring skeleton. Alternatively, it is possible to use an organic compound having both an anthracene skeleton and a nitrogen-containing six-membered ring skeleton where two heteroatoms are included in a ring. Specifically, it is preferable, as the heterocyclic skeleton, to use a pyrazine ring, a pyrimidine ring, a pyridazine ring, or the like.

### [Structure Example of Mixed Material]

A material in which a plurality of kinds of substances are mixed can be used for the layer 113. Specifically, a mixed material which includes an alkali metal, an alkali metal compound, or an alkali metal complex and an electron-transport substance can be used for the layer 113. Note that the electron-transport material preferably has a HOMO level of −6.0 eV or higher.

The mixed material can be suitably used for the layer 113 in combination with a structure using a composite material for the layer 104. For example, a composite material of an acceptor substance and a hole-transport material can be used for the layer 104. Specifically, a composite material of an acceptor substance and a substance having a relatively deep HOMO level (HOMO1), which is from −5.7 eV to −5.4 eV, can be used for the layer 104 (see FIG. 1C). In particular, the mixed material can be suitably used for the layer 113 in combination with the structure using the composite material for the layer 104. This leads to an increase in the reliability of the light-emitting device.

Furthermore, a structure using a hole-transport material for the layer 112 can be suitably combined with the structure using the mixed material for the layer 113 and the composite material for the layer 104. For example, a substance having a HOMO level (HOMO2), which is within the range of −0.2 eV to 0 eV, inclusive, from the above-described relatively deep HOMO level (HOMO1), can be used for the layer 112 (see FIG. 1C). This leads to an increase in the reliability of the light-emitting device.

The concentration of the alkali metal, the alkali metal compound, or the alkali metal complex preferably differs in the thickness direction of the layer 113 (including the case where the concentration is 0).

For example, a metal complex having a 8-hydroxyquinolinato structure can be used. A methyl-substituted product of the metal complex having a 8-hydroxyquinolinato structure (e.g., a 2-methyl-substituted product or a 5-methyl-substituted product) or the like can also be used.

As a metal complex having a 8-hydroxyquinolinato structure, 8-hydroxyquinolinato-lithium (abbreviation: Liq), 8-hydroxyquinolinato-sodium (abbreviation: Naq), or the like can be used. In particular, a complex of a monovalent metal ion, especially a complex of lithium is preferable, and Liq is further preferable.

Note that this embodiment can be combined with any of the other embodiments in this specification as appropriate.

### Embodiment 3

In this embodiment, a structure of the light-emitting device 150 of one embodiment of the present invention is described with reference to FIGS. 1A to 1C.

### <Structure Example of Light-Emitting Device 150>

The light-emitting device 150 described in this embodiment includes the electrode 101, the electrode 102, the unit 103, and a layer 104. The electrode 102 includes a region overlapping with the electrode 101, and the unit 103 includes a region interposed between the electrode 101 and the electrode 102. The layer 104 includes a region interposed between the electrode 101 and the unit 103. For example, the structures described in Embodiments 1 and 2 can be used for the unit 103.

### <Structure Example of Electrode 101>

For example, a conductive material can be used for the electrode 101. Specifically, a metal, an alloy, a conductive compound, and a mixture of these, or the like can be used for the electrode 101. For example, a material having a work function higher than or equal to 4.0 eV can be suitably used.

For example, indium oxide-tin oxide (ITO: indium tin oxide), indium oxide-tin oxide containing silicon or silicon oxide (ITSO), indium oxide-zinc oxide, indium oxide containing tungsten oxide and zinc oxide (IWZO), or the like can be used.

Furthermore, for example, gold (Au), platinum (Pt), nickel (Ni), tungsten (W), chromium (Cr), molybdenum (Mo), iron (Fe), cobalt (Co), copper (Cu), palladium (Pd), a nitride of a metal material (e.g., titanium nitride), or the like can be used. Graphene can also be used.

### <<Structure Example of Layer 104>>

For example, a material having a hole-injection property (also referred to as a hole-injection material) can be used for the layer 104. Note that the layer 104 can be referred to as a hole-injection layer.

Specifically, an acceptor substance can be used for the layer 104. Alternatively, a material in which an acceptor substance and a hole-transport material are combined can be used for the layer 104. This can facilitate the injection of holes from the electrode 101, for example. In addition, the driving voltage of the light-emitting device can be reduced.

### [Acceptor Substance]

An organic compound or an inorganic compound can be used as the acceptor substance. The acceptor substance can extract electrons from an adjacent hole-transport layer or a hole-transport material by the application of an electric field.

For example, a compound having an electron-withdrawing group (a halogen or cyano group) can be used as the acceptor substance. Note that an organic compound having an acceptor property is easily evaporated, which facilitates film deposition. Thus, the productivity of the light-emitting device can be increased.

Specific examples include 7,7,8,8-tetracyano-2,3,5,6-tetrafluoroquinodimethane (abbreviation: F₄-TCNQ), chloranil, 2,3,6,7,10,11-hexacyano-1,4,5,8,9,12-hexaazatriphenylene (abbreviation: HAT-CN), 1,3,4,5,7,8-hexafluorotetracyano-naphthoquinodimethane (abbreviation: F6-TCNNQ), and 2-(7-dicyanomethylene-1,3,4,5,6,8,9,10-octafluoro-7H-pyren-2-ylidene)malononitrile.

A compound in which electron-withdrawing groups are bonded to a condensed aromatic ring having a plurality of heteroatoms, such as HAT-CN, is particularly preferable because it is thermally stable.

A [3]radialene derivative having an electron-withdrawing group (in particular, a cyano group or a halogen group such as a fluoro group) has a very high electron-accepting property and thus is preferred.

Specific examples include α,α′,α″-1,2,3-cyclopropanetriylidenetris[4-cyano-2,3,5,6-tetrafluorobenzeneacetonitrile], α,α′,α″-1,2,3-cyclopropanetriylidenetris[2,6-dichloro-3,5-difluoro-4-(trifluoromethyl)benzeneacetonitrile], and α,α′,α″-1,2,3-cyclopropanetriylidenetris[2,3,4,5,6-pentafluorobenzeneacetonitrile].

A molybdenum oxide, a vanadium oxide, a ruthenium oxide, a tungsten oxide, manganese oxide, or the like can be used as the acceptor substance.

It is possible to use any of the following materials: phthalocyanine-based complex compounds such as phthalocyanine (abbreviation: H₂Pc) and copper phthalocyanine (abbreviation: CuPc); aromatic amine compounds such as 4,4′-bis[N-(4-diphenylaminophenyl)-N-phenylamino]biphenyl (abbreviation: DPAB) and N,N′-bis{4-[bis(3-methylphenyl)amino]phenyl}-N,N′-diphenyl-(1,1′-biphenyl)-4,4′-diamine (abbreviation: DNTPD); and the like.

In addition, high molecular compounds such as poly(3,4-ethylenedioxythiophene)/poly(styrenesulfonic acid) (abbreviation: PEDOT/PSS), and the like can be used.

### [Structure Example 1 of Composite Material]

A material composed of two or more kinds of substances can be used for the hole-injection material. For example, an acceptor substance and a hole-transport material can be used for the composite material. Accordingly, not only a material having a high work function but also a material having a low work function can also be used for the electrode 101. Alternatively, a material used for the electrode 101 can be selected from a wide range of materials regardless of its work function.

For the hole-transport material in the composite material, for example, a compound having an aromatic amine skeleton, a carbazole derivative, an aromatic hydrocarbon, a high molecular compound (such as an oligomer, a dendrimer, or a polymer), or the like can be used. A material having a hole mobility of 1×10⁻⁶ cm²/Vs or higher can be suitably used as the hole-transport material in the composite material.

A substance having a relatively deep HOMO level can be suitably used for the hole-transport material in the composite material. Specifically, the HOMO level is preferably higher than or equal to −5.7 eV and lower than or equal to −5.4 eV. Accordingly, hole injection to the unit 103 can be facilitated. Hole injection to the layer 112 can be facilitated. The reliability of the light-emitting device can be increased.

Examples of the compounds having an aromatic amine skeleton include N,N′-di(p-tolyl)-N,N′-diphenyl-p-phenylenediamine (abbreviation: DTDPPA), 4,4′-bis[N-(4-diphenylaminophenyl)-N-phenylamino]biphenyl (abbreviation: DPAB), N,N′-bis{4-[bis(3-methylphenyl)amino]phenyl}-N,N′-diphenyl-(1,1′-biphenyl)-4,4′-diamine (abbreviation: DNTPD), and 1,3,5-tris[N-(4-diphenylaminophenyl)-N-phenylamino]benzene (abbreviation: DPA3B).

Specific examples of the carbazole derivative include 3-[N-(9-phenylcarbazol-3-yl)-N-phenylamino]-9-phenylcarbazole (abbreviation: PCzPCA1), 3,6-bis[N-(9-phenylcarbazol-3-yl)-N-phenylamino]-9-phenylcarbazole (abbreviation: PCzPCA2), 3-[N-(1-naphthyl)-N-(9-phenylcarbazol-3-yl)amino]-9-phenylcarbazole (abbreviation: PCzPCN1), 4,4′-di(N-carbazolyl)biphenyl (abbreviation: CBP), 1,3,5-tris[4-(N-carbazolyl)phenyl]benzene (abbreviation: TCPB), 9-[4-(10-phenyl-9-anthracenyl)phenyl]-9H-carbazole (abbreviation: CzPA), and 1,4-bis[4-(N-carbazolyl)phenyl]-2,3,5,6-tetraphenylbenzene.

Examples of the aromatic hydrocarbon include 2-tert-butyl-9,10-di(2-naphthyl)anthracene (abbreviation: t-BuDNA), 2-tert-butyl-9,10-di(1-naphthyl)anthracene, 9,10-bis(3,5-diphenylphenyl)anthracene (abbreviation: DPPA), 2-tert-butyl-9,10-bis(4-phenylphenyl)anthracene (abbreviation: t-BuDBA), 9,10-di(2-naphthyl)anthracene (abbreviation: DNA), 9,10-diphenylanthracene (abbreviation: DPAnth), 2-tert-butylanthracene (abbreviation: t-BuAnth), 9,10-bis(4-methyl-1-naphthyl)anthracene (abbreviation: DMNA), 2-tert-butyl-9,10-bis[2-(1-naphthyl)phenyl]anthracene, 9,10-bis[2-(1-naphthyl)phenyl]anthracene, 2,3,6,7-tetramethyl-9,10-di(1-naphthyl)anthracene, 2,3,6,7-tetramethyl-9,10-di(2-naphthyl)anthracene, 9,9′-bianthryl, 10,10′-diphenyl-9,9′-bianthryl, 10,10′-bis(2-phenylphenyl)-9,9′-bianthryl, 10,10′-bis[(2,3,4,5,6-pentaphenyl)phenyl]-9,9′-bianthryl, anthracene, tetracene, rubrene, perylene, 2,5,8,11-tetra(tert-butyl)perylene, pentacene, and coronene.

As aromatic hydrocarbon having a vinyl skeleton, the following can be given for example: 4,4′-bis(2,2-diphenylvinyl)biphenyl (abbreviation: DPVBi), 9,10-bis[4-(2,2-diphenylvinyl)phenyl]anthracene (abbreviation: DPVPA), and the like.

As the high molecular compound, poly(N-vinylcarbazole) (abbreviation: PVK), poly(4-vinyltriphenylamine) (abbreviation: PVTPA), poly[N-(4-{N′-[4-(4-diphenylamino)phenyl]phenyl-N′-phenylamino}phenyl)methacrylamide] (abbreviation: PTPDMA), poly[N,N′-bis(4-butylphenyl)-N,N′-bis(phenyl)benzidine] (abbreviation: Poly-TPD), or the like can be used.

Furthermore, a substance having any of a carbazole derivative, a dibenzofuran skeleton, a dibenzothiophene skeleton, or an anthracene skeleton can be suitably used as the hole-transport material in the composite material, for example. Moreover, a substance including any of the following can be used as the hole-transport material in the composite material: an aromatic amine having a substituent that includes a dibenzofuran ring or a dibenzothiophene ring, an aromatic monoamine that includes a naphthalene ring, and an aromatic monoamine in which a 9-fluorenyl group is bonded to nitrogen of amine through an arylene group. With use of a substance including a N,N-bis(4-biphenyl)amino group, the reliability of the light-emitting device can be increased.

Specific examples of the hole-transport material in the composite material include N-(4-biphenyl)-6,N-diphenylbenzo[b]naphtho[1,2-d]furan-8-amine (abbreviation: BnfABP), N,N-bis(4-biphenyl)-6-phenylbenzo[b]naphtho[1,2-d]furan-8-amine (abbreviation: BBABnf), 4,4′-bis(6-phenylbenzo[b]naphtho[1,2-d]furan-8-yl)-4″-phenyltriphenylamine (abbreviation: BnfBB1BP), N,N-bis(4-biphenyl)benzo[b]naphtho[1,2-d]furan-6-amine (abbreviation: BBABnf(6)), N,N-bis(4-biphenyl)benzo[b]naphtho[1,2-d]furan-8-amine (abbreviation: BBABnf(8)), N,N-bis(4-biphenyl)benzo[b]naphtho[2,3-d]furan-4-amine (abbreviation: BBABnf(II) (4)), N,N-bis[4-(dibenzofuran-4-yl)phenyl]-4-amino-p-terphenyl (abbreviation: DBfBB1TP), N-[4-(dibenzothiophen-4-yl)phenyl]-N-phenyl-4-biphenylamine (abbreviation: ThBA1BP), 4-(2-naphthyl)-4′, 4″-diphenyltriphenylamine (abbreviation: BBAβNB), 4-[4-(2-naphthyl)phenyl]-4′,4″-diphenyltriphenylamine (abbreviation: BBAβNBi), 4,4′-diphenyl-4″-(6;1′-binaphthyl-2-yl)triphenylamine (abbreviation: BBAαNβNB), 4,4′-diphenyl-4″-(7;1′-binaphthyl-2-yl)triphenylamine (abbreviation: BBAαNβNB-03), 4,4′-diphenyl-4″-(7-phenyl)naphthyl-2-yltriphenylamine (abbreviation: BBAPβNB-03), 4,4′-diphenyl-4″-(6;2′-binaphthyl-2-yl)triphenylamine (abbreviation: BBA(βN2)B), 4,4′-diphenyl-4″-(7;2′-binaphthyl-2-yl)triphenylamine (abbreviation: BBA(βN2)B-03), 4,4′-diphenyl-4″-(4;2′-binaphthyl-1-yl)triphenylamine (abbreviation: BBAβNαNB), 4,4′-diphenyl-4″-(5;2′-binaphthyl-1-yl)triphenylamine (abbreviation: BBAβNαNB-02), 4-(4-biphenylyl)-4′-(2-naphthyl)-4″-phenyltriphenylamine (abbreviation: TPBiAβNB), 4-(3-biphenylyl)-4′-[4-(2-naphthyl)phenyl]-4″-phenyltriphenylamine (abbreviation: mTPBiAβNBi), 4-(4-biphenylyl)-4′-[4-(2-naphthyl)phenyl]-4″-phenyltriphenylamine (abbreviation: TPBiAβNBi), 4-phenyl-4′-(1-naphthyl)triphenylamine (abbreviation: αNBA1BP), 4,4′-bis(1-naphthyl)triphenylamine (abbreviation: αNBB1BP), 4,4′-diphenyl-4″-[4′-(carbazol-9-yl)biphenyl-4-yl]triphenylamine (abbreviation: YGTBi1BP), 4′-[4-(3-phenyl-9H-carbazol-9-yl)phenyl]tris(1,1′-biphenyl-4-yl)amine (abbreviation: YGTBi1BP-02), 4-diphenyl-4′-(2-naphthyl)-4″-{9-(4-biphenyl)carbazole}triphenylamine (abbreviation: YGTBiβNB), N-[4-(9-phenyl-9H-carbazol-3-yl)phenyl]-N-[4-(1-naphthyl)phenyl]-9,9′-spirobi[9H-fluoren]-2-amine (abbreviation: PCBNBSF), N,N-bis(4-biphenylyl)-9,9′-spirobi[9H-fluoren]-2-amine (abbreviation: BBASF), NN-bis([1,1′-biphenyl]-4-yl)-9,9′-spirobi[9H-fluoren]-4-amine (abbreviation: BBASF(4)), N-(1,1′-biphenyl-2-yl)-N-(9,9-dimethyl-9H-fluoren-2-yl)-9,9′-spirobi(9H-fluoren)-4-amine (abbreviation: oFBiSF), N-(4-biphenyl)-N-(dibenzofuran-4-yl)-9,9-dimethyl-9H-fluoren-2-amine (abbreviation: FrBiF), N-[4-(1-naphthyl)phenyl]-N-[3-(6-phenyldibenzofuran-4-yl)phenyl]-1-naphthylamine (abbreviation: mPDBfBNBN), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-[4-(9-phenylfluoren-9-yl)phenyl]triphenylamine (abbreviation: BPAFLBi), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), N-phenyl-N-[4-(9-phenyl-9H-carbazol-3-yl)phenyl]spiro-9,9′-bifluoren-2-amine (abbreviation: PCBASF), N-(1,1′-biphenyl-4-yl)-N-[4-(9-phenyl-9H-carbazol-3-yl)phenyl]-9,9-dimethyl-9H-fluoren-2-amine (abbreviation: PCBBiF), N,N-bis(9,9-dimethyl-9H-fluoren-2-yl)-9,9′-spirobi-9H-fluoren-4-amine, N,N-bis(9,9-dimethyl-9H-fluoren-2-yl)-9,9′-spirobi-9H-fluoren-3-amine, N,N-bis(9,9-dimethyl-9H-fluoren-2-yl)-9,9′-spirobi-9H-fluoren-2-amine, and N,N-bis(9,9-dimethyl-9H-fluoren-2-yl)-9,9′-spirobi-9H-fluoren-1-amine.

### [Structure Example 2 of Composite Material]

For example, a composite material including an acceptor substance, a hole-transport material, and a fluoride of an alkali metal or a fluoride of an alkaline earth metal can be used for the hole-injection material. In particular, a composite material in which the proportion of fluorine atoms is higher than or equal to 20% can be suitably used. Thus, the refractive index of the layer 104 can be reduced. A layer with a low refractive index can be formed inside the light-emitting device. The external quantum efficiency of the light-emitting device can be improved.

Note that this embodiment can be combined with any of the other embodiments in this specification as appropriate.

### Embodiment 4

In this embodiment, a structure of the light-emitting device 150 of one embodiment of the present invention is described with reference to FIGS. 1A to 1C.

### <Structure Example of Light-Emitting Device 150>

The light-emitting device 150 described in this embodiment includes the electrode 101, the electrode 102, the unit 103, and a layer 105. The electrode 102 includes a region overlapping with the electrode 101, and the unit 103 includes a region interposed between the electrode 101 and the electrode 102. The layer 105 includes a region interposed between the unit 103 and the electrode 102. For example, the structure described in any of Embodiments 1 to 3 can be used for the unit 103.

### <Structure Example of Electrode 102>

For example, a conductive material can be used for the electrode 102. Specifically, a metal, an alloy, an electrically conductive compound, a mixture of these, or the like can be used for the electrode 102. For example, a material with a lower work function than the electrode 101 can be suitably used for the electrode 102. Specifically, a material having a work function lower than or equal to 3.8 eV is preferably used.

For example, an element belonging to Group 1 of the periodic table, an element belonging to Group 2 of the periodic table, a rare earth metal, or an alloy containing any of these elements can be used for the electrode 102.

Specifically, an element such as lithium (Li) or cesium (Cs), an element such as magnesium (Mg), calcium (Ca), or strontium (Sr), a metal such as europium (Eu) or ytterbium (Yb), or the like or an alloy containing any of these elements such as MgAg or AlLi can be used for the electrode 102.

### <<Structure Example of Layer 105>>

For example, a material having an electron-injection property (also referred to as an electron-injection material) can be used for the layer 105. The layer 105 can also be referred to as an electron-injection layer.

Specifically, a donor substance can be used for the layer 105. Alternatively, a material in which a donor substance and an electron-transport material are combined can be used for the layer 105. Alternatively, electride can be used for the layer 105. This can facilitate the injection of electrons from the electrode 102, for example. Accordingly, not only a material having a low work function but also a material having a high work function can also be used for the electrode 102. Alternatively, a material used for the electrode 102 can be selected from a wide range of materials regardless of its work function. Specifically, Al, Ag, ITO, indium oxide-tin oxide containing silicon or silicon oxide, and the like can be used for the electrode 102. In addition, the driving voltage of the light-emitting device can be reduced.

### [Donor Substance]

For example, an alkali metal, an alkaline earth metal, a rare earth metal, or a compound thereof (an oxide, a halide, a carbonate, or the like) can be used for the donor substance. Alternatively, an organic compound such as tetrathianaphthacene (abbreviation: TTN), nickelocene, or decamethylnickelocene can be used as the donor substance.

As an alkali metal compound (including an oxide, a halide, and a carbonate), lithium oxide, lithium fluoride (LiF), cesium fluoride (CsF), lithium carbonate, cesium carbonate, 8-hydroxyquinolinato-lithium (abbreviation: Liq), or the like can be used.

As an alkaline earth metal compound (including an oxide, a halide, and a carbonate), calcium fluoride (CaF₂) or the like can be used.

### [Structure Example of Composite Material]

A material composed of two or more kinds of substances can be used for the electron-injection material. For example, a donor substance and an electron-transport material can be used for the composite material. For example, an electron-transport material capable of being used for the unit 103 can be used as the composite material.

A material including a fluoride of an alkali metal in a microcrystalline state and an electron-transport material can be used for the composite material. Alternatively, a material including a fluoride of an alkaline earth metal in a microcrystalline state and an electron-transport material can be used for the composite material. In particular, a composite material including a fluoride of an alkali metal or an alkaline earth metal at 50 wt % or higher can be suitably used. Alternatively, a composite material including an organic compound having a bipyridine skeleton can be suitably used. Thus, the refractive index of the layer 104 can be reduced. The external quantum efficiency of the light-emitting device can be improved.

### [Electride]

For example, a substance obtained by adding electrons at high concentration to an oxide where calcium and aluminum are mixed can be used, for example, for the electron-injection material.

Note that this embodiment can be combined with any of the other embodiments in this specification as appropriate.

### Embodiment 5

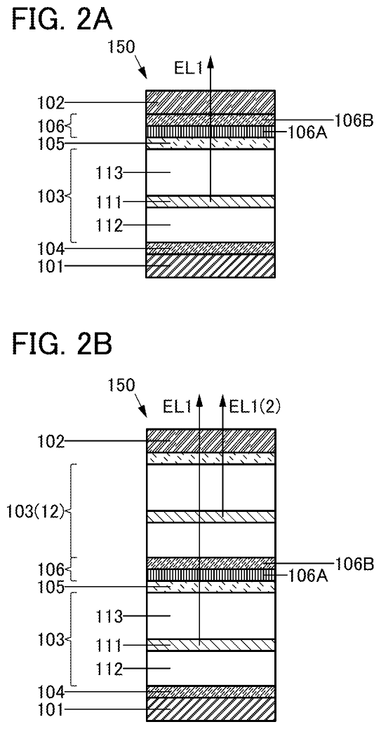

In this embodiment, a structure of the light-emitting device 150 of one embodiment of the present invention is described with reference to FIG. 2A.

FIG. 2A is a cross-sectional view illustrating a structure of a light-emitting device of one embodiment of the present invention.

### <Structure Example of Light-Emitting Device 150>

The light-emitting device 150 described in this embodiment includes the electrode 101, the electrode 102, the unit 103, and an intermediate layer 106 (see FIG. 2A). The electrode 102 includes a region overlapping with the electrode 101, and the unit 103 includes a region interposed between the electrode 101 and the electrode 102. The intermediate layer 106 includes a region interposed between the unit 103 and the electrode 102.

### <<Structure Example of Intermediate Layer 106>>

The intermediate layer 106 includes a layer 106A and a layer 106B. The layer 106B includes a region interposed between the layer 106A and the electrode 102.

### <<Structure Example of Layer 106A>>

For example, an electron-transport material can be used for the layer 106A. The layer 106A can be referred to as an electron-relay layer. With the layer 106A, a layer that is on the anode side and in contact with the layer 106A can be distanced from a layer that is on the cathode side and in contact with the layer 106A. Interaction between the layer that is on the anode side and in contact with the layer 106A and the layer that is on the cathode side and in contact with the layer 106A can be reduced. Electrons can be smoothly supplied to the layer that is on the anode side and in contact with the layer 106A.

A substance whose LUMO level is positioned between the LUMO level of the acceptor substance included in the layer that is on the anode side and in contact with the layer 106A and the LUMO level of the substance included in the layer that is on the cathode side and in contact with the layer 106A can be suitably used for the layer 106A.

For example, a material having a LUMO level in a range higher than or equal to −5.0 eV, preferably higher than or equal to −5.0 eV and lower than or equal to −3.0 eV, can be used as the layer 106A.

Specifically, a phthalocyanine-based material can be used for the layer 106A. In addition, a metal complex having a metal-oxygen bond and an aromatic ligand can be used for the layer 106A.

### <<Structure Example of Layer 106B>>

For example, a material that supplies electrons to the anode side and supplies holes to the cathode side when voltage is applied can be used for the layer 106B. Specifically, electrons can be supplied to the unit 103 that is positioned on the anode side. The layer 106B can be referred to as a charge-generation layer.

Specifically, a hole-injection material capable of being used for the layer 104 can be used for the layer 106B. For example, a composite material can be used for the layer 106B. Alternatively, for example, a stacked film in which a film including the composite material and a film including a hole-transport material are stacked can be used for the layer 106B.

Note that this embodiment can be combined with any of the other embodiments in this specification as appropriate.

### Embodiment 6

In this embodiment, a structure of the light-emitting device 150 of one embodiment of the present invention is described with reference to FIG. 2B.

FIG. 2B is a cross-sectional view illustrating a structure of a light-emitting device of one embodiment of the present invention, which is different from that in FIG. 2A.

### <Structure Example of Light-Emitting Device 150>

The light-emitting device 150 described in this embodiment includes the electrode 101, the electrode 102, the unit 103, the intermediate layer 106, and a unit 103(12) (see FIG. 2B). The electrode 102 includes the region overlapping with the electrode 101, the unit 103 includes the region interposed between the electrode 101 and the electrode 102, and the intermediate layer 106 includes the region interposed between the unit 103 and the electrode 102. The unit 103(12) includes a region interposed between the intermediate layer 106 and the electrode 102, and the unit 103(12) has a function of emitting light EL1(2).

A structure including the intermediate layer 106 and a plurality of units is referred to as a stacked light-emitting device or tandem light-emitting device in some cases. This structure enables high luminance emission while the current density is kept low. Reliability can be improved. The driving voltage can be reduced in comparison with that of the light-emitting device with the same luminance. The power consumption can be reduced.

### <<Structure Example of Unit 103(12)>>

The structure that can be used for the unit 103 can also be employed for the unit 103(12). In other words, the light-emitting device 150 includes a plurality of units that are stacked. Note that the number of stacked units is not limited to two and may be three or more.

The same structure as the unit 103 can be used for the unit 103(12). Alternatively, a structure different from the unit 103 can be used for the unit 103(12).

For example, a structure which exhibits a different emission color from that of the unit 103 can be employed for the unit 103(12). Specifically, the unit 103 emitting red light and green light and the unit 103(12) emitting blue light can be employed. With this structure, a light-emitting device emitting light of a desired color can be provided. A light-emitting device emitting white light can be provided, for example.

### <<Structure Example of Intermediate Layer 106>>

The intermediate layer 106 has a function of supplying electrons to one of the unit 103 and the unit 103(12) and supplying holes to the other. For example, the intermediate layer 106 described in Embodiment 5 can be used.

### <Fabrication Method of Light-Emitting Device 150>

For example, each of the electrode 101, the electrode 102, the unit 103, the intermediate layer 106, and the unit 103(12) can be formed by a dry process, a wet process, an evaporation method, a droplet discharging method, a coating method, a printing method, or the like. A formation method may differ between components of the device.

Specifically, the light-emitting device 150 can be manufactured with a vacuum evaporation machine, an ink-jet machine, a coating machine such as a spin coater, a gravure printing machine, an offset printing machine, a screen printing machine, or the like.

For example, the electrode can be formed by a wet process or a sol-gel method using a paste of a metal material. Specifically, an indium oxide-zinc oxide film can be formed by a sputtering method using a target obtained by adding indium zinc to indium oxide at a concentration higher than or equal to 1 wt % and lower than or equal to 20 wt %. Furthermore, an indium oxide film containing tungsten oxide and zinc oxide (IWZO) can be formed by a sputtering method using a target containing, with respect to indium oxide, tungsten oxide at a concentration higher than or equal to 0.5 wt % and lower than or equal to 5 wt % and zinc oxide at a concentration higher than or equal to 0.1 wt % and lower than or equal to 1 wt %.

Note that this embodiment can be combined with any of the other embodiments in this specification as appropriate.

### Embodiment 7

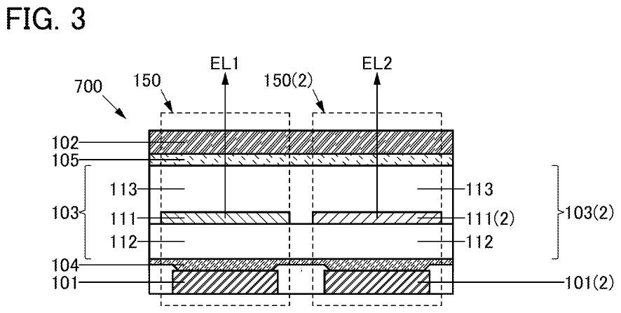

In this embodiment, a structure of a light-emitting panel 700 of one embodiment of the present invention will be described with reference to FIG. 3.

### <Structure Example of Light-Emitting Panel 700>

The light-emitting panel 700 described in this embodiment includes a light-emitting device 150 and a light-emitting device 150(2) (FIG. 3).

For example, the light-emitting device described in any one of Embodiments 1 to 6 can be used for the light-emitting device 150.

### <Structure Example of Light-Emitting Device 150(2)>

The light-emitting device 150(2) described in this embodiment includes an electrode 101(2), the electrode 102, and a unit 103(2) (see FIG. 3). The electrode 102 includes a region overlapping with the electrode 101(2). Note that a component of the light-emitting device 150 can be used as a component of the light-emitting device 150(2). Thus, the components can be common. The fabrication process can be simplified.

### <<Structure Example of Unit 103(2)>>

The unit 103(2) includes a region interposed between the electrode 101(2) and the electrode 102. The unit 103(2) includes a layer 111(2).

The unit 103(2) have a single-layer structure or a stacked-layer structure. For example, the unit 103(2) can include a layer selected from functional layers such as a hole-transport layer, an electron-transport layer, a carrier-blocking layer, and an exciton-blocking layer.

The unit 103(2) includes a region where electrons injected from one of the electrodes recombine with holes injected from the other electrode. For example, a region where holes injected from the electrode 101(2) recombine with electrons injected from the electrode 102 is provided.

### <<Structure Example 1 of Layer 111(2)>>

The layer 111(2) includes a light-emitting material and a host material. The layer 111(2) can be referred to as a light-emitting layer. The layer 111(2) is preferably provided in a region where holes and electrons recombine. Thus, energy generated by the recombination of carriers is efficiently converted into light and emitted. Further, the layer 111(2) is preferably provided to be distanced from a metal used for the electrode or the like. Thus, a quenching phenomenon caused by the metal used for the electrode or the like can be inhibited.

For example, a light-emitting material different from the light-emitting material used for the layer 111 can be used for the layer 111(2). Specifically, a light-emitting material, whose emission color is different from the emission color of the light-emitting material used for the layer 111, can be used for the layer 111(2). Thus, light-emitting devices with different hues can be provided. A plurality of light-emitting devices with different hues can be used to perform additive color mixing. Alternatively, it is possible to express a color of a hue that an individual light-emitting device cannot display.

For example, a light-emitting device that emits blue light, a light-emitting device that emits green light, and a light-emitting device that emits red light can be provided in the light-emitting panel 700. Alternatively, a light-emitting device that emits white light, a light-emitting device that emits yellow light, and a light-emitting device that emits infrared rays can be provided in the light-emitting panel 700.

### <<Structure Example 2 of Layer 111(2)>>

For example, a light-emitting material or a light-emitting material and a host material can be used for the layer 111(2). The layer 111(2) can be referred to as a light-emitting layer. The layer 111(2) is preferably provided in a region where holes and electrons recombine. Thus, energy generated by the recombination of carriers is efficiently converted into light and emitted. Further, the layer 111(2) is preferably provided to be distanced from a metal used for the electrode or the like. Thus, a quenching phenomenon caused by the metal used for the electrode or the like can be inhibited.

For example, a fluorescent substance, a phosphorescent substance, or a substance exhibiting thermally activated delayed fluorescence (TADF) (also referred to as a TADF material) can be used for the light-emitting material. Thus, energy generated by recombination of carriers can be released as light EL2 from the light-emitting material (see FIG. 3).

### [Fluorescent Substance]

A fluorescent substance can be used as the layer 111(2). For example, the following fluorescent substances can be used for the layer 111(2). Note that the fluorescent substance that can be used for the layer 111(2) is not limited to the following, but a variety of known fluorescent substances can be used.

Specific examples include 5,6-bis[4-(10-phenyl-9-anthryl)phenyl]-2,2′-bipyridine (abbreviation: PAP2BPy), 5,6-bis[4′-(10-phenyl-9-anthryl)biphenyl-4-yl]-2,2′-bipyridine (abbreviation: PAPP2BPy), N,N′-diphenyl-N,N′-bis[4-(9-phenyl-9H-fluoren-9-yl)phenyl]pyrene-1,6-diamine (abbreviation: 1,6FLPAPrn), N,N′-bis(3-methylphenyl)-N,N′-bis[3-(9-phenyl-9H-fluoren-9-yl)phenyl]pyrene-1,6-diamine (abbreviation: 1,6mMemFLPAPrn), N,N′-bis[4-(9H-carbazol-9-yl)phenyl]-N,N′-diphenylstilbene-4,4′-diamine (abbreviation: YGA2S), 4-(9H-carbazol-9-yl)-4′-(10-phenyl-9-anthryl)triphenylamine (abbreviation: YGAPA), 4-(9H-carbazol-9-yl)-4′-(9,10-diphenyl-2-anthryl)triphenylamine (abbreviation: 2YGAPPA), N,9-diphenyl-N-[4-(10-phenyl-9-anthryl)phenyl]-9H-carbazol-3-amine (abbreviation: PCAPA), perylene, 2,5,8,11-tetra(tert-butyl)perylene (abbreviation: TBP), 4-(10-phenyl-9-anthryl)-4′-(9-phenyl-9H-carbazol-3-yl)triphenylamine (abbreviation: PCBAPA), N,N″-(2-tert-butylanthracene-9,10-diyldi-4,1-phenylene)bis[N,N′,N′-triphenyl-1,4-phenylenediamine](abbreviation: DPABPA), N,9-diphenyl-N-[4-(9,10-diphenyl-2-anthryl)phenyl]-9H-carbazol-3-amine (abbreviation: 2PCAPPA), N-[4-(9,10-diphenyl-2-anthryl)phenyl]-N,N′,N′-triphenyl-1,4-phenylenediamine (abbreviation: 2DPAPPA), N,N,N′,N′,N″,N″,N′″,N′″-octaphenyldibenzo[g,p]chrysene-2,7,10,15-tetraamine (abbreviation: DBC1), coumarin 30, N-(9,10-diphenyl-2-anthryl)-N,9-diphenyl-9H-carbazol-3-amine (abbreviation: 2PCAPA), N-[9,10-bis(1,1′-biphenyl-2-yl)-2-anthryl]-N,9-diphenyl-9H-carbazol-3-amine (abbreviation: 2PCABPhA), N-(9,10-diphenyl-2-anthryl)-N,N,N-triphenyl-1,4-phenylenediamine (abbreviation: 2DPAPA), N-[9,10-bis(1,1′-biphenyl-2-yl)-2-anthryl]-N,N′,N′-triphenyl-1,4-phenylenediamine (abbreviation: 2DPABPhA), 9,10-bis(1,1′-biphenyl-2-yl)-N-[4-(9H-carbazol-9-yl)phenyl]-N-phenylanthracen-2-amine (abbreviation: 2YGABPhA), N,N,9-triphenylanthracen-9-amine (abbreviation: DPhAPhA), coumarin 545T, N,N′-diphenylquinacridone (abbreviation: DPQd), rubrene, 5,12-bis(1,1′-biphenyl-4-yl)-6,11-diphenyltetracene (abbreviation: BPT), 2-(2-{2-[4-(dimethylamino)phenyl]ethenyl}-6-methyl-4H-pyran-4-ylidene)propanedinitrile (abbreviation: DCM1), 2-{2-methyl-6-[2-(2,3,6,7-tetrahydro-1H,5H-benzo[ij]quinolizin-9-yl)ethenyl]-4H-pyran-4-ylidene}propanedinitrile (abbreviation: DCM2), N,N,N′,N′-tetrakis(4-methylphenyl)tetracene-5,11-diamine (abbreviation: p-mPhTD), 7,14-diphenyl-N,N,N′,N′-tetrakis(4-methylphenyl)acenaphtho[1,2-a]fluoranthene-3,10-diamine (abbreviation: p-mPhAFD), 2-{2-isopropyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTI), 2-{2-tert-butyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTB), 2-(2,6-bis{2-[4-(dimethylamino)phenyl]ethenyl}-4H-pyran-4-ylidene)propanedinitrile (abbreviation: BisDCM), 2-{2,6-bis[2-(8-methoxy-1,1,7,7-tetramethyl-2,3, 6,7-tetrahydro-1H,5H-benzo[ij]quinolizin-9-yl)ethenyl]-4H-pyran-4-ylidene}propanedinitrile (abbreviation: BisDCJTM), N,N′-(pyrene-diyl)bis[(6,N-diphenylbenzo[b]naphtho[1,2-d]furan)-8-amine] (abbreviation:1,6BnfAPrn-03), 3,10-bis[N-(9-phenyl-9H-carbazol-2-yl)-N-phenylamino]naphtho[2,3-b;6,7-b′]bisbenzofuran (abbreviation: 3,10PCA2Nbf(IV)-02), and 3,10-bis[N-(dibenzofuran-3-yl)-N-phenylamino]naphtho[2,3-b;6,7-b′]bisbenzofuran (abbreviation: 3,10FrA2Nbf(IV)-02).

In particular, a condensed aromatic diamine compound typified by a pyrenediamine compound such as 1,6FLPAPrn, 1,6mMemFLPAPrn, or 1,6BnfAPrn-03 is preferable because of their high hole-trapping properties, high emission efficiency, and high reliability.

### [Phosphorescent Substance]

A phosphorescent substance can also be used for the layer 111(2). For example, the following phosphorescent substances can be used for the layer 111(2). Note that the phosphorescent substance that can be used for the layer 111(2) is not limited to the following, but a variety of known phosphorescent substances can be used.

Any of the following can be used for the layer 111(2): an organometallic iridium complex having a 4H-triazole skeleton, an organometallic iridium complex having a 1H-triazole skeleton, an organometallic iridium complex having an imidazole skeleton, an organometallic iridium complex having a phenylpyridine derivative with an electron-withdrawing group as a ligand, an organometallic iridium complex having a pyrimidine skeleton, an organometallic iridium complex having a pyrazine skeleton, an organometallic iridium complex having a pyridine skeleton, a rare earth metal complex, a platinum complex, and the like.

### [Phosphorescent Substance (Blue)]

As an organometallic iridium complex having a 4H-triazole skeleton or the like, tris{2-[5-(2-methylphenyl)-4-(2,6-dimethylpyridin-3-yl)-4H-1,2,4-triazol-3-yl-κN²]phenyl-κC}iridium(III) (abbreviation: [Ir(mpptz-dmp)₃]), tris(5-methyl-3,4-diphenyl-4H-1,2,4-triazolato)iridium(III) (abbreviation: [Ir(Mptz)₃]), tris[4-(3-biphenyl)-5-isopropyl-3-phenyl-4H-1,2,4-triazolato]iridium(III) (abbreviation: [Ir(iPrptz-3b)₃]), or the like can be used.

As an organometallic iridium complex having a 1H-triazole skeleton or the like, tris[3-methyl-1-(2-methylphenyl)-5-phenyl-1H-1,2,4-triazolato]iridium(III) (abbreviation: [Ir(Mptz1-mp)₃]), tris(1-methyl-5-phenyl-3-propyl-1H-1,2,4-triazolato]iridium(III) (abbreviation: [Ir(Prptz1-Me)₃]), or the like can be used.

As an organometallic iridium complex having an imidazole skeleton or the like, fac-tris[1-(2,6-diisopropylphenyl)-2-phenyl-1H-imidazole]iridium(III) (abbreviation: [Ir(iPrpmi)₃]), tris[3-(2,6-dimethylphenyl)-7-methylimidazo[1,2-f]phenanthridinato]iridium(III) (abbreviation: [Ir(dmpimpt-Me)₃]), or the like can be used.

As an organometallic iridium complex having a phenylpyridine derivative with an electron-withdrawing group as a ligand, or the like, bis[2-(4′,6′-difluorophenyl)pyridinato-N,C^{2′}]iridium(III) tetrakis(1-pyrazolyl)borate (abbreviation: FIr6), bis[2-(4′,6′-difluorophenyl)pyridinato-N,C^{2′}]iridium(III) picolinate (abbreviation: FIrpic), bis{2-[3′,5′-bis(trifluoromethyl)phenyl]pyridinato-N,C^{2′}}iridium(III) picolinate (abbreviation: Ir(CF₃ppy)₂(pic)), bis[2-(4′,6′-difluorophenyl)pyridinato-N,C^{2′}]iridium(III) acetylacetonate (abbreviation: FIracac), or the like can be used.

These substances are compounds exhibiting blue phosphorescence and having an emission wavelength peak at 440 nm to 520 nm.

### [Phosphorescent Substance (Green)]

As an organometallic iridium complex having a pyrimidine skeleton or the like, tris(4-methyl-6-phenylpyrimidinato)iridium(III) (abbreviation: [Ir(mppm)₃]), tris(4-t-butyl-6-phenylpyrimidinato)iridium(III) (abbreviation: [Ir(tBuppm)₃]), (acetylacetonato)bis(6-methyl-4-phenylpyrimidinato)iridium(III) (abbreviation: [Ir(mppm)₂(acac)]), (acetylacetonato)bis(6-tert-butyl-4-phenylpyrimidinato)iridium(III) (abbreviation: [Ir(tBuppm)₂(acac)]), (acetylacetonato)bis[6-(2-norbornyl)-4-phenylpyrimidinato]iridium(III) (abbreviation: [Ir(nbppm)₂(acac)]), (acetylacetonato)bis[5-methyl-6-(2-methylphenyl)-4-phenylpyrimidinato]iridium(III) (abbreviation: [Ir(mpmppm)₂(acac)]), (acetylacetonato)bis(4,6-diphenylpyrimidinato)iridium(III) (abbreviation: [Ir(dppm)₂(acac)]), or the like can be used.

As an organometallic iridium complex having a pyrazine skeleton or the like, (acetylacetonato)bis(3,5-dimethyl-2-phenylpyrazinato)iridium(III) (abbreviation: [Ir(mppr-Me)₂(acac)]), (acetylacetonato)bis(5-isopropyl-3-methyl-2-phenylpyrazinato)iridium(III) (abbreviation: [Ir(mppr-iPr)₂(acac)]), or the like can be used.

As an organometallic iridium complex having a pyridine skeleton or the like, tris(2-phenylpyridinato-N,C^{2′})iridium(III) (abbreviation: [Ir(ppy)₃]), bis(2-phenylpyridinato-N,C^{2′})iridium(III) acetylacetonate (abbreviation: [Ir(ppy)₂(acac)]), bis(benzo[h]quinolinato)iridium(III) acetylacetonate (abbreviation: [Ir(bzq)₂(acac)]), tris(benzo[h]quinolinato)iridium(III) (abbreviation: [Ir(bzq)₃]), tris(2-phenylquinolinato-N,C^{2′})iridium(III) (abbreviation: [Ir(pq)₃]), bis(2-phenylquinolinato-N,C^{2′})iridium(III) acetylacetonate (abbreviation: [Ir(pq)₂(acac)]), [2-d3-methyl-8-(2-pyridinyl-κN)benzofuro[2,3-b]pyridine-κC]bis[2-(5-d3-methyl-2-pyridinyl-κN2)phenyl-κC]iridium(III) (abbreviation: [Ir(5mppy-d3)₂(mbfpypy-d3)]), [2-d3-methyl-(2-pyridinyl-κN)benzofuro[2,3-b]pyridine-κC]bis[2-(2-pyridinyl-κN)phenyl-κC]iridium(III) (abbreviation: [Ir(ppy)₂(mbfpypy-d3)]), or the like can be used.

Examples of a rare earth metal complex are tris(acetylacetonato) (monophenanthroline)terbium(III) (abbreviation: Tb(acac)₃(Phen)), and the like.

These are compounds that mainly exhibit green phosphorescence and have an emission wavelength peak at 500 nm to 600 nm. Note that an organometallic iridium complex having a pyrimidine skeleton has distinctively high reliability or emission efficiency.

### [Phosphorescent Substance (Red)]

As an organometallic iridium complex having a pyrimidine skeleton or the like, (diisobutyrylmethanato)bis[4,6-bis(3-methylphenyl)pyrimidinato]iridium(III) (abbreviation: Ir(5mdppm)₂(dibm)), bis[4,6-bis(3-methylphenyl)pyrimidinato](dipivaloylmethanato)iridium(III) (abbreviation: Ir(5mdppm)₂(dpm)), bis[4,6-di(naphthalen-1-yl)pyrimidinato](dipivaloylmethanato)iridium(III) (abbreviation: Ir(d1pm)₂(dpm)), or the like can be used.

As an organometallic iridium complex having a pyrazine skeleton or the like, (acetylacetonato)bis(2,3,5-triphenylpyrazinato)iridium(III) (abbreviation: [Ir(tppr)₂(acac)]), bis(2,3,5-triphenylpyrazinato)(dipivaloylmethanato)iridium(III) (abbreviation: Ir(tppr)₂(dpm)), (acetylacetonato)bis[2,3-bis(4-fluorophenyl)quinoxalinato]iridium(III) (abbreviation: [Ir(Fdpq)₂(acac)]), or the like can be used.

As an organometallic iridium complex having a pyridine skeleton or the like, tris(1-phenylisoquinolinato-N,C^{2′})iridium(III) (abbreviation: [Ir(piq)₃]), bis(1-phenylisoquinolinato-N,C^{2′})iridium(III) acetylacetonate (abbreviation: [Ir(piq)₂(acac)]), or the like can be used.

A rare earth metal complex or the like, tris(1,3-diphenyl-1,3-propanedionato) (monophenanthroline)europium(III) (abbreviation: Eu(DBM)₃(Phen)), tris[1-(2-thenoyl)-3,3,3-trifluoroacetonato] (monophenanthroline)europium(III) (abbreviation: Eu(TTA)₃(Phen)), or the like can be used.

As a platinum complex or the like, 2,3,7,8,12,13,17,18-octaethyl-21H,23H-porphyrin platinum(II) (abbreviation: PtOEP) or the like can be used.

These compounds emit red phosphorescence having an emission peak at 600 nm to 700 nm. Furthermore, the organometallic iridium complexes having a pyrazine skeleton can provide red light emission with chromaticity favorably used for display devices.

### [Substance Exhibiting Thermally Activated Delayed Fluorescence (TADF)]

A TADF material can be used for the layer 111(2). For example, any of the TADF materials given below can be used as the light-emitting material. Note that without being limited thereto, a variety of known TADF materials can be used as the light-emitting material.

In the TADF material, the difference between the S1 level and the T1 level is small, and reverse intersystem crossing (upconversion) from the triplet excited state into the singlet excited state can be achieved by a small amount of thermal energy. Thus, the singlet excited state can be efficiently generated from the triplet excited state. In addition, the triplet excitation energy can be converted into luminescence.

An exciplex whose excited state is formed of two kinds of substances has an extremely small difference between the S1 level and the T1 level and functions as a TADF material capable of converting triplet excitation energy into singlet excitation energy.

A phosphorescent spectrum observed at a low temperature (e.g., 77 K to 10 K) is used for an index of the T1 level. When the level of energy with a wavelength of the line obtained by extrapolating a tangent to the fluorescent spectrum at a tail on the shortest wavelength side is the S1 level and the level of energy with a wavelength of the line obtained by extrapolating a tangent to the phosphorescent spectrum at a tail on the shortest wavelength side is the T1 level, the difference between the S1 level and the T1 level of the TADF material is preferably smaller than or equal to 0.3 eV, further preferably smaller than or equal to 0.2 eV.

When a TADF material is used as the light-emitting substance, the S1 level of the host material is preferably higher than that of the TADF material. In addition, the T1 level of the host material is preferably higher than that of the TADF material.

Examples of the TADF material include a fullerene, a derivative thereof, an acridine, a derivative thereof, and an eosin derivative. Furthermore, porphyrin containing a metal such as magnesium (Mg), zinc (Zn), cadmium (Cd), tin (Sn), platinum (Pt), indium (In), or palladium (Pd) can be also used for the TADF material.

Specifically, the following materials whose structural formulae are shown below can be used: a protoporphyrin-tin fluoride complex (SnF₂(Proto IX)), a mesoporphyrin-tin fluoride complex (SnF₂(Meso IX)), a hematoporphyrin-tin fluoride complex (SnF₂(Hemato IX)), a coproporphyrin tetramethyl ester-tin fluoride complex (SnF₂(Copro III-4Me)), an octaethylporphyrin-tin fluoride complex (SnF₂(OEP)), an etioporphyrin-tin fluoride complex (SnF₂(Etio I)), an octaethylporphyrin-platinum chloride complex (PtCl₂OEP), or the like.

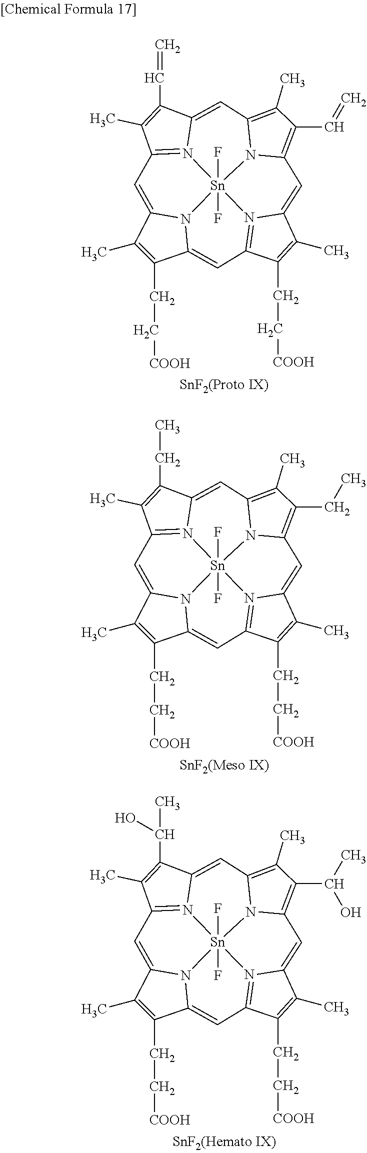

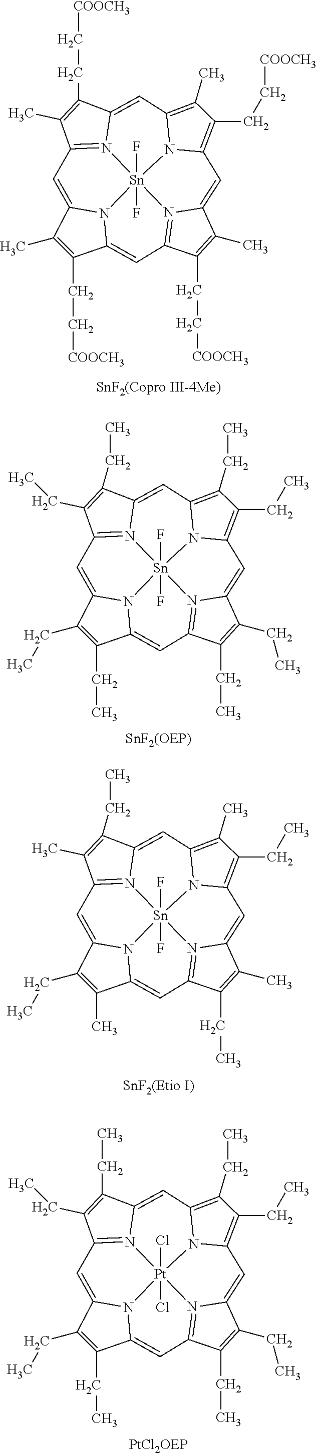

Furthermore, a heterocyclic compound including one or both of a π-electron rich heteroaromatic ring and a π-electron deficient heteroaromatic ring can be used, for example, for the TADF material.

Specifically, the following compounds whose structural formulae are shown below can be used: 2-(biphenyl-4-yl)-4,6-bis(12-phenylindolo[2,3-a]carbazol-11-yl)-1,3,5-triazine (abbreviation: PIC-TRZ), 9-(4,6-diphenyl-1,3,5-triazin-2-yl)-9′-phenyl-9H,9′H-3,3′-bicarbazole (abbreviation: PCCzTzn), 2-{4-[3-(N-phenyl-9H-carbazol-3-yl)-9H-carbazol-9-yl]phenyl}-4,6-diphenyl-1,3,5-triazine (abbreviation: PCCzPTzn), 2-[4-(10H-phenoxazine-10-yl)phenyl]-4,6-diphenyl-1,3,5-triazine (abbreviation: PXZ-TRZ), 3-[4-(5-phenyl-5,10-dihydrophenazin-10-yl)phenyl]-4,5-diphenyl-1,2,4-triazole (abbreviation: PPZ-3TPT), 3-(9,9-dimethyl-9H-acridin-10-yl)-9H-xanthen-9-one (abbreviation: ACRXTN), bis[4-(9,9-dimethyl-9,10-dihydroacridine)phenyl]sulfone (abbreviation: DMAC-DPS), 10-phenyl-10H,10′H-spiro[acridin-9,9′-anthracen]-10′-one (abbreviation: ACRSA), or the like can be used.

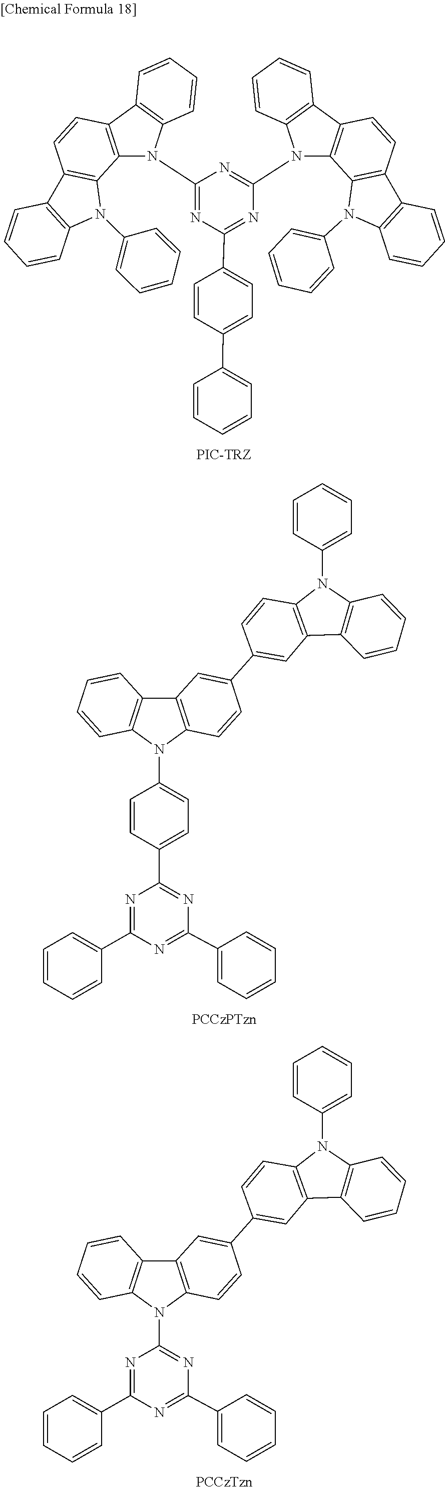 [SMILES: c1ccc(-c2ccc(-c3nc(-n4c5ccccc5c5ccc6c7ccccc7n(-c7ccccc7)c6c54)nc(-n4c5ccccc5c5ccc6c7ccccc7n(-c7ccccc7)c6c54)n3)cc2)cc1 ; c1ccc(-c2nc(-c3ccccc3)nc(-c3ccc(-n4c5ccccc5c5cc(-c6ccc7c(c6)c6ccccc6n7-c6ccccc6)ccc54)cc3)n2)cc1 ; c1ccc(-c2nc(-c3ccccc3)nc(-n3c4ccccc4c4cc(-c5ccc6c(c5)c5ccccc5n6-c5ccccc5)ccc43)n2)cc1]

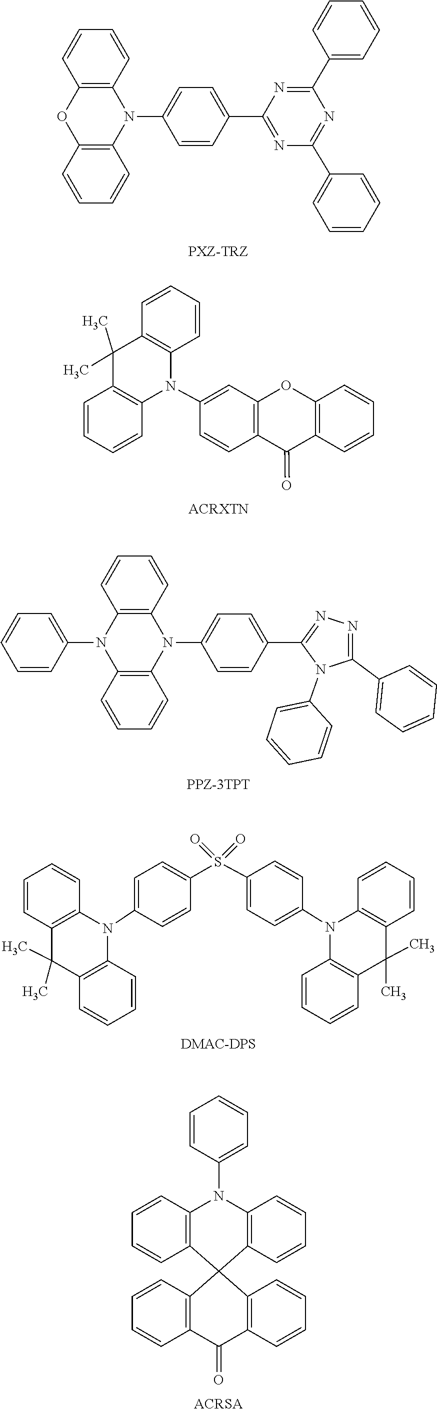

Such a heterocyclic compound is preferable because of having excellent electron-transport and hole-transport properties owing to a π-electron rich heteroaromatic ring and a π-electron deficient heteroaromatic ring. Among skeletons having the π-electron deficient heteroaromatic ring, in particular, a pyridine skeleton, a diazine skeleton (a pyrimidine skeleton, a pyrazine skeleton, and a pyridazine skeleton), and a triazine skeleton are preferred because of their high stability and reliability. In particular, a benzofuropyrimidine skeleton, a benzothienopyrimidine skeleton, a benzofuropyrazine skeleton, and a benzothienopyrazine skeleton are preferred because of their high accepting properties and high reliability.

Among skeletons having the π-electron rich heteroaromatic ring, an acridine skeleton, a phenoxazine skeleton, a phenothiazine skeleton, a furan skeleton, a thiophene skeleton, and a pyrrole skeleton have high stability and reliability; therefore, at least one of these skeletons is preferably included. A dibenzofuran skeleton is preferable as a furan skeleton, and a dibenzothiophene skeleton is preferable as a thiophene skeleton. As a pyrrole skeleton, an indole skeleton, a carbazole skeleton, an indolocarbazole skeleton, a bicarbazole skeleton, and a 3-(9-phenyl-9H-carbazol-3-yl)-9H-carbazole skeleton are particularly preferable.

Note that a substance in which the π-electron rich heteroaromatic ring is directly bonded to the π-electron deficient heteroaromatic ring is particularly preferred because the electron-donating property of the π-electron rich heteroaromatic ring and the electron-accepting property of the π-electron deficient heteroaromatic ring are both improved, the energy difference between the S1 level and the T1 level becomes small, and thus thermally activated delayed fluorescence can be obtained with high efficiency. Note that an aromatic ring to which an electron-withdrawing group such as a cyano group is bonded may be used instead of the π-electron deficient heteroaromatic ring. As a π-electron rich skeleton, an aromatic amine skeleton, a phenazine skeleton, or the like can be used.

As a π-electron deficient skeleton, a xanthene skeleton, a thioxanthene dioxide skeleton, an oxadiazole skeleton, a triazole skeleton, an imidazole skeleton, an anthraquinone skeleton, a skeleton containing boron such as phenylborane and boranthrene, an aromatic ring or a heteroaromatic ring having a cyano group or a nitrile group such as benzonitrile or cyanobenzene, a carbonyl skeleton such as benzophenone, a phosphine oxide skeleton, a sulfone skeleton, or the like can be used.

As described above, a π-electron deficient skeleton and a π-electron rich skeleton can be used instead of at least one of the π-electron deficient heteroaromatic ring and the π-electron rich heteroaromatic ring.

### <<Structure Example 3 of Layer 111(2)>>

A carrier-transport material can be used as the host material. For example, a hole-transport material, an electron-transport material, a substance that exhibits thermally activated delayed fluorescence (TADF), a material having an anthracene skeleton, a mixed material, or the like can be used as the host material.

### [Hole-Transport Material]

The material having a hole mobility of 1×10⁻⁶ cm²/Vs or higher can be suitably used as a hole-transport material.

For example, a hole-transport material that can be used for the layer 111 can be used for the layer 111(2).

### [Electron-Transport Material]

For example, an electron-transport material that can be used for the layer 111 can be used for the layer 111(2).

### [Material Having Anthracene Skeleton]

For example, a material having an anthracene skeleton that can be used for the layer 111 can be used for the layer 111(2).

### [Substance Exhibiting Thermally Activated Delayed Fluorescence (TADF)]

A TADF material can be used for the layer 111(2). For example, any of the TADF materials given below can be used as the host material. Note that without being limited thereto, a variety of known TADF materials can be used as the host material.

When the TADF material is used as the host material, triplet excitation energy generated in the TADF material can be converted into singlet excitation energy by reverse intersystem crossing. Moreover, excitation energy can be transferred to the light-emitting substance. In other words, the TADF material functions as an energy donor, and the light-emitting substance functions as an energy acceptor. Thus, the emission efficiency of the light-emitting device can be increased.

This is very effective in the case where the light-emitting substance is a fluorescent substance. In that case, the S1 level of the TADF material is preferably higher than that of the fluorescent substance in order that high emission efficiency be achieved. Furthermore, the T1 level of the TADF material is preferably higher than the S1 level of the fluorescent substance. Therefore, the T1 level of the TADF material is preferably higher than that of the fluorescent substance.

It is also preferable to use a TADF material that emits light whose wavelength overlaps with the wavelength on a lowest-energy-side absorption band of the fluorescent substance. This enables smooth transfer of excitation energy from the TADF material to the fluorescent substance and accordingly enables efficient light emission, which is preferable.

In addition, in order to efficiently generate singlet excitation energy from the triplet excitation energy by reverse intersystem crossing, carrier recombination preferably occurs in the TADF material. It is also preferable that the triplet excitation energy generated in the TADF material not be transferred to the triplet excitation energy of the fluorescent substance. For that reason, the fluorescent substance preferably has a protecting group around a luminophore (a skeleton which causes light emission) of the fluorescent substance. As the protecting group, a substituent having no π bond and a saturated hydrocarbon are preferably used. Specific examples include an alkyl group having 3 to 10 carbon atoms, a substituted or unsubstituted cycloalkyl group having 3 to 10 carbon atoms, and a trialkylsilyl group having 3 to 10 carbon atoms. It is further preferable that the fluorescent substance have a plurality of protecting groups. The substituents having no π bond are poor in carrier-transport performance, whereby the TADF material and the luminophore of the fluorescent substance can be made away from each other with little influence on carrier-transportation or carrier recombination.

Here, the luminophore refers to an atomic group (skeleton) that causes light emission in a fluorescent substance. The luminophore is preferably a skeleton having a π bond, further preferably includes an aromatic ring, and still further preferably includes a condensed aromatic ring or a condensed heteroaromatic ring.

Examples of the condensed aromatic ring or the condensed heteroaromatic ring include a phenanthrene skeleton, a stilbene skeleton, an acridone skeleton, a phenoxazine skeleton, and a phenothiazine skeleton. Specifically, a fluorescent substance having any of a naphthalene skeleton, an anthracene skeleton, a fluorene skeleton, a chrysene skeleton, a triphenylene skeleton, a tetracene skeleton, a pyrene skeleton, a perylene skeleton, a coumarin skeleton, a quinacridone skeleton, and a naphthobisbenzofuran skeleton is preferred because of its high fluorescence quantum yield.

For example, the TADF material that can be used as the light-emitting material can be used as the host material.

[Structure example 1 of mixed material]A material in which a plurality of kinds of substances are mixed can be used as the host material. For example, an electron-transport material and a hole-transport material can be used for the mixed material. In the mixed material, the weight ratio of the hole-transport material to the electron-transport material can be 1:19 to 19:1. Thus, the carrier-transport property of the layer 111(2) can be easily adjusted and a recombination region can be easily controlled.

### [Structure Example 2 of Mixed Material]

In addition, a material mixed with a phosphorescent substance can be used as the host material. When a fluorescent substance is used as the light-emitting substance, a phosphorescent substance can be used as an energy donor for supplying excitation energy to the fluorescent substance.

A mixed material containing a material to form an exciplex can be used for the host material. For example, a material in which an emission spectrum of a formed exciplex overlaps with a wavelength of the absorption band on the lowest energy side of the light-emitting substance can be used for the host material. This enables smooth energy transfer and improve emission efficiency. The driving voltage can be suppressed.

A phosphorescent substance can be used as at least one of the materials forming an exciplex. Accordingly, reverse intersystem crossing can be used. Triplet excitation energy can be efficiently converted into singlet excitation energy.

Combination of an electron-transport material and a hole-transport material whose HOMO level is higher than or equal to that of the electron-transport material is preferable for forming an exciplex. The LUMO level of the hole-transport material is preferably higher than or equal to the LUMO level of the electron-transport material. Thus, an exciplex can be efficiently formed. Note that the LUMO levels and the HOMO levels of the materials can be derived from the electrochemical characteristics (the reduction potentials and the oxidation potentials). Specifically, the reduction potentials and the oxidation potentials can be measured by cyclic voltammetry (CV).

The formation of an exciplex can be confirmed by a phenomenon in which the emission spectrum of the mixed film in which the hole-transport material and the electron-transport material are mixed is shifted to a longer wavelength side than the emission spectra of each of the materials (or has another peak on the longer wavelength side) observed by comparison of the emission spectra of the hole-transport material, the electron-transport material, and the mixed film of these materials, for example. Alternatively, the formation of an exciplex can be confirmed by a difference in transient response, such as a phenomenon in which the transient PL lifetime of the mixed film has more long lifetime components or has a larger proportion of delayed components than that of each of the materials, observed by comparison of transient photoluminescence (PL) of the hole-transport material, the electron-transport material, and the mixed film of the materials. The transient PL can be rephrased as transient electroluminescence (EL). That is, the formation of an exciplex can also be confirmed by a difference in transient response observed by comparison of the transient EL of the hole-transport material, the electron-transport material, and the mixed film of the materials.

Note that this embodiment can be combined with any of the other embodiments in this specification as appropriate.

### Embodiment 8

In this embodiment, a light-emitting apparatus including the light-emitting device described in any one of Embodiments 1 to 6 will be described.

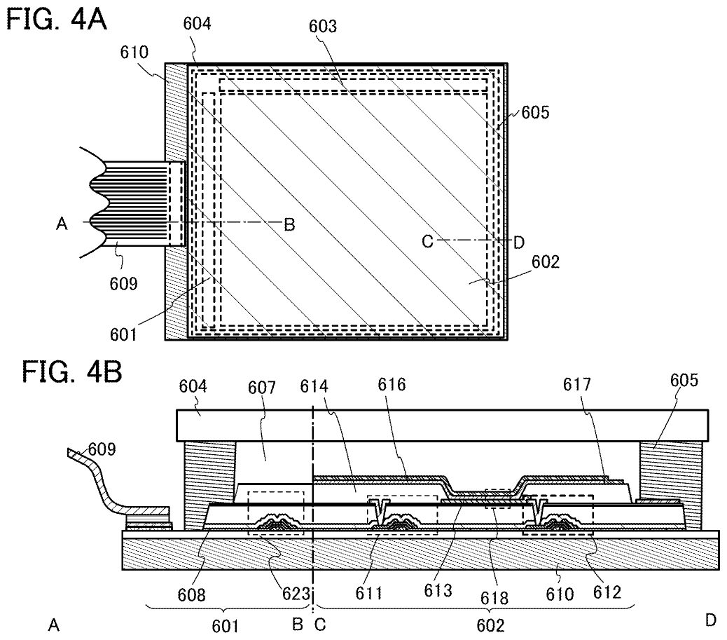

In this embodiment, the light-emitting apparatus fabricated using the light-emitting device described in any one of Embodiments 1 to 6 is described with reference to FIGS. 4A and 4B. Note that FIG. 4A is atop view of the light-emitting apparatus and FIG. 4B is a cross-sectional view taken along the lines A-B and C-D in FIG. 4A. This light-emitting apparatus includes a driver circuit portion (a source line driver circuit 601), a pixel portion 602, and another driver circuit portion (a gate line driver circuit 603), which are to control light emission of a light-emitting device and illustrated with dotted lines. Reference numeral 604 denotes a sealing substrate; 605, a sealing material; and 607, a space surrounded by the sealing material 605.

A lead wiring 608 is a wiring for transmitting signals to be input to the source line driver circuit 601 and the gate line driver circuit 603 and receiving signals such as a video signal, a clock signal, a start signal, and a reset signal from a flexible printed circuit (FPC) 609 serving as an external input terminal. Although only the FPC is illustrated here, a printed wiring board (PWB) may be attached to the FPC. The light-emitting apparatus in the present specification includes, in its category, not only the light-emitting apparatus itself but also the light-emitting apparatus provided with the FPC or the PWB.

Next, a cross-sectional structure is described with reference to FIG. 4B. The driver circuit portions and the pixel portion are formed over an element substrate 610; here, the source line driver circuit 601, which is a driver circuit portion, and one pixel in the pixel portion 602 are illustrated.

The element substrate 610 may be a substrate containing glass, quartz, an organic resin, a metal, an alloy, or a semiconductor or a plastic substrate formed of fiber reinforced plastics (FRP), poly(vinyl fluoride) (PVF), polyester, an acrylic resin, or the like.

The structure of transistors used in pixels or driver circuits is not particularly limited. For example, inverted staggered transistors may be used, or staggered transistors may be used. Furthermore, top-gate transistors or bottom-gate transistors may be used. A semiconductor material used for the transistors is not particularly limited, and for example, silicon, germanium, silicon carbide, gallium nitride, or the like can be used. Alternatively, an oxide semiconductor containing at least one of indium, gallium, and zinc, such as an In—Ga—Zn-based metal oxide, may be used.

There is no particular limitation on the crystallinity of a semiconductor material used for the transistors, and an amorphous semiconductor or a semiconductor having crystallinity (a microcrystalline semiconductor, a polycrystalline semiconductor, a single crystal semiconductor, or a semiconductor partly including crystal regions) may be used. It is preferable that a semiconductor having crystallinity be used, in which case deterioration of the transistor characteristics can be suppressed.

Here, an oxide semiconductor is preferably used for semiconductor devices such as the transistors provided in the pixels or driver circuits and transistors used for touch sensors described later, and the like. In particular, an oxide semiconductor having a wider band gap than silicon is preferably used. When an oxide semiconductor having a wider band gap than silicon is used, off-state current of the transistors can be reduced.

The oxide semiconductor preferably contains at least indium (In) or zinc (Zn). Further preferably, the oxide semiconductor contains an oxide represented by an In-M-Zn-based oxide (M represents a metal such as Al, Ti, Ga, Ge, Y, Zr, Sn, La, Ce, or Hf).

As a semiconductor layer, it is particularly preferable to use an oxide semiconductor film including a plurality of crystal parts whose c-axes are aligned perpendicular to a surface on which the semiconductor layer is formed or the top surface of the semiconductor layer and in which the adjacent crystal parts have no grain boundary.

The use of such materials for the semiconductor layer makes it possible to provide a highly reliable transistor in which a change in the electrical characteristics is suppressed.

Charge accumulated in a capacitor through a transistor including the above-described semiconductor layer can be held for a long time because of the low off-state current of the transistor. When such a transistor is used in a pixel, operation of a driver circuit can be stopped while a gray scale of an image displayed in each display region is maintained. As a result, an electronic device with extremely low power consumption can be obtained.

For stable characteristics of the transistor, a base film is preferably provided. The base film can be formed with a single-layer structure or a stacked-layer structure using an inorganic insulating film such as a silicon oxide film, a silicon nitride film, a silicon oxynitride film, or a silicon nitride oxide film. The base film can be formed by a sputtering method, a chemical vapor deposition (CVD) method (e.g., a plasma CVD method, a thermal CVD method, or a metal organic CVD (MOCVD) method), an atomic layer deposition (ALD) method, a coating method, a printing method, or the like. Note that the base film is not necessarily provided.

Note that an FET 623 is illustrated as a transistor formed in the source line driver circuit 601. In addition, the driver circuit may be formed with any of a variety of circuits such as a CMOS circuit, a PMOS circuit, or an NMOS circuit. Although a driver integrated type in which the driver circuit is formed over the substrate is illustrated in this embodiment, the driver circuit is not necessarily formed over the substrate, and the driver circuit can be formed outside, not over the substrate.

The pixel portion 602 includes a plurality of pixels each including a switching FET 611, a current controlling FET 612, and a first electrode 613 electrically connected to a drain of the current controlling FET 612. One embodiment of the present invention is not limited to the structure. The pixel portion 602 may include three or more FETs and a capacitor in combination.

Note that an insulator 614 is formed to cover an end portion of the first electrode 613. Here, the insulator 614 can be formed using a positive photosensitive acrylic resin film.

In order to improve coverage with an EL layer or the like which is formed later, the insulator 614 is formed to have a curved surface with curvature at its upper or lower end portion. For example, in the case where a positive photosensitive acrylic resin is used for a material of the insulator 614, only the upper end portion of the insulator 614 preferably has a surface with a curvature radius (greater than or equal to 0.2 μm and less than or equal to 3 μm). As the insulator 614, either a negative photosensitive resin or a positive photosensitive resin can be used.

An EL layer 616 and a second electrode 617 are formed over the first electrode 613. Here, as a material used for the first electrode 613 functioning as an anode, a material having a high work function is preferably used. For example, a single-layer film of an ITO film, an indium tin oxide film containing silicon, an indium oxide film containing zinc oxide at 2 wt % to 20 wt %, a titanium nitride film, a chromium film, a tungsten film, a Zn film, a Pt film, or the like, a stack of a titanium nitride film and a film containing aluminum as its main component, a stack of three layers of a titanium nitride film, a film containing aluminum as its main component, and a titanium nitride film, or the like can be used. The stacked-layer structure enables low wiring resistance, favorable ohmic contact, and a function as an anode.

The EL layer 616 is formed by any of a variety of methods such as an evaporation method using an evaporation mask, an inkjet method, and a spin coating method. The EL layer 616 has the structure described in any one of Embodiments 1 to 6. As another material included in the EL layer 616, a low molecular compound or a high molecular compound (including an oligomer or a dendrimer) may be used.

As a material used for the second electrode 617, which is formed over the EL layer 616 and functions as a cathode, a material having a low work function (e.g., Al, Mg, Li, and Ca, or an alloy or a compound thereof, such as MgAg, MgIn, and AlLi) is preferably used. In the case where light generated in the EL layer 616 passes through the second electrode 617, a stack including a thin metal film and a transparent conductive film (e.g., ITO, indium oxide containing zinc oxide at 2 wt % or higher and 20 wt % or lower, indium tin oxide containing silicon, or zinc oxide (ZnO)) is preferably used for the second electrode 617.

Note that the light-emitting device 618 is formed with the first electrode 613, the EL layer 616, and the second electrode 617. The light-emitting device is the light-emitting device described in any one of Embodiments 1 to 6. In the light-emitting apparatus of this embodiment, the pixel portion, which includes a plurality of light-emitting devices, may include both the light-emitting device described in any one of Embodiments 1 to 6 and a light-emitting device having a different structure.

The sealing substrate 604 is attached to the element substrate 610 with the sealing material 605, so that a light-emitting device 618 is provided in a space 607 surrounded by the element substrate 610, the sealing substrate 604, and the sealing material 605. The space 607 may be filled with a filler, or may be filled with an inert gas (such as nitrogen or argon), or the sealing material. It is preferable that the sealing substrate be provided with a recessed portion and a drying agent be provided in the recessed portion, in which case degradation due to influence of moisture can be suppressed.

An epoxy-based resin or glass frit is preferably used for the sealing material 605. It is preferable that such a material not be permeable to moisture or oxygen as much as possible. As the sealing substrate 604, a glass substrate, a quartz substrate, or a plastic substrate formed of fiber reinforced plastics (FRP), poly(vinyl fluoride) (PVF), polyester, an acrylic resin, or the like can be used.

Although not illustrated in FIGS. 4A and 4B, a protective film may be provided over the second electrode. As the protective film, an organic resin film or an inorganic insulating film may be formed. The protective film may be formed so as to cover an exposed portion of the sealing material 605. The protective film may be provided so as to cover surfaces and side surfaces of the pair of substrates and exposed side surfaces of a sealing layer, an insulating layer, and the like.

The protective film can be formed using a material through which an impurity such as water does not permeate easily. Thus, diffusion of an impurity such as water from the outside into the inside can be effectively suppressed.

As a material of the protective film, an oxide, a nitride, a fluoride, a sulfide, a ternary compound, a metal, a polymer, or the like can be used. For example, the material may contain aluminum oxide, hafnium oxide, hafnium silicate, lanthanum oxide, silicon oxide, strontium titanate, tantalum oxide, titanium oxide, zinc oxide, niobium oxide, zirconium oxide, tin oxide, yttrium oxide, cerium oxide, scandium oxide, erbium oxide, vanadium oxide, indium oxide, aluminum nitride, hafnium nitride, silicon nitride, tantalum nitride, titanium nitride, niobium nitride, molybdenum nitride, zirconium nitride, gallium nitride, a nitride containing titanium and aluminum, an oxide containing titanium and aluminum, an oxide containing aluminum and zinc, a sulfide containing manganese and zinc, a sulfide containing cerium and strontium, an oxide containing erbium and aluminum, an oxide containing yttrium and zirconium, or the like.

The protective film is preferably formed using a deposition method with favorable step coverage. One such method is an atomic layer deposition (ALD) method. A material that can be deposited by an ALD method is preferably used for the protective film. A dense protective film having reduced defects such as cracks or pinholes or a uniform thickness can be formed by an ALD method. Furthermore, damage caused to a process member in forming the protective film can be reduced.

By an ALD method, a uniform protective film with few defects can be formed even on, for example, a surface with a complex uneven shape or upper, side, and lower surfaces of a touch panel.

As described above, the light-emitting apparatus fabricated using the light-emitting device described in any one of Embodiments 1 to 6 can be obtained.

The light-emitting apparatus in this embodiment is fabricated using the light-emitting device described in any one of Embodiments 1 to 6 and thus can have favorable characteristics. Specifically, since the light-emitting device described in any one of Embodiments 1 to 6 has high emission efficiency, the light-emitting apparatus can achieve low power consumption.

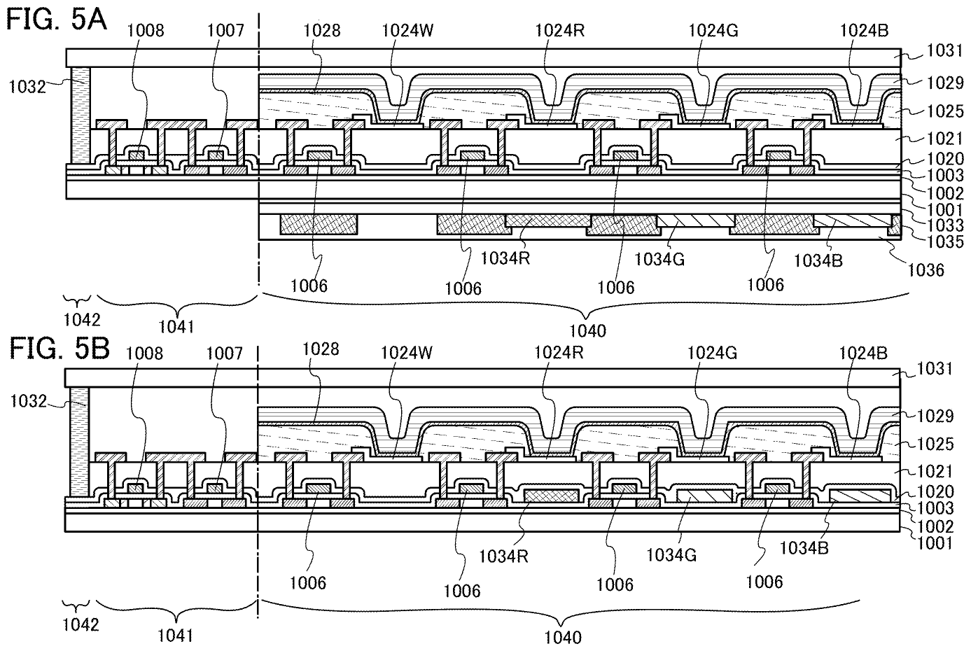

FIGS. 5A and 5B each illustrate an example of a light-emitting apparatus that includes a light-emitting device exhibiting white light emission, coloring layers (color filters) and the like to display a full-color image. In FIG. 5A, a substrate 1001, a base insulating film 1002, a gate insulating film 1003, gate electrodes 1006, 1007, and 1008, a first interlayer insulating film 1020, a second interlayer insulating film 1021, a peripheral portion 1042, a pixel portion 1040, a driver circuit portion 1041, first electrodes 1024W, 1024R, 1024G, and 1024B of light-emitting devices, a partition 1025, an EL layer 1028, a second electrode 1029 of the light-emitting devices, a sealing substrate 1031, a sealing material 1032, and the like are illustrated.

In FIG. 5A, coloring layers (a red coloring layer 1034R, a green coloring layer 1034G, and a blue coloring layer 1034B) are provided on a transparent base material 1033. A black matrix 1035 may be additionally provided. The transparent base material 1033 provided with the coloring layers and the black matrix is aligned and fixed to the substrate 1001. Note that the coloring layers and the black matrix 1035 are covered with an overcoat layer 1036. In FIG. 5A, light emitted from part of the light-emitting layer does not pass through the coloring layers, while light emitted from the other part of the light-emitting layer passes through the coloring layers. The light that does not pass through the coloring layers is white and the light that passes through any one of the coloring layers is red, green, or blue; thus, an image can be displayed using pixels of the four colors.

FIG. 5B illustrates an example in which the coloring layers (the red coloring layer 1034R, the green coloring layer 1034G, and the blue coloring layer 1034B) are provided between the gate insulating film 1003 and the first interlayer insulating film 1020. As in the structure, the coloring layers may be provided between the substrate 1001 and the sealing substrate 1031.

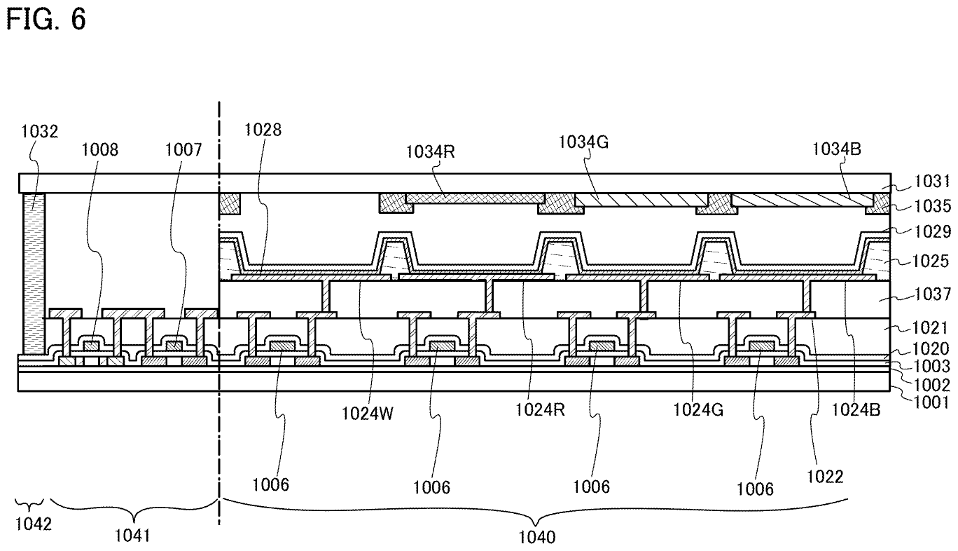

The above-described light-emitting apparatus has a structure in which light is extracted from the substrate 1001 side where FETs are formed (a bottom emission structure), but may have a structure in which light is extracted from the sealing substrate 1031 side (a top emission structure). FIG. 6 is a cross-sectional view of a light-emitting apparatus having a top emission structure. In this case, a substrate which does not transmit light can be used as the substrate 1001. The process up to the step of forming a connection electrode which connects the FET and the anode of the light-emitting device is performed in a manner similar to that of the light-emitting apparatus having a bottom emission structure. Then, a third interlayer insulating film 1037 is formed to cover an electrode 1022. This insulating film may have a planarization function. The third interlayer insulating film 1037 can be formed using a material similar to that of the second interlayer insulating film, and can alternatively be formed using any of other known materials.

The first electrodes 1024W, 1024R, 1024G, and 1024B of the light-emitting devices each serve as an anode here, but may serve as a cathode. Furthermore, in the case of the top-emission light-emitting apparatus illustrated in FIG. 6, the first electrodes are preferably reflective electrodes. The EL layer 1028 is formed to have a structure similar to the structure of the unit 103, which is described in any one of Embodiments 1 to 6, with which white light emission can be obtained.

In the case of a top emission structure as illustrated in FIG. 6, sealing can be performed with the sealing substrate 1031 on which the coloring layers (the red coloring layer 1034R, the green coloring layer 1034G, and the blue coloring layer 1034B) are provided. The sealing substrate 1031 may be provided with the black matrix 1035 which is positioned between pixels. The coloring layers (the red coloring layer 1034R, the green coloring layer 1034G, and the blue coloring layer 1034B) or the black matrix may be covered with the overcoat layer 1036. Note that a light-transmitting substrate is used as the sealing substrate 1031. Although an example in which full color display is performed using four colors of red, green, blue, and white is shown here, there is no particular limitation and full color display using four colors of red, yellow, green, and blue or three colors of red, green, and blue may be performed.

In the light-emitting apparatus having a top emission structure, a microcavity structure can be suitably employed. A light-emitting device with a microcavity structure is formed with use of a reflective electrode as the first electrode and a semi-transmissive and semi-reflective electrode as the second electrode. The light-emitting device with a microcavity structure includes at least an EL layer between the reflective electrode and the semi-transmissive and semi-reflective electrode, which includes at least a light-emitting layer serving as a light-emitting region.

Note that the reflective electrode has a visible light reflectance higher than or equal to 40% and lower than or equal to 100%, preferably higher than or equal to 70% and lower than or equal to 100%, and a resistivity of 1×10⁻² Ωcm or lower. In addition, the semi-transmissive and semi-reflective electrode has a visible light reflectance higher than or equal to 20% and lower than or equal to 80%, preferably higher than or equal to 40% and lower than or equal to 70%, and a resistivity of 1×10⁻² Ωcm or lower.

Light emitted from the light-emitting layer included in the EL layer is reflected and resonated by the reflective electrode and the semi-transmissive and semi-reflective electrode.

In the light-emitting device, by changing thicknesses of the transparent conductive film, the composite material, the carrier-transport material, or the like, the optical path length between the reflective electrode and the semi-transmissive and semi-reflective electrode can be changed. Thus, light with a wavelength that is resonated between the reflective electrode and the semi-transmissive and semi-reflective electrode can be intensified while light with a wavelength that is not resonated therebetween can be attenuated.

Note that light that is reflected back by the reflective electrode (first reflected light) considerably interferes with light that directly enters the semi-transmissive and semi-reflective electrode from the light-emitting layer (first incident light). For this reason, the optical path length between the reflective electrode and the light-emitting layer is preferably adjusted to (2n−1)λ/4 (n is a natural number of 1 or larger and λ is a wavelength of color to be amplified). By adjusting the optical path length, the phases of the first reflected light and the first incident light can be aligned with each other and the light emitted from the light-emitting layer can be further amplified.

Note that in the above structure, the EL layer may include a plurality of light-emitting layers or may include a single light-emitting layer. The tandem light-emitting device described above may be combined with a plurality of EL layers; for example, a light-emitting device may have a structure in which a plurality of EL layers are provided, a charge-generation layer is provided between the EL layers, and each EL layer includes a plurality of light-emitting layers or a single light-emitting layer.

With the microcavity structure, emission intensity with a specific wavelength in the front direction can be increased, whereby power consumption can be reduced. Note that in the case of a light-emitting apparatus which displays images with subpixels of four colors, red, yellow, green, and blue, the light-emitting apparatus can have favorable characteristics because the luminance can be increased owing to yellow light emission and each subpixel can employ a microcavity structure suitable for wavelengths of the corresponding color.

The light-emitting apparatus in this embodiment is fabricated using the light-emitting device described in any one of Embodiments 1 to 6 and thus can have favorable characteristics. Specifically, since the light-emitting device described in any one of Embodiments 1 to 6 has high emission efficiency, the light-emitting apparatus can achieve low power consumption.

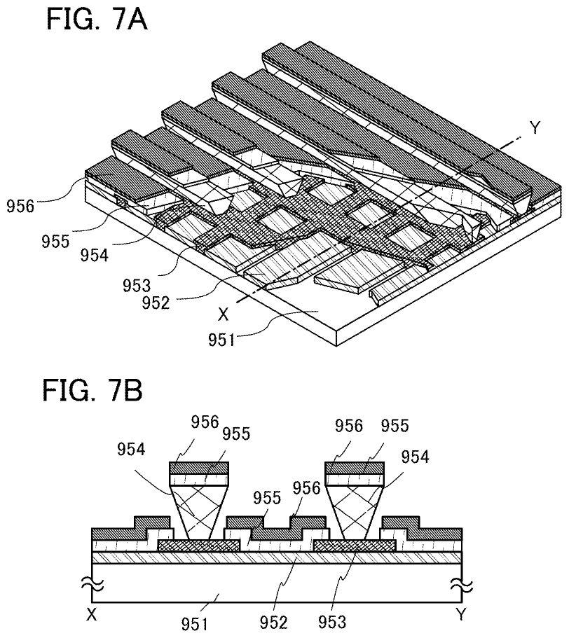

An active matrix light-emitting apparatus is described above, whereas a passive matrix light-emitting apparatus is described below. FIGS. 7A and 7B illustrate a passive matrix light-emitting apparatus manufactured using the present invention. Note that FIG. 7A is a perspective view of the light-emitting apparatus, and FIG. 7B is a cross-sectional view taken along the line X-Y in FIG. 7A. In FIGS. 7A and 7B, over a substrate 951, an EL layer 955 is provided between an electrode 952 and an electrode 956. An end portion of the electrode 952 is covered with an insulating layer 953. A partition layer 954 is provided over the insulating layer 953. The sidewalls of the partition layer 954 are aslope such that the distance between both sidewalls is gradually narrowed toward the surface of the substrate. In other words, a cross section taken along the direction of the short side of the partition layer 954 is trapezoidal, and the lower side (a side of the trapezoid which is parallel to the surface of the insulating layer 953 and is in contact with the insulating layer 953) is shorter than the upper side (a side of the trapezoid which is parallel to the surface of the insulating layer 953 and is not in contact with the insulating layer 953). The partition layer 954 thus provided can prevent defects in the light-emitting device due to static electricity or others. The passive-matrix light-emitting apparatus also includes the light-emitting device described in any one of Embodiments 1 to 6; thus, the light-emitting apparatus can have high reliability or low power consumption.

Since many minute light-emitting devices arranged in a matrix in the light-emitting apparatus described above can each be controlled, the light-emitting apparatus can be suitably used as a display device for displaying images.

This embodiment can be freely combined with any of the other embodiments.

### Embodiment 9

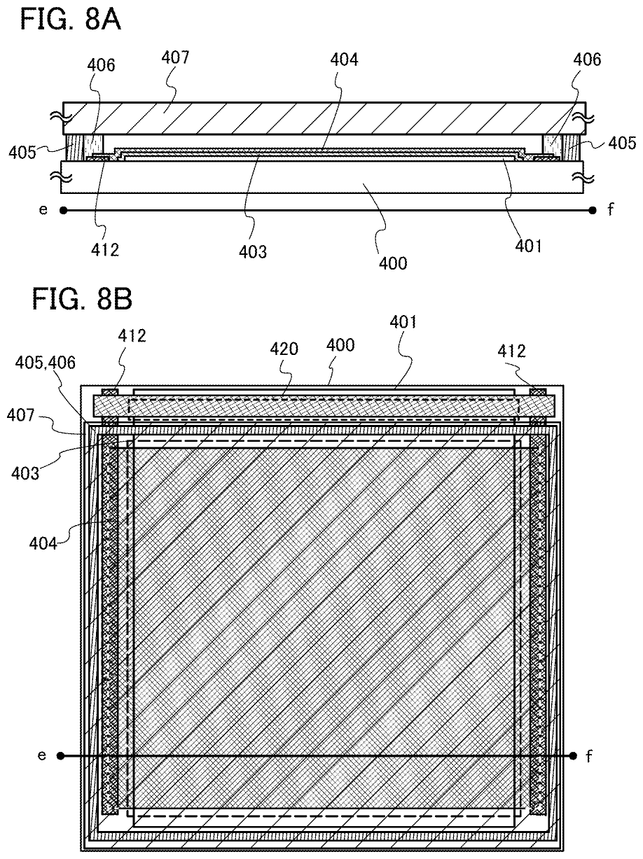

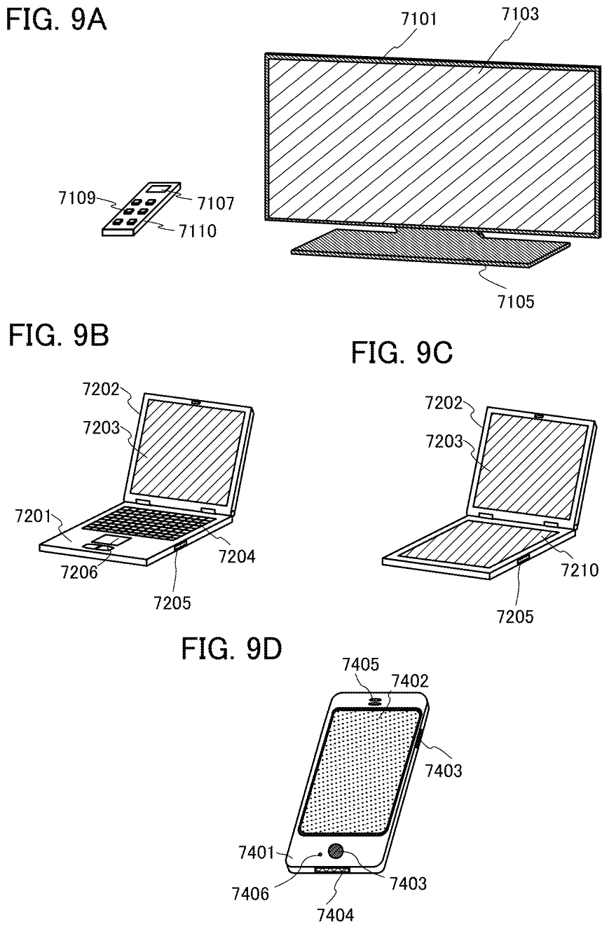

In this embodiment, an example in which the light-emitting device described in any one of Embodiments 1 to 6 is used for a lighting device will be described with reference to FIGS. 8A and 8B. FIG. 8B is a top view of the lighting device, and FIG. 8A is a cross-sectional view taken along the line e-f in FIG. 8B.

In the lighting device in this embodiment, a first electrode 401 is formed over a substrate 400 which is a support and has a light-transmitting property. The first electrode 401 corresponds to the electrode 101 in any one of Embodiments 1 to 6. When light is extracted from the first electrode 401 side, the first electrode 401 is formed using a material having a light-transmitting property.

A pad 412 for applying voltage to a second electrode 404 is provided over the substrate 400.

An EL layer 403 is formed over the first electrode 401. The structure of the EL layer 403 corresponds to, for example, the structure of the unit 103 in any one of Embodiments 1 to 6, or the structure in which the unit 103(2), and the intermediate layer 106 are combined. Refer to the descriptions for the structure.

The second electrode 404 is formed to cover the EL layer 403. The second electrode 404 corresponds to the electrode 102 in any one of Embodiments 1 to 6. The second electrode 404 is formed using a material having high reflectance when light is extracted from the first electrode 401 side. The second electrode 404 is connected to the pad 412, whereby voltage is applied.

As described above, the lighting device described in this embodiment includes a light-emitting device including the first electrode 401, the EL layer 403, and the second electrode 404. Since the light-emitting device is a light-emitting device with high emission efficiency, the lighting device in this embodiment can be a lighting device having low power consumption.

The substrate 400 provided with the light-emitting device having the above structure is fixed to a sealing substrate 407 with sealing materials 405 and 406 and sealing is performed, whereby the lighting device is completed. It is possible to use only either the sealing material 405 or the sealing material 406. The inner sealing material 406 (not illustrated in FIG. 8B) can be mixed with a desiccant that enables moisture to be adsorbed, which results in improved reliability.

When parts of the pad 412 and the first electrode 401 are extended to the outside of the sealing materials 405 and 406, the extended parts can serve as external input terminals. An IC chip 420 mounted with a converter or the like may be provided over the external input terminals.

The lighting device described in this embodiment includes as an EL element the light-emitting device described in any one of Embodiments 1 to 6; thus, the lighting device can consume less power.

### Embodiment 10

In this embodiment, examples of electronic devices each including the light-emitting device described in any one of Embodiments 1 to 6 will be described. The light-emitting device described in any one of Embodiments 1 to 6 has high emission efficiency and low power consumption. As a result, the electronic devices described in this embodiment can each include a light-emitting portion having low power consumption.

Examples of the electronic device including the above light-emitting device include television devices (also referred to as TV or television receivers), monitors for computers and the like, digital cameras, digital video cameras, digital photo frames, cellular phones (also referred to as mobile phones or mobile phone devices), portable game machines, portable information terminals, audio playback devices, and large game machines such as pachinko machines. Specific examples of these electronic devices are shown below.

FIG. 9A illustrates an example of a television device. In the television device, a display portion 7103 is incorporated in a housing 7101. Here, the housing 7101 is supported by a stand 7105. Images can be displayed on the display portion 7103, and in the display portion 7103, the light-emitting devices described in any one of Embodiments 1 to 6 are arranged in a matrix.

The television device can be operated with an operation switch of the housing 7101 or a separate remote controller 7110. With operation keys 7109 of the remote controller 7110, channels or volume can be controlled and images displayed on the display portion 7103 can be controlled. Furthermore, the remote controller 7110 may be provided with a display portion 7107 for displaying data output from the remote controller 7110.

Note that the television device is provided with a receiver, a modem, or the like. With use of the receiver, a general television broadcast can be received. Moreover, when the television device is connected to a communication network with or without wires via the modem, one-way (from a sender to a receiver) or two-way (between a sender and a receiver or between receivers) data communication can be performed.

FIG. 9B illustrates a computer, which includes a main body 7201, a housing 7202, a display portion 7203, a keyboard 7204, an external connection port 7205, a pointing device 7206, and the like. Note that this computer is fabricated using the light-emitting devices that are described in any one of Embodiments 1 to 6 and arranged in a matrix in the display portion 7203. The computer illustrated in FIG. 9B may have a structure illustrated in FIG. 9C. A computer illustrated in FIG. 9C is provided with a second display portion 7210 instead of the keyboard 7204 and the pointing device 7206. The second display portion 7210 is a touch panel, and input operation can be performed by touching display for input on the second display portion 7210 with a finger or a dedicated pen. The second display portion 7210 can also display images other than the display for input. The display portion 7203 may also be a touch panel. Connecting the two screens with a hinge can prevent troubles; for example, the screens can be prevented from being cracked or broken while the computer is being stored or carried.

FIG. 9D illustrates an example of a portable terminal. A portable terminal is provided with a display portion 7402 incorporated in a housing 7401, operation buttons 7403, an external connection port 7404, a speaker 7405, a microphone 7406, and the like. Note that the portable terminal has the display portion 7402 including the light-emitting devices described in any one of Embodiments 1 to 6 and arranged in a matrix.

When the display portion 7402 of the portable terminal illustrated in FIG. 9D is touched with a finger or the like, data can be input into the portable terminal. In this case, operations such as making a call and creating an e-mail can be performed by touching the display portion 7402 with a finger or the like.

The display portion 7402 has mainly three screen modes. The first mode is a display mode mainly for displaying images. The second mode is an input mode mainly for inputting information such as text. The third mode is a display-and-input mode in which the two modes, the display mode and the input mode, are combined.

For example, in the case of making a call or creating an e-mail, a text input mode mainly for inputting text is selected for the display portion 7402 so that text displayed on the screen can be input. In this case, it is preferable to display a keyboard or number buttons on almost the entire screen of the display portion 7402.

When a sensing device including a sensor such as a gyroscope sensor or an acceleration sensor for detecting inclination is provided inside the portable terminal, display on the screen of the display portion 7402 can be automatically changed in direction by determining the orientation of the portable terminal (whether the portable terminal is placed horizontally or vertically).

The screen modes are switched by touching the display portion 7402 or operating the operation buttons 7403 of the housing 7401. Alternatively, the screen modes can be switched depending on the kind of images displayed on the display portion 7402. For example, when a signal of an image displayed on the display portion is a signal of moving image data, the screen mode is switched to the display mode. When the signal is a signal of text data, the screen mode is switched to the input mode.

Moreover, in the input mode, when input by touching the display portion 7402 is not performed for a certain period while a signal sensed by an optical sensor in the display portion 7402 is sensed, the screen mode may be controlled so as to be switched from the input mode to the display mode.

The display portion 7402 may also function as an image sensor. For example, an image of a palm print, a fingerprint, or the like is taken when the display portion 7402 is touched with the palm or the finger, whereby personal authentication can be performed. Furthermore, by providing a backlight or a sensing light source which emits near-infrared light in the display portion, an image of a finger vein, a palm vein, or the like can be taken.

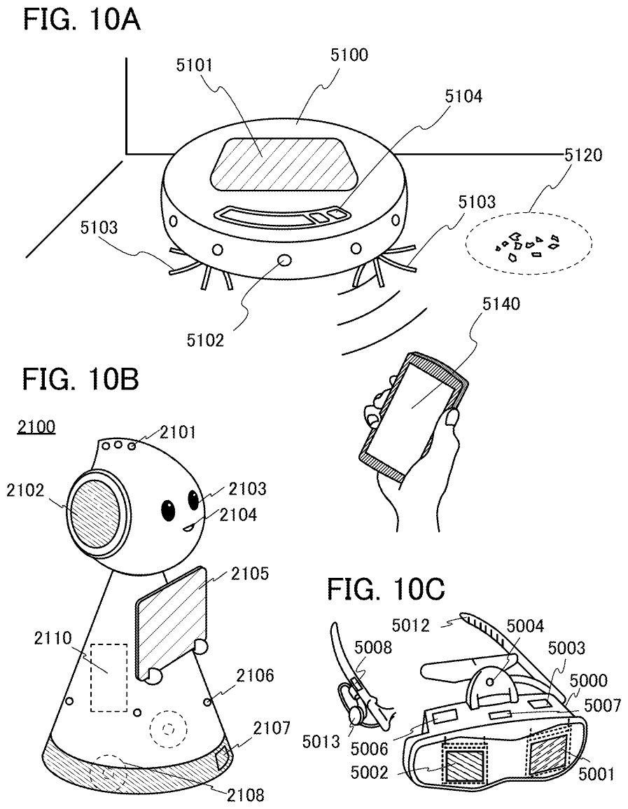

FIG. 10A is a schematic view illustrating an example of a cleaning robot.

A cleaning robot 5100 includes a display 5101 on its top surface, a plurality of cameras 5102 on its side surface, a brush 5103, and operation buttons 5104. Although not illustrated, the bottom surface of the cleaning robot 5100 is provided with a tire, an inlet, and the like. Furthermore, the cleaning robot 5100 includes various sensors such as an infrared sensor, an ultrasonic sensor, an acceleration sensor, a piezoelectric sensor, an optical sensor, and a gyroscope sensor. The cleaning robot 5100 has a wireless communication means.

The cleaning robot 5100 is self-propelled, detects dust 5120, and sucks up the dust through the inlet provided on the bottom surface.

The cleaning robot 5100 can determine whether there is an obstacle such as a wall, furniture, or a step by analyzing images taken by the cameras 5102. When the cleaning robot 5100 detects an object that is likely to be caught in the brush 5103 (e.g., a wire) by image analysis, the rotation of the brush 5103 can be stopped.

The display 5101 can display the remaining capacity of a battery, the amount of collected dust, or the like. The display 5101 may display a path on which the cleaning robot 5100 has run. The display 5101 may be a touch panel, and the operation buttons 5104 may be provided on the display 5101.

The cleaning robot 5100 can communicate with a portable electronic device 5140 such as a smartphone. The portable electronic device 5140 can display images taken by the cameras 5102. Accordingly, an owner of the cleaning robot 5100 can monitor his/her room even when the owner is not at home. The owner can also check the display on the display 5101 by the portable electronic device 5140 such as a smartphone.

The light-emitting apparatus of one embodiment of the present invention can be used for the display 5101.

A robot 2100 illustrated in FIG. 10B includes an arithmetic device 2110, an illuminance sensor 2101, a microphone 2102, an upper camera 2103, a speaker 2104, a display 2105, a lower camera 2106, an obstacle sensor 2107, and a moving mechanism 2108.

The microphone 2102 has a function of detecting a speaking voice of a user, an environmental sound, and the like. The speaker 2104 also has a function of outputting sound. The robot 2100 can communicate with a user using the microphone 2102 and the speaker 2104.

The display 2105 has a function of displaying various kinds of information. The robot 2100 can display information desired by a user on the display 2105. The display 2105 may be provided with a touch panel. Moreover, the display 2105 may be a detachable information terminal, in which case charging and data communication can be performed when the display 2105 is set at the home position of the robot 2100.

The upper camera 2103 and the lower camera 2106 each have a function of taking an image of the surroundings of the robot 2100. The obstacle sensor 2107 can detect an obstacle in the direction where the robot 2100 advances with the moving mechanism 2108. The robot 2100 can move safely by recognizing the surroundings with the upper camera 2103, the lower camera 2106, and the obstacle sensor 2107. The light-emitting apparatus of one embodiment of the present invention can be used for the display 2105.

FIG. 10C illustrates an example of a goggle-type display. The goggle-type display includes, for example, a housing 5000, a display portion 5001, a speaker 5003, an LED lamp 5004, operation keys (including a power switch and an operation switch), a connection terminal 5006, a sensor 5007 (a sensor having a function of measuring force, displacement, position, speed, acceleration, angular velocity, rotational frequency, distance, light, liquid, magnetism, temperature, chemical substance, sound, time, hardness, electric field, current, voltage, electric power, radiation, flow rate, humidity, gradient, oscillation, odor, or infrared ray), a microphone 5008, a display portion 5002, a support 5012, and an earphone 5013.

The light-emitting apparatus of one embodiment of the present invention can be used for the display portion 5001 and the display portion 5002.

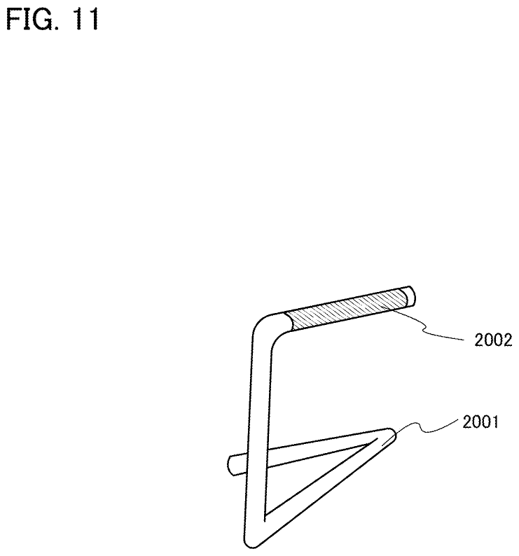

FIG. 11 illustrates an example in which the light-emitting device described in any one of Embodiments 1 to 6 is used for a table lamp which is a lighting device. The table lamp illustrated in FIG. 11 includes a housing 2001 and a light source 2002, and the lighting device described in Embodiment 9 may be used for the light source 2002.

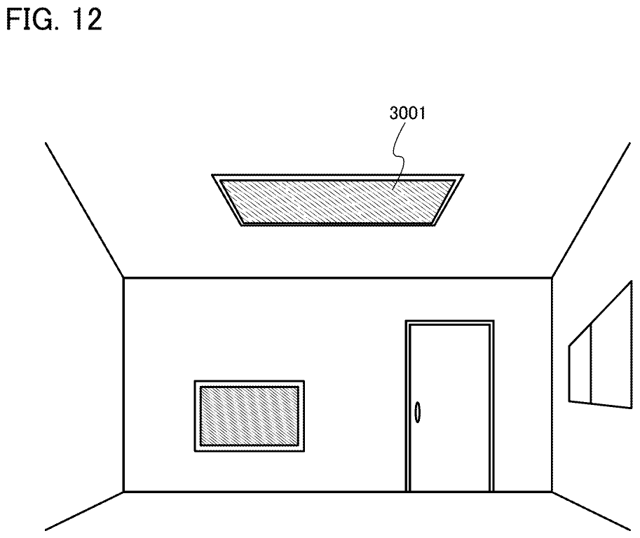

FIG. 12 illustrates an example in which the light-emitting device described in any one of Embodiments 1 to 6 is used for an indoor lighting device 3001. Since the light-emitting device described in any one of Embodiments 1 to 6 has high emission efficiency, the lighting device can have low power consumption. Furthermore, since the light-emitting device described in any one of Embodiments 1 to 6 can have a large area, the light-emitting device can be used for a large-area lighting device. Furthermore, since the light-emitting device described in any one of Embodiments 1 to 6 is thin, the light-emitting device can be used for a lighting device having a reduced thickness.

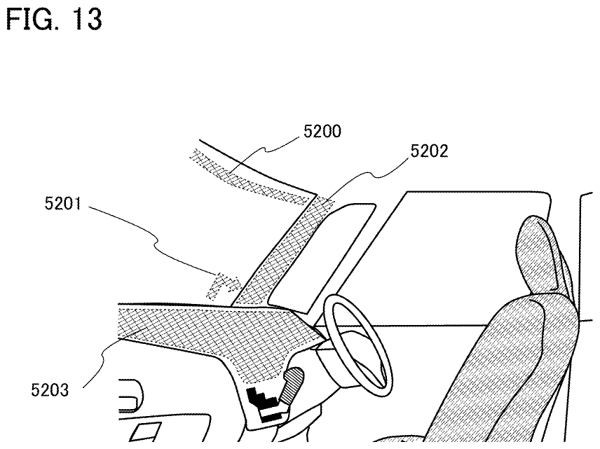

The light-emitting device described in any one of Embodiments 1 to 6 can also be used for an automobile windshield or an automobile dashboard. FIG. 13 illustrates one mode in which the light-emitting device described in any one of Embodiments 1 to 6 is used for an automobile windshield or an automobile dashboard. Display regions 5200 to 5203 each include the light-emitting device described in any one of Embodiments 1 to 6.

The display regions 5200 and 5201 are display devices which are provided in the automobile windshield and in which the light-emitting device described in any one of Embodiments 1 to 6 is incorporated. The light-emitting device described in any one of Embodiments 1 to 6 can be formed into what is called a see-through display device, through which the opposite side can be seen, by including a first electrode and a second electrode formed of electrodes having a light-transmitting property. Such see-through display devices can be provided even in the automobile windshield without hindering the view. In the case where a driving transistor or the like is provided, a transistor having a light-transmitting property, such as an organic transistor including an organic semiconductor material or a transistor including an oxide semiconductor, is preferably used.

A display device incorporating the light-emitting device described in any one of Embodiments 1 to 6 is provided in the display region 5202 in a pillar portion. The display region 5202 can compensate for the view hindered by the pillar by displaying an image taken by an imaging unit provided in the car body. Similarly, the display region 5203 provided in the dashboard portion can compensate for the view hindered by the car body by displaying an image taken by an imaging unit provided on the outside of the automobile. Thus, blind areas can be eliminated to enhance the safety. Images that compensate for the areas which a driver cannot see enable the driver to ensure safety easily and comfortably.

The display region 5203 can provide a variety of kinds of information by displaying navigation data, a speedometer, a tachometer, a mileage, a fuel meter, a gearshift state, air-condition setting, and the like. The content or layout of the display can be changed freely by a user as appropriate. Note that such information can also be displayed on the display regions 5200 to 5202. The display regions 5200 to 5203 can also be used as lighting devices.

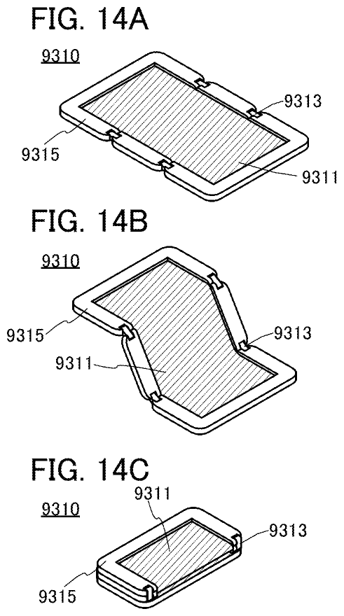

FIGS. 14A to 14C illustrate a foldable portable information terminal 9310. FIG. 14A illustrates the portable information terminal 9310 that is opened. FIG. 14B illustrates the portable information terminal 9310 that is being opened or being folded. FIG. 14C illustrates the portable information terminal 9310 that is folded. The portable information terminal 9310 is highly portable when folded. The portable information terminal 9310 is highly browsable when opened because of a seamless large display region.

A functional panel 9311 is supported by three housings 9315 joined together by hinges 9313. Note that the functional panel 9311 may be a touch panel (an input/output device) including a touch sensor (an input device). By folding the functional panel 9311 at the hinges 9313 between two housings 9315, the portable information terminal 9310 can be reversibly changed in shape from the opened state to the folded state. The light-emitting apparatus of one embodiment of the present invention can be used for the functional panel 9311.

Note that the structure described in this embodiment can be combined with any of the structures described in Embodiments 1 to 6 as appropriate.

As described above, the application range of the light-emitting apparatus including the light-emitting device described in any one of Embodiments 1 to 6 is wide, and thus the light-emitting apparatus can be applied to electronic devices in a variety of fields. By using the light-emitting device described in any one of Embodiments 1 to 6, an electronic device with low power consumption can be obtained.

Note that this embodiment can be combined with any of the other embodiments in this specification as appropriate.

### Example 1

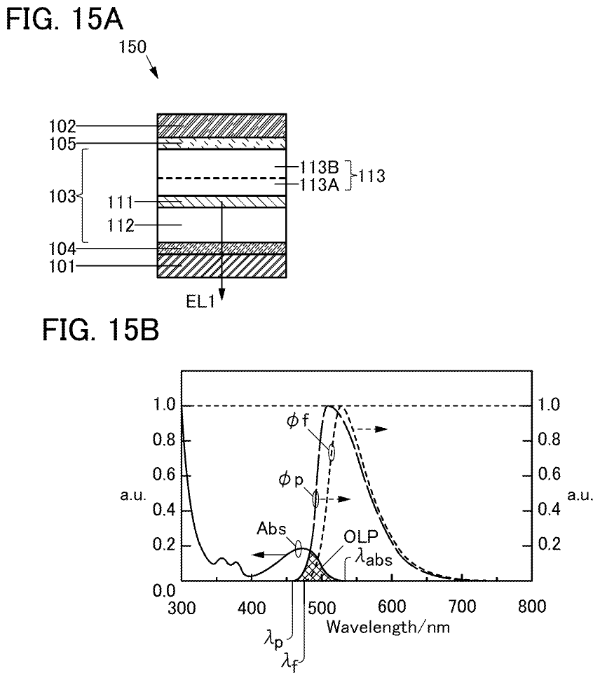

In this example, structures of a light-emitting device 21(11) to a light-emitting device 32(23) of one embodiment of the present invention, fabrication methods thereof, and characteristics thereof will be described with reference to FIGS. 15A and 15B to FIG. 57.

FIGS. 15A and 15B show the structure of the light-emitting devices 21(21), 22(21), and 32(21).

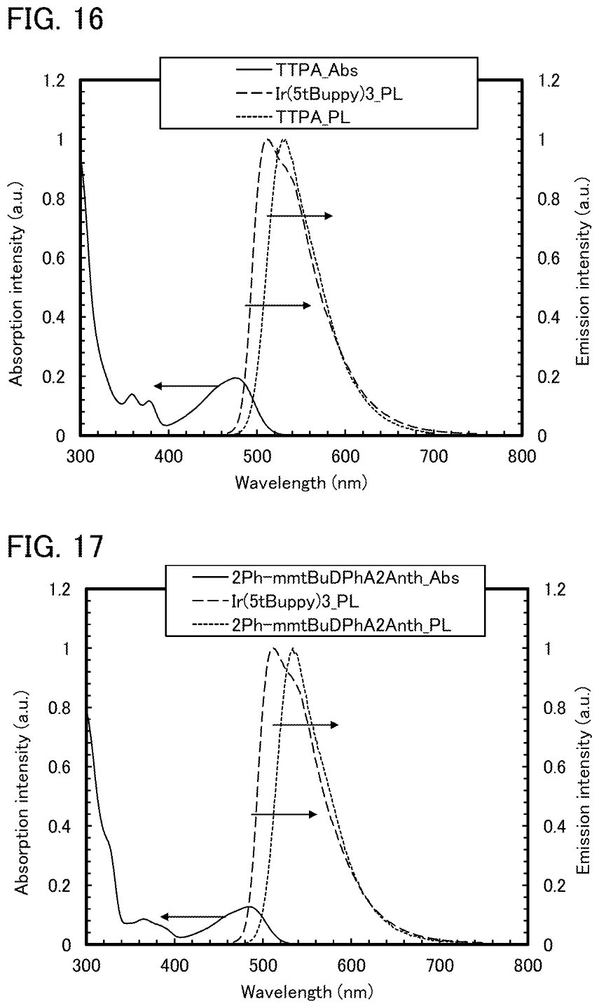

FIG. 16 shows an absorption spectrum of TTPA, an emission spectrum of Ir(5tBuppy)₃, and an emission spectrum of TTPA.

FIG. 17 shows an absorption spectrum of 2Ph-mmtBuDPhA2Anth, an emission spectrum of Ir(5tBuppy)₃, and an emission spectrum of 2Ph-mmtBuDPhA2Anth.

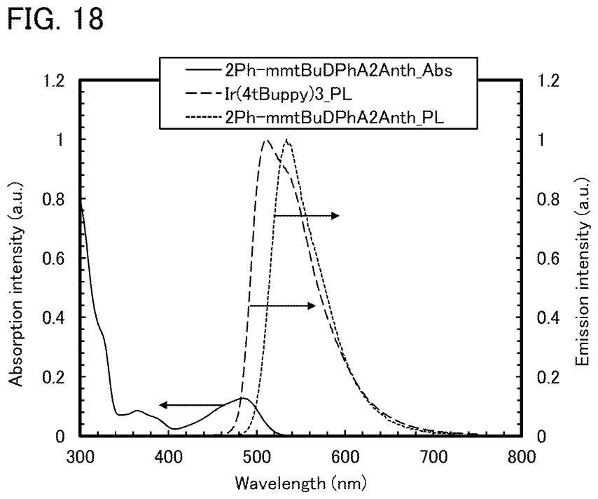

FIG. 18 shows an absorption spectrum of 2Ph-mmtBuDPhA2Anth, an emission spectrum of Ir(4tBuppy)₃, and an emission spectrum of 2Ph-mmtBuDPhA2Anth.

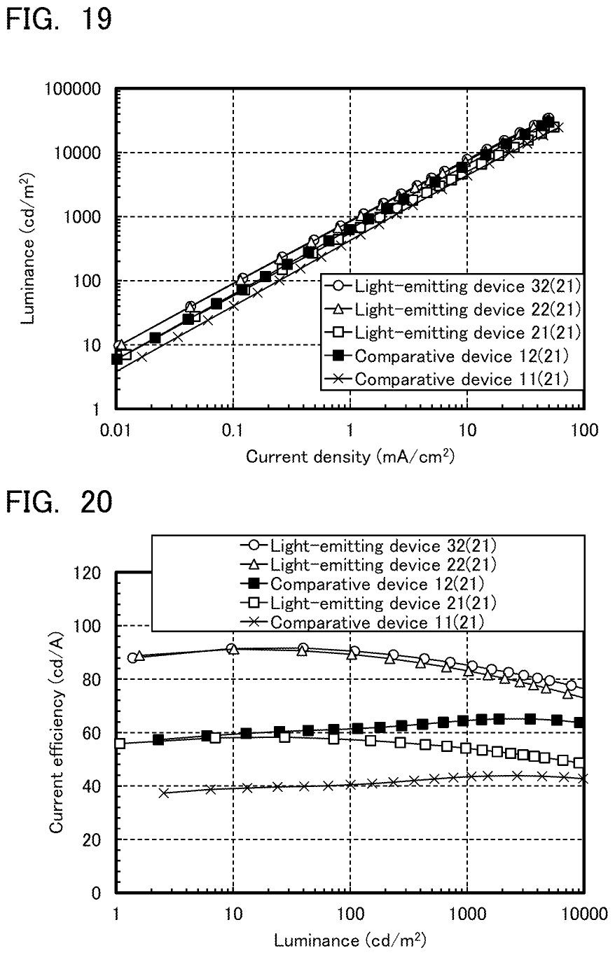

FIG. 19 shows luminance versus current density characteristics of the light-emitting devices 21(21), 22(21), and 32(21).

FIG. 20 shows current efficiency versus luminance characteristics of the light-emitting devices 21(21), 22(21), and 32(21).

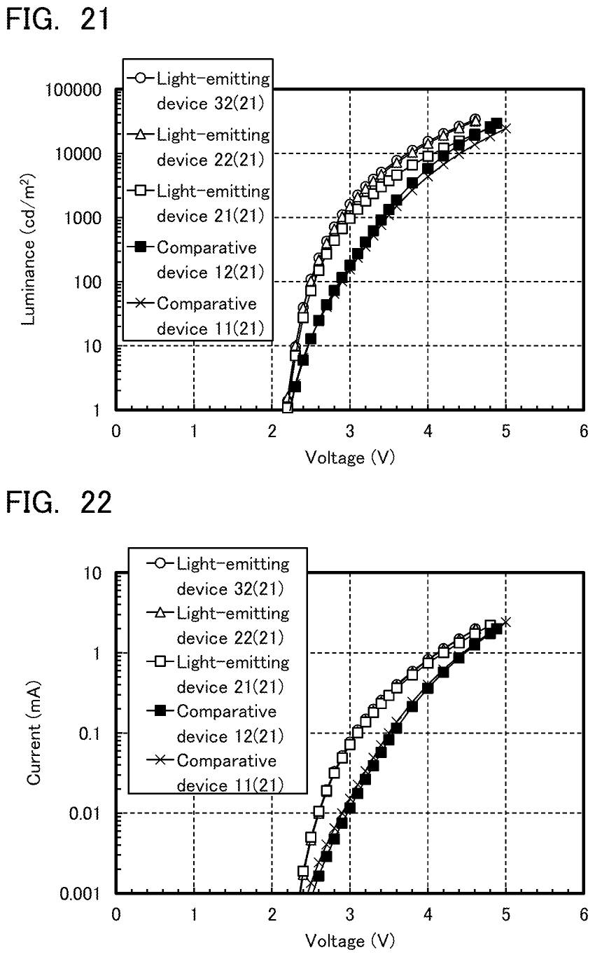

FIG. 21 shows luminance versus voltage characteristics of the light-emitting devices 21(21), 22(21), and 32(21).

FIG. 22 shows current versus voltage characteristics of the light-emitting devices 21(21), 22(21), and 32(21).

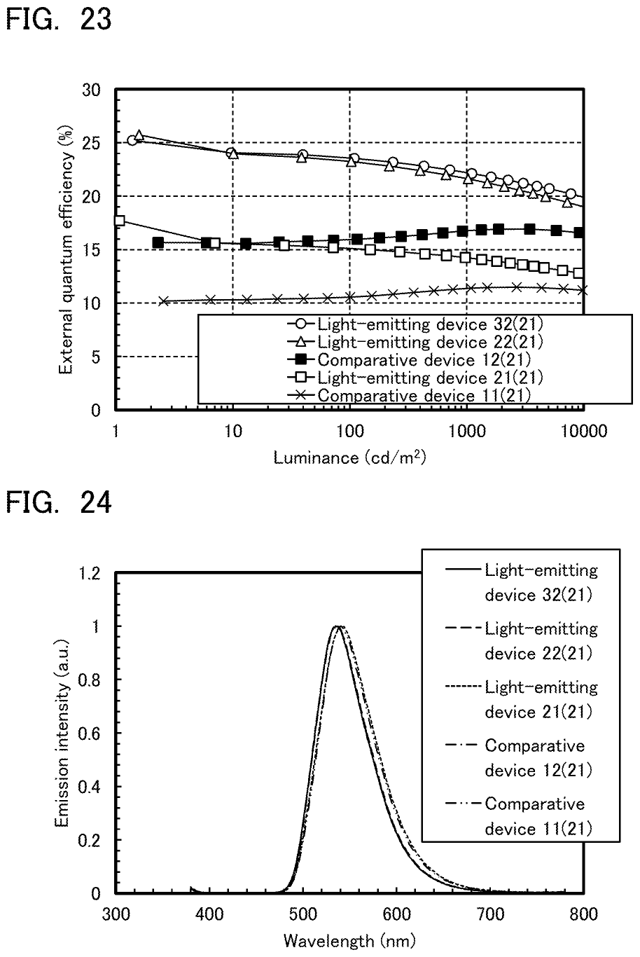

FIG. 23 shows external quantum efficiency versus luminance characteristics of the light-emitting devices 21(21), 22(21), and 32(21). Note that the external quantum efficiency was calculated from luminance assuming that the light distribution characteristics of the light-emitting devices are Lambertian type.

FIG. 24 shows emission spectra of the light-emitting devices 21(21), 22(21), and 32(21) under the condition where light was emitted at a luminance of 1000 cd/m².

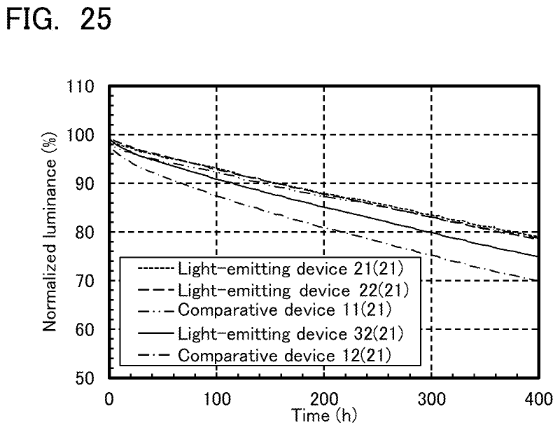

FIG. 25 shows time dependence of normalized luminance characteristics of the light-emitting devices 21(21), 22(21), and 32(21) under the condition where light was emitted at a constant current density of 50 mA/cm².

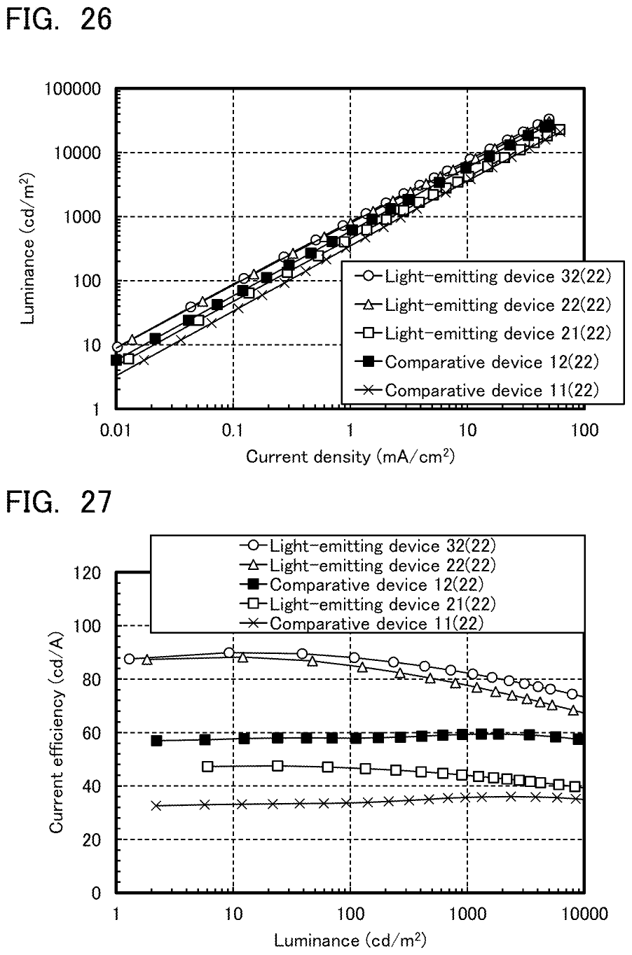

FIG. 26 shows luminance versus current density characteristics of the light-emitting devices 21(22), 22(22), and 32(22).

FIG. 27 shows current efficiency versus luminance characteristics of the light-emitting devices 21(22), 22(22), and 32(22).

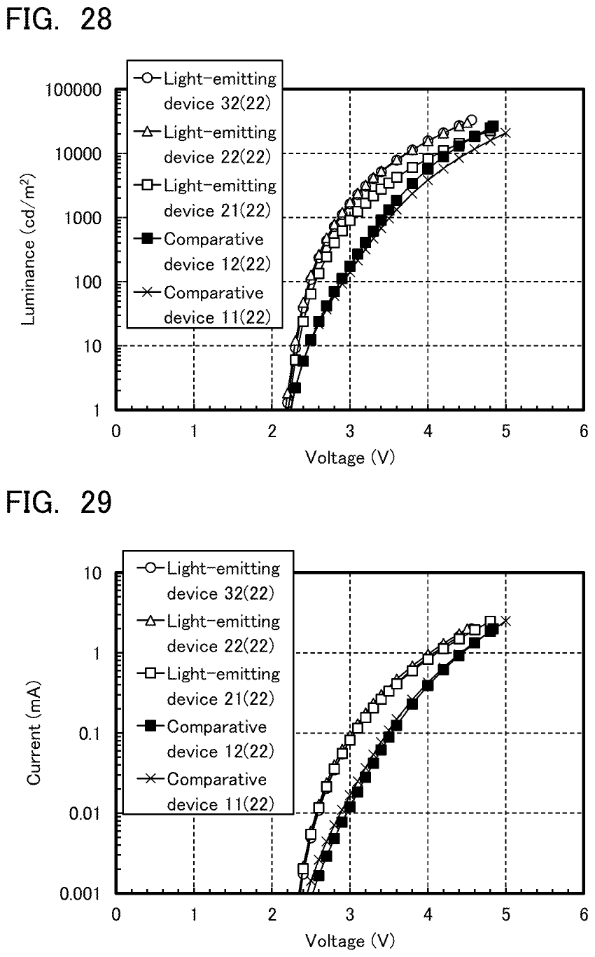

FIG. 28 shows luminance versus voltage characteristics of the light-emitting devices 21(22), 22(22), and 32(22).

FIG. 29 shows current versus voltage characteristics of the light-emitting devices 21(22), 22(22), and 32(22).

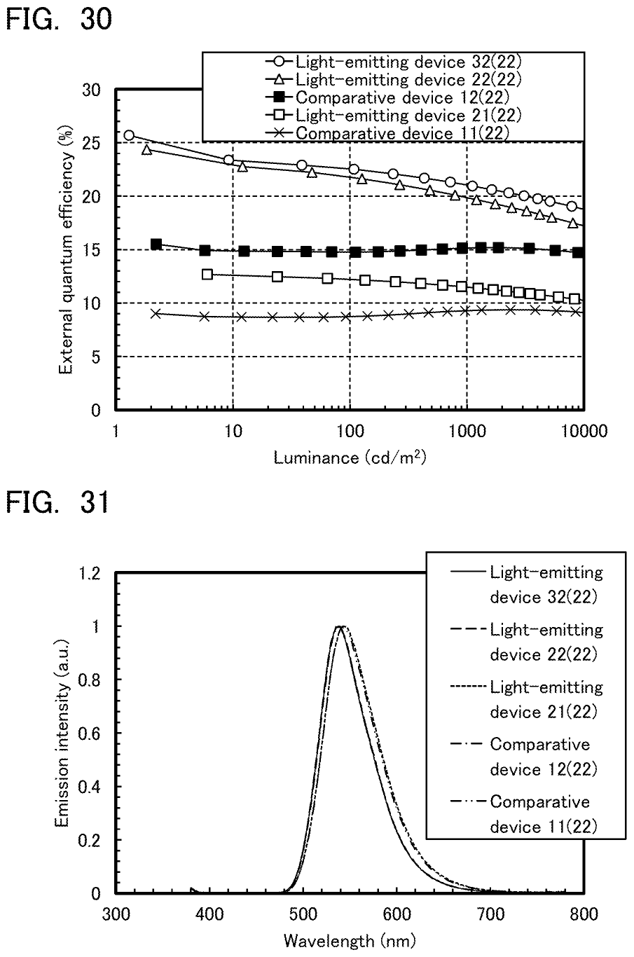

FIG. 30 shows external quantum efficiency versus luminance characteristics of the light-emitting devices 21(22), 22(22), and 32(22). Note that the external quantum efficiency was calculated from luminance assuming that the light distribution characteristics of the light-emitting devices are Lambertian type.

FIG. 31 shows emission spectra of the light-emitting devices 21(22), 22(22), and 32(22) under the condition where light was emitted at a luminance of 1000 cd/m².

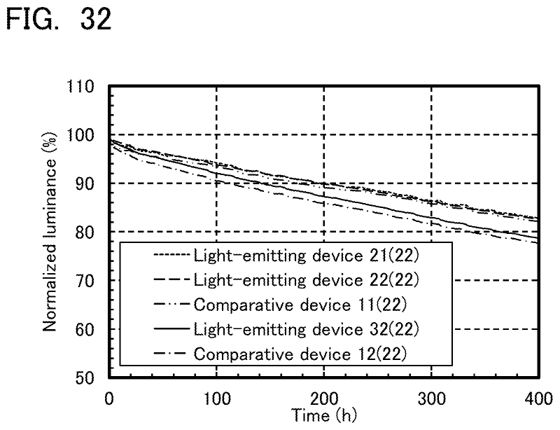

FIG. 32 shows time dependence of normalized luminance characteristics of the light-emitting devices 21(22), 22(22), and 32(22) under the condition where light was emitted at a constant current density of 50 mA/cm².

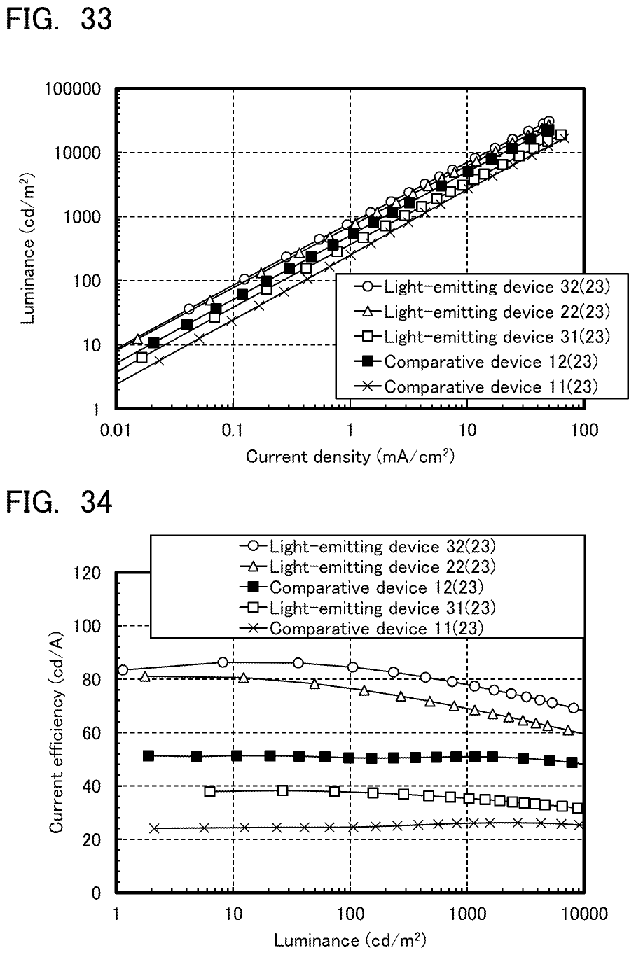

FIG. 33 shows luminance versus current density characteristics of the light-emitting devices 21(23), 22(23), and 32(23).

FIG. 34 shows current efficiency versus luminance characteristics of the light-emitting devices 21(23), 22(23), and 32(23).

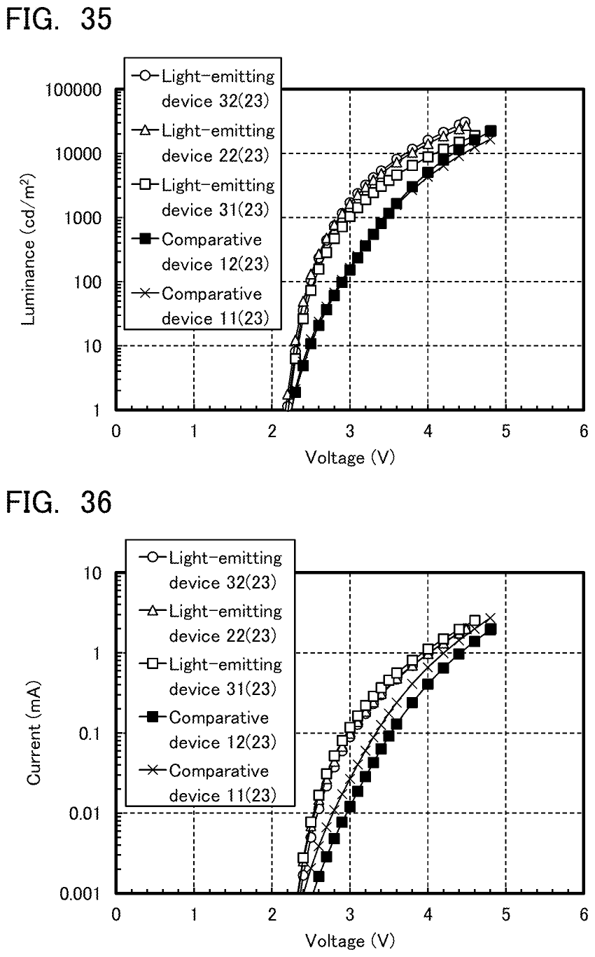

FIG. 35 shows luminance versus voltage characteristics of the light-emitting devices 21(23), 22(23), and 32(23).

FIG. 36 shows current versus voltage characteristics of the light-emitting devices 21(23), 22(23), and 32(23).

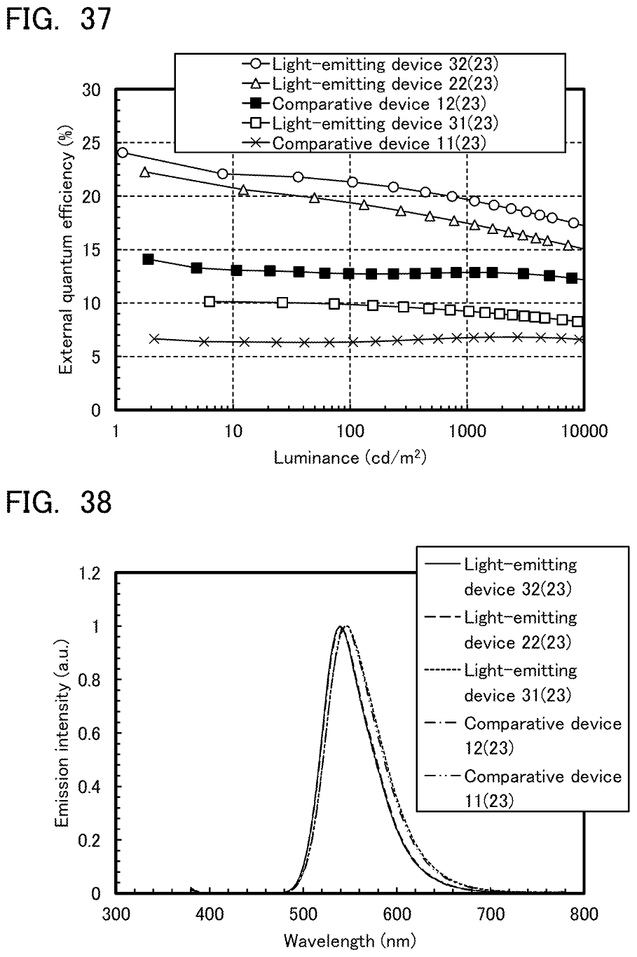

FIG. 37 shows external quantum efficiency versus luminance characteristics of the light-emitting devices 21(23), 22(23), and 32(23). Note that the external quantum efficiency was calculated from luminance assuming that the light distribution characteristics of the light-emitting devices are Lambertian type.

FIG. 38 shows emission spectra of the light-emitting devices 21(23), 22(23), and 32(23) under the condition where light was emitted at a luminance of 1000 cd/m².

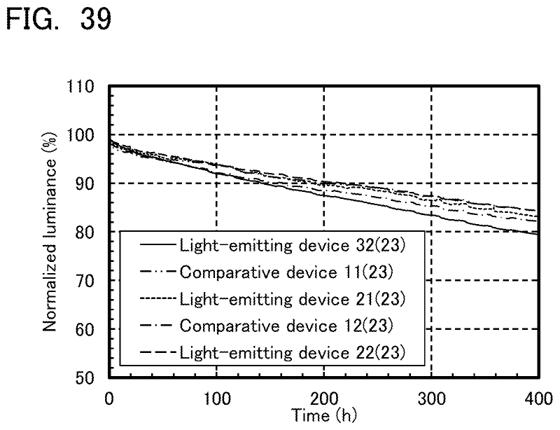

FIG. 39 shows time dependence of normalized luminance characteristics of the light-emitting devices 21(23), 22(23), and 32(23) under the condition where light was emitted at a constant current density of 50 mA/cm².

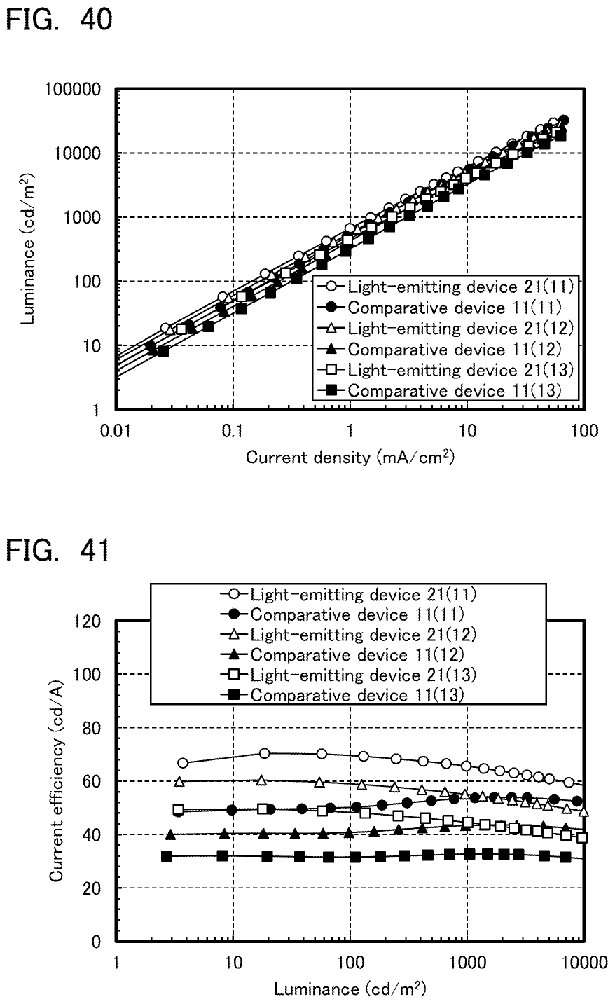

FIG. 40 shows luminance versus current density characteristics of the light-emitting devices 21(11), 21(12), and 21(13).

FIG. 41 shows current efficiency versus luminance characteristics of the light-emitting devices 21(11), 21(12), and 21(13).

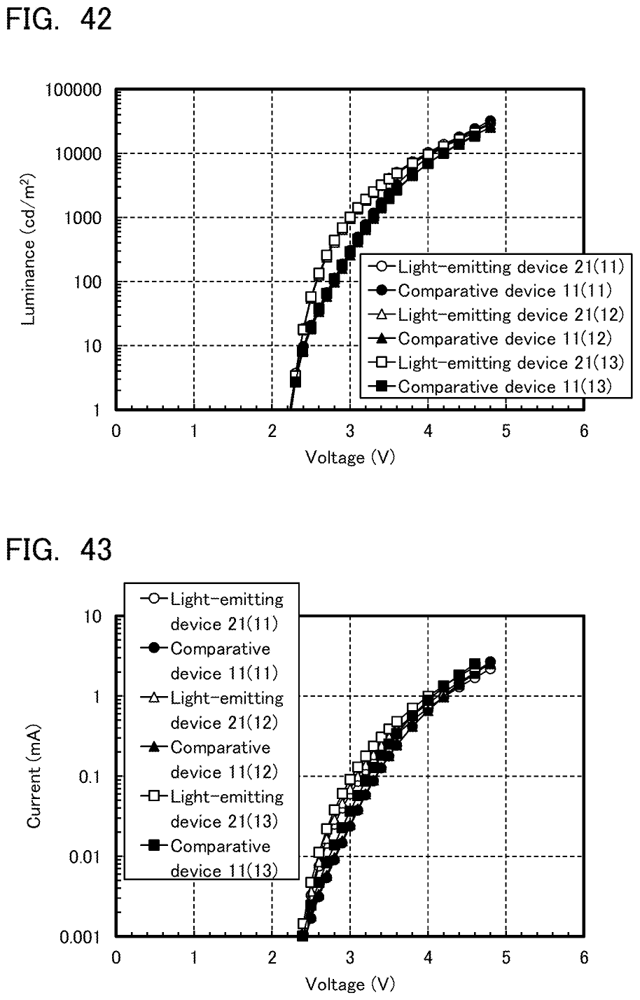

FIG. 42 shows luminance versus voltage characteristics of the light-emitting devices 21(11), 21(12), and 21(13).

FIG. 43 shows current versus voltage characteristics of the light-emitting devices 21(11), 21(12), and 21(13).

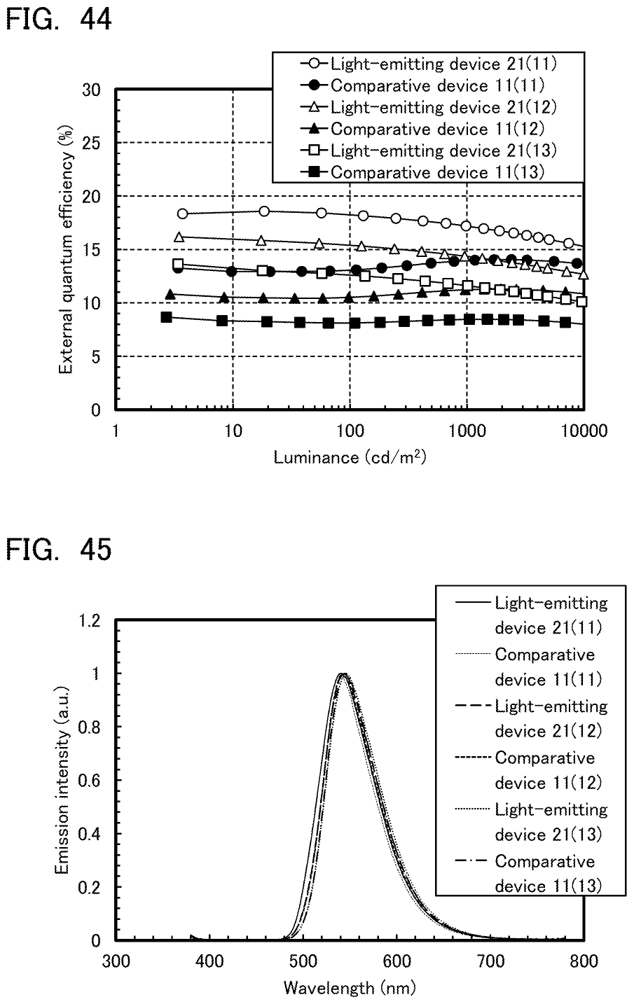

FIG. 44 shows external quantum efficiency versus luminance characteristics of the light-emitting devices 21(11), 21(12), and 21(13). Note that the external quantum efficiency was calculated from luminance assuming that the light distribution characteristics of the light-emitting devices are Lambertian type.

FIG. 45 shows emission spectra of the light-emitting devices 21(11), 21(12), and 21(13) under the condition where light was emitted at a luminance of 1000 cd/m².

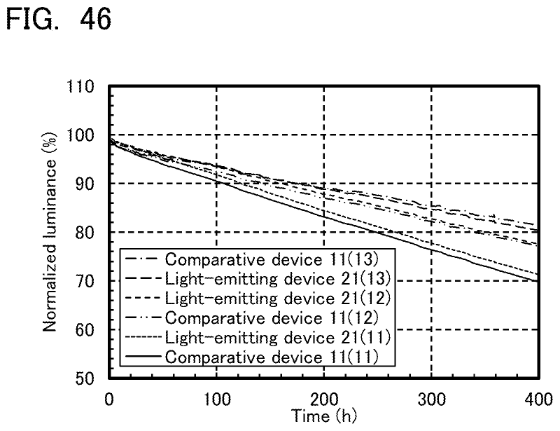

FIG. 46 shows time dependence of normalized luminance characteristics of the light-emitting devices 21(11), 21(12), and 21(13) under the condition where light was emitted at a constant current density of 50 mA/cm².

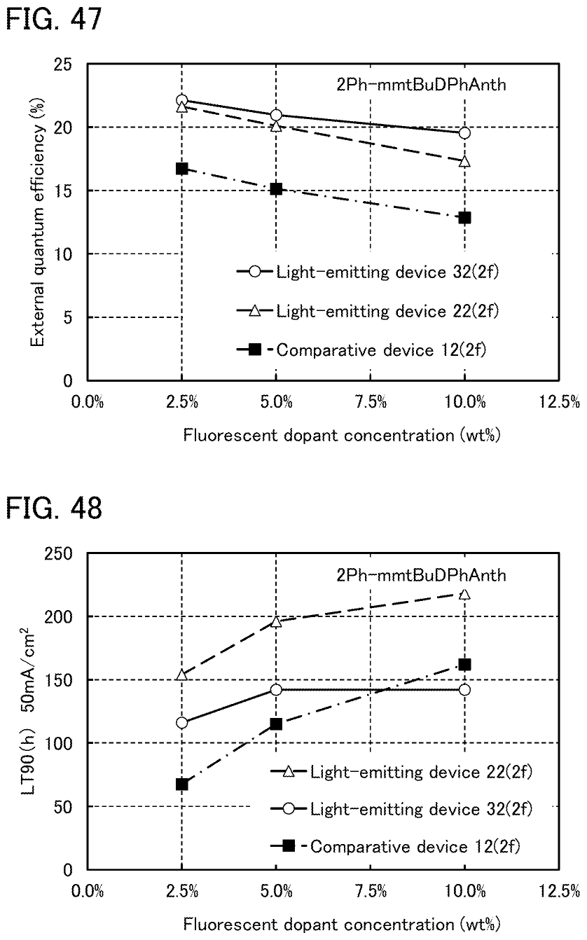

In FIG. 47, the external quantum efficiency is plotted with respect to the concentration of the light-emitting material FM under the condition where each of the light-emitting devices 22(21) to 22(23) and 32(21) to 32(23) emitted light at approximately 1000 cd/m².

In FIG. 48, the time for the luminance to drop to 90% of its initial value is plotted with respect to the concentration of the light-emitting material FM under the condition where each of the light-emitting devices 22(21) to 22(23) and 32(21) to 32(23) emitted light at a constant current density of 50 mA/cm².

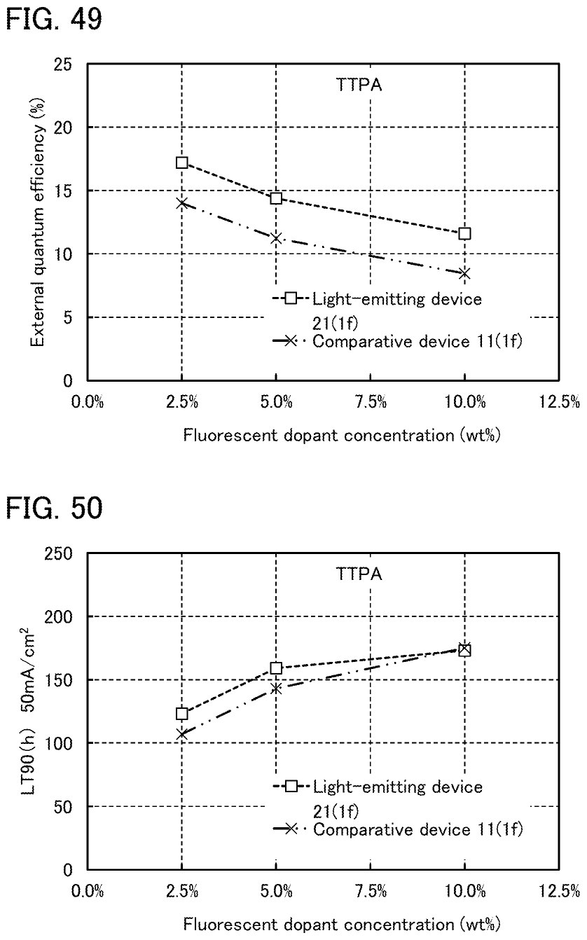

In FIG. 49, the external quantum efficiency is plotted with respect to the concentration of the light-emitting material FM under the condition where each of the light-emitting devices 21(11) to 21(13) emitted light at approximately 1000 cd/m².

In FIG. 50, the time for the luminance to drop to 90% of its initial value is plotted with respect to the concentration of the light-emitting material FM under the condition where each of the light-emitting devices 21(11) to 21(13) emitted light at a constant current density of 50 mA/cm².

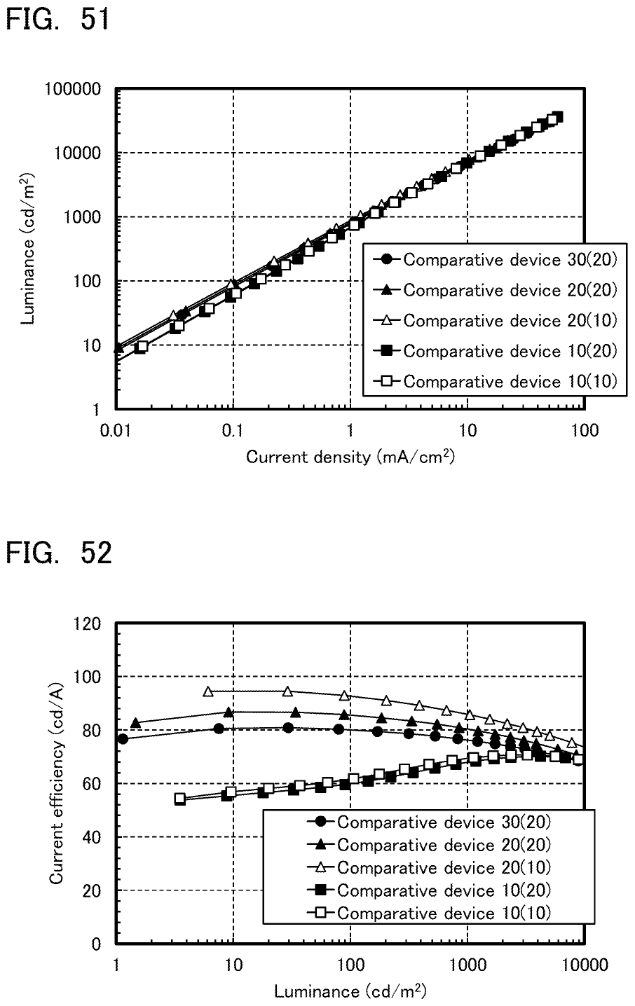

FIG. 51 shows luminance versus current density characteristics of the comparative devices 10(10) to 30(20).

FIG. 52 shows current efficiency versus luminance characteristics of the comparative devices 10(10) to 30(20).

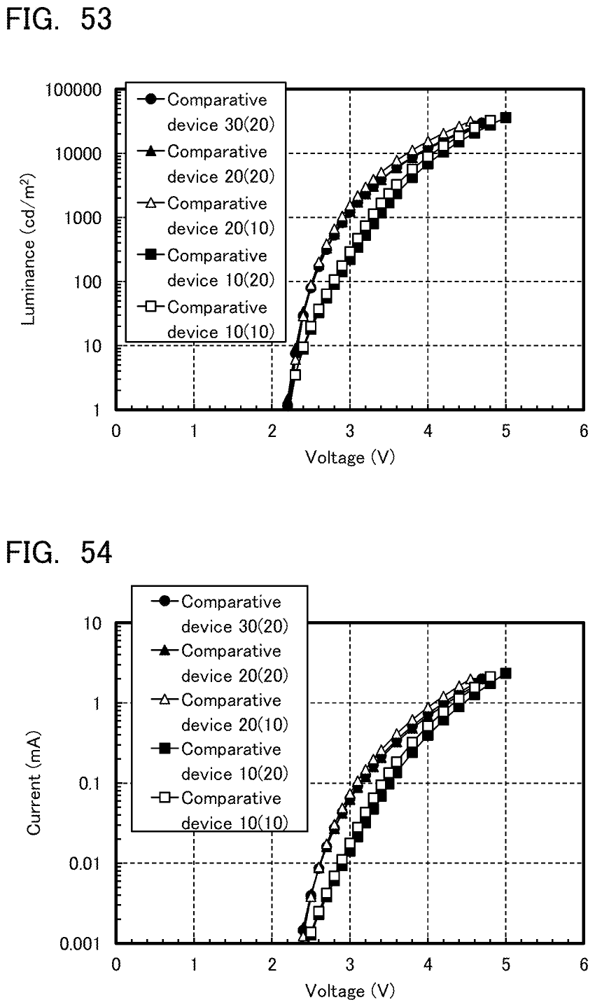

FIG. 53 shows luminance versus voltage characteristics of the comparative devices 10(10) to 30(20).

FIG. 54 shows current versus voltage characteristics of the comparative devices 10(10) to 30(20).

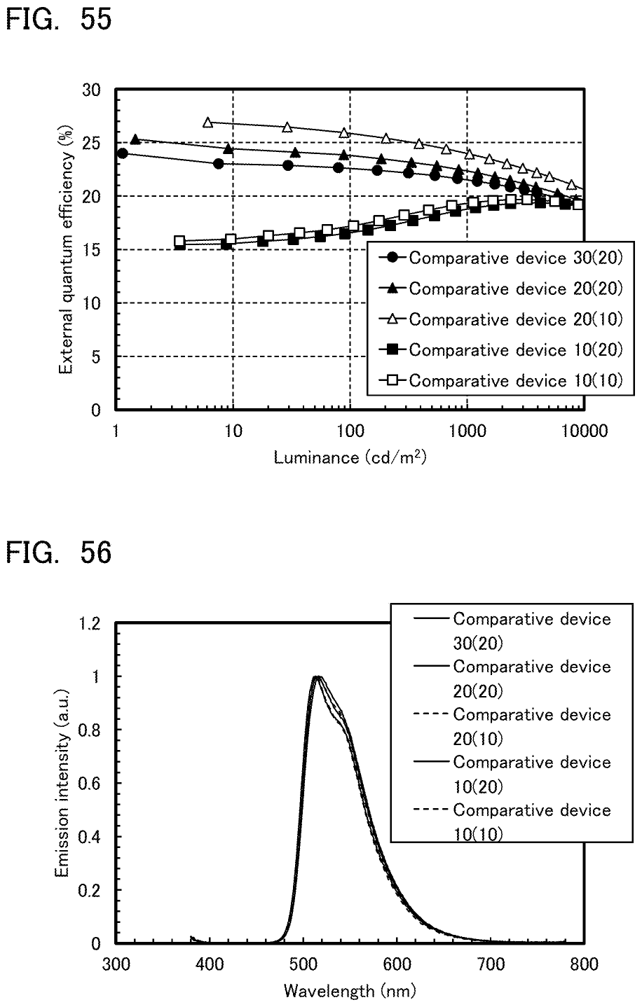

FIG. 55 shows external quantum efficiency versus luminance characteristics of the comparative devices 10(10) to 30(20). Note that the external quantum efficiency was calculated from luminance assuming that the light distribution characteristics of the light-emitting devices are Lambertian type

FIG. 56 shows emission spectra of the comparative devices 10(10) to 30(20) under the condition where light was emitted at a luminance of 1000 cd/m².

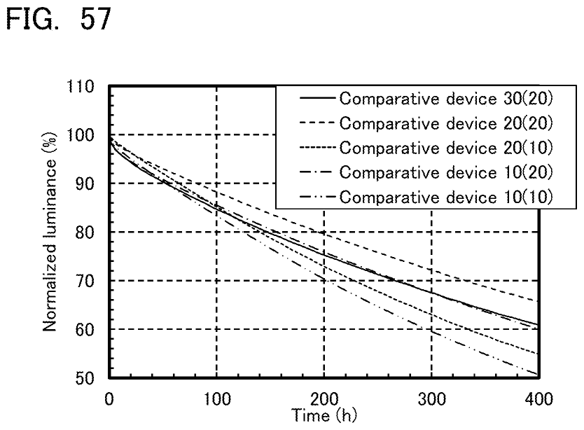

FIG. 57 shows time dependence of normalized luminance characteristics of the comparative devices 10(10) to 30(20) under the condition where light was emitted at a constant current density of 50 mA/cm².

### <Light-Emitting Devices 21(11) to 32(23)>

The light-emitting devices 21(11) to 32(23) described and fabricated in this example each include the electrode 101, the electrode 102, and the unit 103, and the electrode 102 includes the region overlapping with the electrode 101 (see FIG. 15A).

The unit 103 includes a region interposed between the electrode 101 and the electrode 102. The unit 103 includes the layer 111, the layer 112, and the layer 113.

The layer 111 includes the region interposed between the layer 112 and the layer 113, and the layer 111 includes the energy donor material ED and the light-emitting material FM. Note that the organometallic complex was used as the energy donor material ED.

The organometallic complex includes a ligand, and the ligand has at least one substituent R¹ selected from a branched alkyl group, a substituted or unsubstituted cycloalkyl group, and a trialkylsilyl group. When the ligand has a branched alkyl group, the number of carbon atoms is 3 to 12. When the ligand has a cycloalkyl group, the number of carbon atoms is 3 to 10. When the ligand has a trialkylsilyl group, the number of carbon atoms is from 3 to 12.

The organometallic complex has a function of emitting phosphorescence at room temperature, and the phosphorescence has a spectrum with the shortest-wavelength edge at the wavelength λp (nm) (see FIG. 15B).

The light-emitting material FM has a function of emitting fluorescence, and the light-emitting material FM has an absorption spectrum with the longest-wavelength edge at the wavelength λabs (nm). The wavelength λabs (nm) is longer than the wavelength λp (nm).

### <<Structure of Light-Emitting Devices 21(11) to 21(23)>>

Table 1 shows structures of the light-emitting devices 21(11), 21(12), 21(13), 21(21), 21(22), and 21(23). Structural formulae of materials used in the light-emitting devices described in this example are shown below. Note that in the tables in this example, subscript and superscript characters are written in ordinary size for convenience. For example, a subscript character in an abbreviation or a superscript character in a unit are written in ordinary size in the tables. The corresponding description in the specification gives an accurate reading of such notations in the tables.

FIG. 16 shows a phosphorescence spectrum of the energy donor material ED in a dichloromethane solution, an absorption spectrum of the light-emitting material FM in a toluene solution, and an emission spectrum of the light-emitting material FM in the toluene solution (see FIG. 16). The phosphorescence spectrum of the energy donor material ED, the absorption spectrum of the light-emitting material FM, and the emission spectrum of the light-emitting material FM were measured at room temperature using a fluorescence spectrophotometer (FP-8600, produced by JASCO Corporation), an ultraviolet-visible spectrophotometer (V550, produced by JASCO Corporation), and (FS920, produced by Hamamatsu Photonics K.K.), respectively. The absorption spectrum of TTPA includes a region overlapping with the phosphorescence spectrum of Ir(5tBuppy)₃. This region is in the absorption band of the absorption spectrum that is positioned in the longest wavelength range. The absorption spectrum of TTPA has the longest-wavelength edge at 514 nm. The phosphorescence spectrum of Ir(5tBuppy)₃ also has the shortest-wavelength edge at 484 nm. The emission spectrum of TTPA also has the shortest-wavelength edge at 495 nm. The longest-wavelength edge of the absorption spectrum of TTPA is at a wavelength longer than the wavelength of the shortest-wavelength edge of the phosphorescence spectrum of Ir(5tBuppy)₃. When 514 (nm) is assigned to the wavelength λabs and 484 (nm) is assigned to the wavelength λp, the solution of Formula (3) shown below is 0.15. When 484 (nm) is assigned to the wavelength λp and 495 (nm) is assigned to the wavelength Δf, the solution of Formula (4) shown below is 0.057. The wavelength of the shortest-wavelength edge is regarded as a wavelength at the intersection of the horizontal axis and a tangent to the wavelength in the shortest wavelength range at the point where the slope of the tangent of the spectrum has a maximum value. The wavelength of the longest-wavelength edge is regarded as a wavelength at the intersection of the horizontal axis and a tangent to the wavelength in the longest wavelength range at the point where the slope of the tangent of the spectrum has a minimum value.

$$\begin{matrix}[ Formula 3 ] & \\ 1240 \times ( \frac{1}{{λ}_{p}} - \frac{1}{{λ}_{abs}} ) & ( 3 ) \\ [ Formula 4 ] & \\ 1240 \times ( \frac{1}{{λ}_{p}} - \frac{1}{{λ}_{f}} ) & ( 4 )\end{matrix}$$

TABLE 1

| | | | Composition | Thickness/ |
|---|---|---|---|---|
| Structure | Numeral | Material | ratio | nm |
| Electrode | 102 | Al | | 200 |
| Layer | 105 | LiF | | 1 |
| Layer | 113B | NBPhen | | 10 |
| Layer | 113A | mPCCzPTzn-02 | | 20 |
| Layer | 111 | mPCCzPTzn-02:PCCP: | 0.5:0.5:e:f | 40 |
| | | Ir(5tBuppy)3:TTPA | | |
| Layer | 112 | PCBBi1BP | | 20 |
| Layer | 104 | DBT3P II:MoOx | 1:0.5 | 40 |
| Electrode | 101 | ITSO | | 70 |

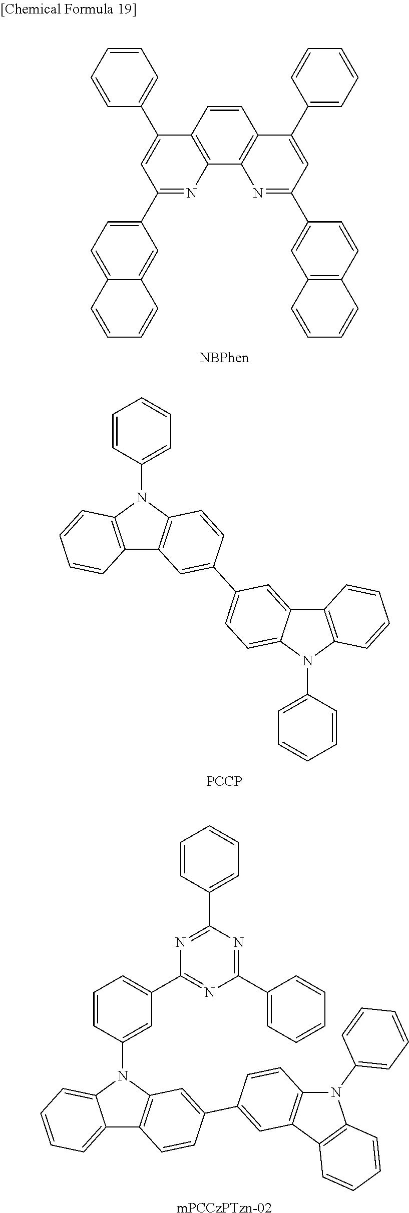 [SMILES: c1ccc(-c2cc(-c3ccc4ccccc4c3)nc3c2ccc2c(-c4ccccc4)cc(-c4ccc5ccccc5c4)nc23)cc1 ; c1ccc(-n2c3ccccc3c3cc(-c4ccc5c(c4)c4ccccc4n5-c4ccccc4)ccc32)cc1 ; "PCCP" ; c1ccc(-c2nc(-c3ccccc3)nc(-c3cccc(-n4c5ccccc5c5ccc(-c6ccc7c(c6)c6ccccc6n7-c6ccccc6)cc54)c3)n2)cc1 ; "mPCCzPTzn-02"]

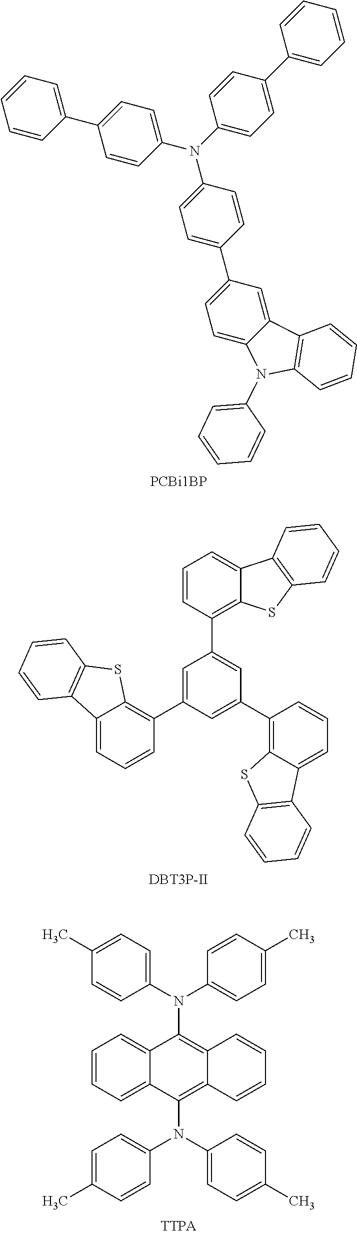

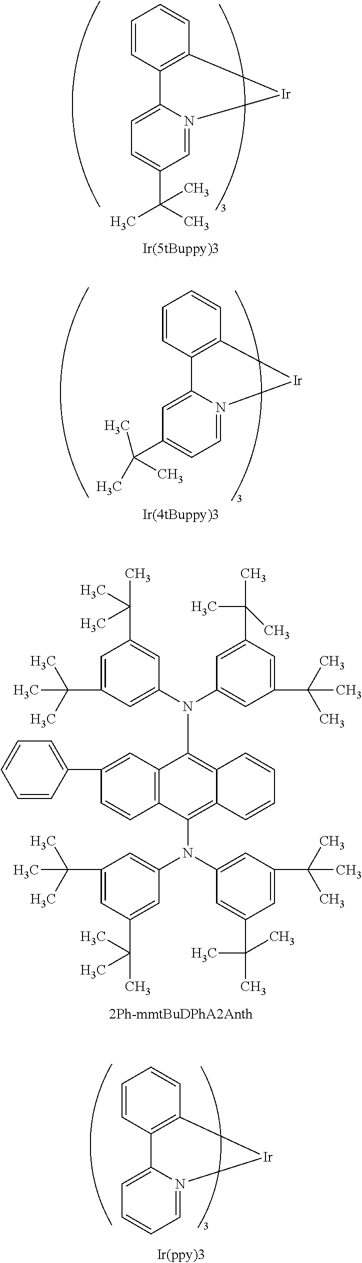

### <<Fabrication Method of Light-Emitting Devices 21(11) to 21(23)>>

The light-emitting devices 21(11) to 21(23) described in this example were fabricated by a method including steps described below.

### [First Step]

In a first step, the electrode 101 was formed. Specifically, the electrode 101 was formed by a sputtering method using indium oxide-tin oxide containing silicon or silicon oxide (abbreviation: ITSO) as a target.

Note that the electrode 101 includes ITSO and has a thickness of 70 nm.

### [Second Step]

In a second step, the layer 104 was formed over the electrode 101. Specifically, materials were co-deposited by a resistance-heating method.

The layer 104 includes 4,4′,4″-(benzene-1,3,5-triyl)tri(dibenzothiophene) (abbreviation: DBF3PII) and molybdenum oxide (abbreviation: MoOₓ) at a weight ratio of 1:0.5 and has a thickness of 40 nm.

### [Third Step]

In a third step, the layer 112 was formed over the layer 104. Specifically, materials were co-deposited by a resistance-heating method.

Note that layer 112 includes 4,4′-diphenyl-4″-(9-phenyl-9H-carbazol-3-yl)triphenylamine (abbreviation: PCBBi1BP) and has a thickness of 20 nm.

### [Fourth Step]

In a fourth step, the layer 111 was formed over the layer 112. Specifically, materials were co-deposited by a resistance-heating method.

The layer 111 includes 9-[3-(4,6-diphenyl-1,3,5-triazin-2-yl)phenyl]-9′-phenyl-2,3′-bi-9H-carbazole (abbreviation: mPCCzPTzn-02), 3,3′-bis(9-phenyl-9H-carbazole) (abbreviation: PCCP), tris[2-[5-(tert-butyl)-2-pyridinyl-κN]phenyl-κC]iridium (abbreviation: Ir(5tBuppy)₃), and N,N,N′,N′-tetrakis(4-methylphenyl)-9,10-anthracenediamine (abbreviation: TTPA) at a weight ratio of 0.5:0.5:e:f and has a thickness of 40 nm. Table 2 shows the values e and f of the light-emitting devices.

TABLE 2

| | Ir(5tBuppy)3 | TTPA |
|---|---|---|
| | Weight ratio e | Weight ratio f |
| Light-emitting device 21(11) | 0.05 | 0.025 |
| Light-emitting device 21(12) | 0.05 | 0.05 |
| Light-emitting device 21(13) | 0.05 | 0.1 |
| Light-emitting device 21(21) | 0.1 | 0.025 |
| Light-emitting device 21(22) | 0.1 | 0.05 |
| Light-emitting device 21(23) | 0.1 | 0.1 |

### [Fifth Step]

In a fifth step, a layer 113A was formed over the layer 111. Specifically, materials were co-deposited by a resistance-heating method.

Note that the layer 113A includes mPCCzPTzn-02 and has a thickness of 20 nm.

### [Sixth Step]

In a sixth step, a layer 113B was formed over the layer 113A. Specifically, materials were co-deposited by a resistance-heating method.

The layer 113B includes 2,9-bis(naphthalen-2-yl)-4,7-diphenyl-1,10-phenanthroline (abbreviation: NBPhen) and has a thickness of 10 nm.

### [Seventh Step]

In a seventh step, the layer 105 was formed over the layer 113B. Specifically, materials were co-deposited by a resistance-heating method.

Note that the layer 105 includes lithium fluoride (abbreviation: LiF) and has a thickness of 1 nm.

### [Eighth Step]

In an eighth step, the electrode 102 was formed over the layer 105. Specifically, a material of the electrode was deposited by a resistance-heating method.

Note that the electrode 102 includes Al and has a thickness of 200 nm.

### <<Structure of Light-Emitting Devices 22(21) to 22(23)>>

Table 3 shows structures of the light-emitting devices 22(21), 22(22), and 22(23).

FIG. 17 shows a phosphorescence spectrum of the energy donor material ED, an absorption spectrum of the light-emitting material FM, and an emission spectrum of the light-emitting material FM (see FIG. 17). The absorption spectrum of 2Ph-mmtBuDPhA2Anth includes a region overlapping with the phosphorescence spectrum of Ir(5tBuppy)₃. This region is in the absorption band of the absorption spectrum that is positioned in the longest wavelength range. The absorption spectrum of 2Ph-mmtBuDPhA2Anth has the longest-wavelength edge at 519 nm. The phosphorescence spectrum of Ir(5tBuppy)₃ also has the shortest-wavelength edge at 484 nm. The fluorescence spectrum of 2Ph-mmtBuDPhA2Anth also has the shortest-wavelength edge at 501 nm. The longest-wavelength edge of the absorption spectrum of 2Ph-mmtBuDPhA2Anth is at a wavelength longer than the wavelength of the shortest-wavelength edge of the phosphorescence spectrum of Ir(5tBuppy)₃. When 519 (nm) is assigned to the wavelength λabs and 484 (nm) is assigned to the wavelength λp, the solution of Formula (3) shown below is 0.17. When 484 (nm) is assigned to the wavelength λp and 501 (nm) is assigned to the wavelength Δf, the solution of Formula (4) shown below is 0.087.

$$\begin{matrix}[ Formula 3 ] & \\ 1240 \times ( \frac{1}{{λ}_{p}} - \frac{1}{{λ}_{abs}} ) & ( 3 ) \\ [ Formula 4 ] & \\ 1240 \times ( \frac{1}{{λ}_{p}} - \frac{1}{{λ}_{f}} ) & ( 4 )\end{matrix}$$

TABLE 3

| | | | Composition | Thickness/ |
|---|---|---|---|---|
| Structure | Numeral | Material | ratio | nm |
| Electrode | 102 | Al | | 200 |
| Layer | 105 | LiF | | 1 |
| Layer | 113B | NBPhen | | 10 |
| Layer | 113A | mPCCzPTzn-02 | | 20 |
| Layer | 111 | mPCCzPTzn-02:PCCP: | 0.5:0.5:0.1:f | 40 |
| | | Ir(5tBuppy)3: | | |
| | | 2Ph-mmtBuDPhA2Anth | | |
| Layer | 112 | PCBBi1BP | | 20 |
| Layer | 104 | DBT3P II:MoOx | 1:0.5 | 40 |
| Electrode | 101 | ITSO | | 70 |

### <<Fabrication Method of Light-Emitting Devices 22(21) to 22(23)>>

The light-emitting devices 22(21) to 22(23) described in this example were fabricated by a method including steps described below.

Note that the fabrication method of the light-emitting devices 22(21) to 22(23) differs from that of the light-emitting devices 21(11) to 21(23) in that N,N′-bis(3,5-di-tert-butylphenyl)-N,N′-bis[3,5-bis(3,5-di-tert-butylphenyl)phenyl]-2-phenylanthracene-9,10-diamine (abbreviation: 2Ph-mmtBuDPhA2Anth) is used instead of TTPA in the step of forming the layer 111. Different portions will be described in detail below, and the above description is referred to for the other similar portions.

### [Fourth Step]

In a fourth step, the layer 111 was formed over the layer 112. Specifically, materials were co-deposited by a resistance-heating method.

The layer 111 includes mPCCzPTzn-02, PCCP, Ir(5tBuppy)₃, and 2Ph-mmtBuDPhA2Anth at a weight ratio of 0.5:0.5:0.1:f and has a thickness of 40 nm. Table 4 shows values f of the light-emitting devices.

TABLE 4

| | Ir(5tBuppy)3 | 2Ph-mmtBuDPhA2Anth |
|---|---|---|
| | Weight ratio e | Weight ratio f |
| Light-emitting device 22(21) | 0.1 | 0.025 |
| Light-emitting device 22(22) | 0.1 | 0.05 |
| Light-emitting device 22(23) | 0.1 | 0.1 |

### <<Structure of Light-Emitting Devices 32(21) to 32(23)>>

Table 5 shows structures of the light-emitting devices 32(21), 32(22), and 32(23).

FIG. 18 shows a phosphorescence spectrum of the energy donor material ED, an absorption spectrum of the light-emitting material FM, and an emission spectrum of the light-emitting material FM. The absorption spectrum of 2Ph-mmtBuDPhA2Anth includes a region overlapping with the phosphorescence spectrum of Ir(4tBuppy)₃. This region is in the absorption band of the absorption spectrum that is positioned in the longest wavelength range. The absorption spectrum of 2Ph-mmtBuDPhA2Anth has the longest-wavelength edge at 519 nm. The phosphorescence spectrum of Ir(4tBuppy)₃ also has the shortest-wavelength edge at 482 nm. The fluorescence spectrum of 2Ph-mmtBuDPhA2Anth also has the shortest-wavelength edge at 501 nm. The longest-wavelength edge of the absorption spectrum of 2Ph-mmtBuDPhA2Anth is at a wavelength longer than the wavelength of the shortest-wavelength edge of the phosphorescence spectrum of Ir(4tBuppy)₃. When 519 (nm) is assigned to the wavelength λabs and 482 (nm) is assigned to the wavelength λp, the solution of Formula (3) shown below is 0.18. When 482 (nm) is assigned to the wavelength λp and 501 (nm) is assigned to the wavelength Δf, the solution of Formula (4) shown below is 0.098.

$$\begin{matrix}[ Formula 3 ] & \\ 1240 \times ( \frac{1}{{λ}_{p}} - \frac{1}{{λ}_{abs}} ) & ( 3 ) \\ [ Formula 4 ] & \\ 1240 \times ( \frac{1}{{λ}_{p}} - \frac{1}{{λ}_{f}} ) & ( 4 )\end{matrix}$$

TABLE 5

| | | | Composition | Thickness/ |
|---|---|---|---|---|
| Structure | Numeral | Material | ratio | nm |
| Electrode | 102 | Al | | 200 |
| Layer | 105 | LiF | | 1 |
| Layer | 113B | NBPhen | | 10 |
| Layer | 113A | mPCCzPTzn-02 | | 20 |
| Layer | 111 | mPCCzPTzn-02:PCCP: | 0.5:0.5:0.1:f | 40 |
| | | Ir(4tBuppy)3: | | |
| | | 2Ph-mmtBuDPhA2Anth | | |
| Layer | 112 | PCBBi1BP | | 20 |
| Layer | 104 | DBT3P II:MoOx | 1:0.5 | 40 |
| Electrode | 101 | ITSO | | 70 |

### <<Fabrication Method of Light-Emitting Devices 32(21) to 32(23)>>

The light-emitting devices 32(21) to 32(23) described in this example were fabricated by a method including steps described below.

The fabrication of the light-emitting devices 32(21) to 32(23) differs from that of the light-emitting devices 21(11) to 21(23) in that tris[2-[4-(tert-butyl)-2-pyridinyl-κN]phenyl-κC]iridium (abbreviation: Ir(4tBuppy)₃) is used instead of Ir(5tBuppy)₃ and 2Ph-mmtBuDPhA2Anth is used instead of TTPA in the step of forming the layer 111. Different portions will be described in detail below, and the above description is referred to for the other similar portions.

### [Fourth Step]

In a fourth step, the layer 111 was formed over the layer 112. Specifically, materials were co-deposited by a resistance-heating method.

The layer 111 includes mPCCzPTzn-02, PCCP, Ir(4tBuppy)₃, and 2Ph-mmtBuDPhA2Anth at a weight ratio of 0.5:0.5:0.1:f and has a thickness of 40 nm. Table 6 shows values f of the light-emitting devices.

TABLE 6

| | Ir(4tBuppy)3 | 2Ph-mmtBuDPhA2Anth |
|---|---|---|
| | Weight ratio e | Weight ratio f |
| Light-emitting device 32(21) | 0.1 | 0.025 |
| Light-emitting device 32(22) | 0.1 | 0.05 |
| Light-emitting device 32(23) | 0.1 | 0.1 |

### <<Operation Characteristics of Light-Emitting Devices 21(11) to 32(23)>>

The light-emitting devices 21(11) to 32(23) emitted light EL1 when supplied with power (see FIGS. 15A and 15B). Operation characteristics of the light-emitting devices 21(11) to 32(23) were measured (see FIG. 19 to FIG. 46). Note that the measurement was performed at room temperature.

Table 7 shows main initial characteristics at a luminance of approximately 1000 cd/m² and a time LT90 for the luminance to drop to 90% of its initial value at a constant current density of 50 mA/cm², which were obtained under the condition where the light-emitting devices 21(11) to 32(23) each emitted light. Note that the initial characteristics of the other light-emitting devices are also shown in Table 7, and their structures are described later.

TABLE 7

| | | | | | | | External | LT90 |
|---|---|---|---|---|---|---|---|---|
| | | | Current | | | Current | quantum | @50 |
| | Voltage | Current | density | Chromaticity | Chromaticity | efficiency | efficiency | mA/cm2 |
| | (V) | (mA) | (mA/cm2) | x | y | (cd/A) | (%) | (h) |
| Light-emitting device 32(21) | 2.9 | 0.05 | 1.3 | 0.33 | 0.63 | 84.9 | 22.1 | 116.0 |
| Light-emitting device 22(21) | 2.9 | 0.05 | 1.2 | 0.34 | 0.63 | 83.1 | 21.6 | 154.0 |
| Light-emitting device 21(21) | 3.0 | 0.07 | 1.8 | 0.36 | 0.61 | 54.1 | 14.3 | 155.2 |
| Comparative device 12(21) | 3.4 | 0.06 | 1.4 | 0.34 | 0.63 | 64.4 | 16.7 | 67.6 |
| Comparative device 11(21) | 3.5 | 0.10 | 2.5 | 0.36 | 0.61 | 43.5 | 11.4 | 143.0 |
| Light-emitting device 32(22) | 2.9 | 0.05 | 1.4 | 0.35 | 0.62 | 81.9 | 20.9 | 142.0 |
| Light-emitting device 22(22) | 2.8 | 0.04 | 1.0 | 0.35 | 0.62 | 78.6 | 20.1 | 196.0 |
| Light-emitting device 21(22) | 3.0 | 0.08 | 2.0 | 0.38 | 0.60 | 44.2 | 11.5 | 193.2 |
| Comparative device 12(22) | 3.4 | 0.06 | 1.5 | 0.35 | 0.62 | 59.3 | 15.1 | 115.0 |
| Comparative device 11(22) | 3.5 | 0.11 | 2.7 | 0.38 | 0.60 | 35.7 | 9.3 | 178.2 |
| Light-emitting device 32(23) | 2.9 | 0.06 | 1.5 | 0.36 | 0.62 | 77.3 | 19.5 | 142.0 |
| Light-emitting device 22(23) | 2.9 | 0.07 | 1.7 | 0.36 | 0.62 | 68.4 | 17.3 | 218.0 |
| Light-emitting device 21(23) | 3.0 | 0.12 | 2.9 | 0.39 | 0.59 | 35.3 | 9.2 | 191.0 |
| Comparative device 12(23) | 3.5 | 0.09 | 2.3 | 0.36 | 0.62 | 50.9 | 12.9 | 162.0 |
| Comparative device 11(23) | 3.5 | 0.18 | 4.4 | 0.39 | 0.59 | 26.1 | 6.8 | 194.2 |
| Light-emitting device 21(11) | 3.0 | 0.06 | 1.5 | 0.36 | 0.61 | 65.6 | 17.2 | 123.2 |
| Light-emitting device 21(12) | 3.0 | 0.07 | 1.7 | 0.38 | 0.60 | 55.1 | 14.4 | 159.0 |
| Light-emitting device 21(13) | 3.0 | 0.09 | 2.3 | 0.39 | 0.59 | 44.5 | 11.6 | 173.0 |
| Comparative device 11(11) | 3.3 | 0.09 | 2.2 | 0.36 | 0.61 | 53.7 | 14.0 | 107.0 |
| Comparative device 11(12) | 3.3 | 0.09 | 2.2 | 0.38 | 0.60 | 43.3 | 11.2 | 143.0 |
| Comparative device 11(13) | 3.3 | 0.13 | 3.2 | 0.39 | 0.60 | 32.7 | 8.5 | 175.0 |
| Comparative device 30(20) | 2.9 | 0.04 | 1.1 | 0.30 | 0.63 | 76.7 | 21.6 | 52.3 |
| Comparative device 20(20) | 2.9 | 0.04 | 1.0 | 0.30 | 0.63 | 80.9 | 22.5 | 81.3 |
| Comparative device 20(10) | 2.9 | 0.05 | 1.2 | 0.29 | 0.64 | 85.7 | 23.9 | 64.8 |
| Comparative device 10(20) | 3.4 | 0.07 | 1.7 | 0.31 | 0.63 | 68.4 | 18.9 | 56.9 |
| Comparative device 10(10) | 3.3 | 0.06 | 1.6 | 0.30 | 0.63 | 69.6 | 19.4 | 52.9 |

The light-emitting devices 21(11) to 32(23) were found to have favorable characteristics. For example, the light-emitting devices 21(11) to 32(23) each emitted light with an emission spectrum derived from the light-emitting material FM, having a peak wavelength at approximately 540 nm (see FIG. 24, FIG. 31, FIG. 38, and FIG. 45). Light emission derived from the energy donor material ED was not observed. Energy was transferred from the energy donor material ED to the light-emitting material FM.

The voltages at which the light-emitting devices 21(11) to 32(23) exhibited luminance of approximately 1000 cd/m² were lower than those of the comparative devices 11(11) to 12(23) (see Table 7). A variation in each of the driving voltages of the light-emitting devices 21(11) to 32(23) less depended on the concentration of the light-emitting material FM. The light-emitting material FM less affected carrier-transport in each of the light-emitting devices 21(11) to 32(23). The light-emitting device 21(2f) (f is 1 to 3) exhibited higher external quantum efficiency than the comparative device 11(2f) with the same concentration of the light-emitting material FM as that of the light-emitting material FM in the light-emitting device 21(2f).

The light-emitting device 21(1f) exhibited higher external quantum efficiency than the comparative device 11(1f) with the same concentration of the light-emitting material FM as that of the light-emitting material FM in the light-emitting device 21(1f) (see FIG. 44 and FIG. 49). The light-emitting device 21(1f) took a longer time for the luminance to drop to 90% of its initial value than the comparative device 11(1f) with the same concentration of the light-emitting material FM as that of the light-emitting material FM in the light-emitting device 21(1f) under the condition where light was emitted at a constant current density of 50 mA/cm² (see FIG. 50).

The light-emitting device 22(2f) exhibited higher external quantum efficiency than the comparative device 12(2f) with the same concentration of the light-emitting material FM as that of the light-emitting material FM in the light-emitting device 22(2f) (see FIG. 47). The light-emitting device 32(2f) exhibited higher external quantum efficiency than the comparative device 12(2f) with the same concentration of the light-emitting material FM as that of the light-emitting material FM in the light-emitting device 32(2f). The light-emitting device 32(2f) suppressed dependence of external quantum efficiency on the concentration of the light-emitting material FM than the comparative device 12(2f) with the same concentration of the light-emitting material FM as that of the light-emitting material FM in the light-emitting device 32(2f). The light-emitting devices suppressed undesired energy transfer from the energy donor material ED to the light-emitting material FM, or suppressed energy transfer by the Dexter mechanism.

The light-emitting device 32(2f) took a longer time for the luminance to drop to 90% of its initial value than the comparative device 12(2f) with the same concentration of the light-emitting material FM as that of the light-emitting material FM in the light-emitting device 32(2f) under the condition where light was emitted at a constant current density of 50 mA/cm² (see FIG. 48). The light-emitting device 22(22) was capable of increasing the time for the luminance to drop to 90% of its initial value 2.4 times longer than that of the comparative device 20(20).

As a result, a novel light-emitting device that is highly convenient, useful, or reliable can be provided.

### Reference Example 1

The fabricated comparative devices described in this reference example differ from the light-emitting devices 21(11) to 32(23) in that Ir(ppy)₃ is used as the energy donor material.

### <<Structures of Comparative Devices 11(11) to 11(23)>>

Table 8 shows structures of the comparative devices 11(11), 11(12), 11(13), 11(21), 11(22), and 11(23).

TABLE 8

| | | | Composition | Thickness/ |
|---|---|---|---|---|
| Structure | Numeral | Material | ratio | nm |
| Electrode | 102 | Al | | 200 |
| Layer | 105 | LiF | | 1 |
| Layer | 113B | NBPhen | | 10 |
| Layer | 113A | mPCCzPTzn-02 | | 20 |
| Layer | 111 | mPCCzPTzn-02:PCCP: | 0.5:0.5:e:f | 40 |
| | | Ir(ppy)3:TTPA | | |
| Layer | 112 | PCBBi1BP | | 20 |
| Layer | 104 | DBT3P II:MoOx | 1:0.5 | 40 |
| Electrode | 101 | ITSO | | 70 |

### <<Fabrication Method of Comparative Devices 11(11) to 11(23)>>

The comparative devices 11(11) to 11(23) described in this example were fabricated by a method including steps described below.

The fabrication of the comparative devices 11(11) to 12(23) differs from that of the light-emitting devices 21(11) to 21(23) in that tris(2-phenylpyridinato-N,C^{2′})iridium(III) (abbreviation: Ir(ppy)₃) is used instead of Ir(5tBuppy)₃ in the step of forming the layer 111. Different portions will be described in detail below, and the above description is referred to for the other similar portions.

### [Fourth Step]

In a fourth step, the layer 111 was formed over the layer 112. Specifically, materials were co-deposited by a resistance-heating method.

The layer 111 includes mPCCzPTzn-02, PCCP, Ir(ppy)₃, and TTPA at a weight ratio of 0.5:0.5:e:f and has a thickness of 40 nm. Table 9 shows the values e and f of the light-emitting devices.

TABLE 9

| | Ir(ppy)3 | TTPA |
|---|---|---|
| | Weight ratio e | Weight ratio f |
| Comparative device 11(11) | 0.05 | 0.025 |
| Comparative device 11(12) | 0.05 | 0.05 |
| Comparative device 11(13) | 0.05 | 0.1 |
| Comparative device 11(21) | 0.1 | 0.025 |
| Comparative device 11(22) | 0.1 | 0.05 |
| Comparative device 11(23) | 0.1 | 0.1 |

### <<Structure of Comparative Devices 12(21) to 12(23)>>

Table 10 shows structures of the comparative devices 12(21), 12(22), and 12(23).

TABLE 10

| | | | Composition | Thickness/ |
|---|---|---|---|---|
| Structure | Numeral | Material | ratio | nm |
| Electrode | 102 | Al | | 200 |
| Layer | 105 | LiF | | 1 |
| Layer | 113B | NBPhen | | 10 |
| Layer | 113A | mPCCzPTzn-02 | | 20 |
| Layer | 111 | mPCCzPTzn-02: | 0.5:0.5:0.1:f | 40 |
| | | PCCP:Ir(ppy)3: | | |
| | | 2Ph-mmtBuDPhA2Anth | | |
| Layer | 112 | PCBBi1BP | | 20 |
| Layer | 104 | DBT3P II:MoOx | 1:0.5 | 40 |
| Electrode | 101 | ITSO | | 70 |

### <<Fabrication Method of Comparative Devices 12(21) to 12(23)>>

The comparative devices 12(21) to 12(23) described in this example were fabricated by a method including steps described below.

The fabrication of the comparative devices 12(21) to 12(23) differs from that of the light-emitting devices 21(11) to 21(23) in that Ir(ppy)₃ is used instead of Ir(5tBuppy)₃ and 2Ph-mmtBuDPhA2Anth is used instead of TTPA in the step of forming the layer 111. Different portions will be described in detail below, and the above description is referred to for the other similar portions.

### [Fourth Step]

In a fourth step, the layer 111 was formed over the layer 112. Specifically, materials were co-deposited by a resistance-heating method.

The layer 111 includes mPCCzPTzn-02, PCCP, Ir(ppy)₃, and 2Ph-mmtBuDPhA2Anth at a weight ratio of 0.5:0.5:0.1:f and has a thickness of 40 nm. Table 11 shows values f of the comparative devices.

TABLE 11

| | Ir(ppy)3 | 2Ph-mmtBuDPhA2Anth |
|---|---|---|
| | Weight ratio e | Weight ratio f |
| Comparative device 12(21) | 0.1 | 0.025 |
| Comparative device 12(22) | 0.1 | 0.05 |
| Comparative device 12(23) | 0.1 | 0.1 |

### <<Operation Characteristics of Comparative Devices 12(21) to 12(23)>>

The operation characteristics of the comparative devices 12(21) to 12(23) were measured. Note that the measurement was performed at room temperature.

Table 7 shows initial characteristics of the comparative devices 12(21) to 12(23).

### Reference Example 2

The fabricated comparative devices described in this reference example differ from the light-emitting devices 21(11) to 32(23) in that the energy donor material is used as the light-emitting material.

### <<Structures of Comparative Devices 10(10) to 30(20)>>

Table 12 shows structures of the comparative devices 10(10), 20(10), 30(10), 10(20), 20(20), and 30(20).

TABLE 12

| | | | Composition | Thickness/ |
|---|---|---|---|---|
| Structure | Numeral | Material | ratio | nm |
| Electrode | 102 | Al | | 200 |
| Layer | 105 | LiF | | 1 |
| Layer | 113B | NBPhen | | 10 |
| Layer | 113A | mPCCzPTzn-02 | | 20 |
| Layer | 111 | mPCCzPTzn-02: | 0.5:0.5:e | 40 |
| | | PCCP:Ir(L)3 | | |
| Layer | 112 | PCBBi1BP | | 20 |
| Layer | 104 | DBT3P II:MoOx | 1:0.5 | 40 |
| Electrode | 101 | ITSO | | 70 |

### <<Fabrication Method of Comparative Devices 10(10) to 30(20)>>

The comparative devices 10(10) to 30(20) described in this example were fabricated by a method including steps described below.

Note that the fabrication method of the comparative devices 10(10) to 30(20) differs from that of the light-emitting devices 21(11) to 21(23) in that the energy donor material is used as the light-emitting material in the step of forming the layer 111. Different portions will be described in detail below, and the above description is referred to for the other similar portions.

### [Fourth Step]

In a fourth step, the layer 111 was formed over the layer 112. Specifically, materials were co-deposited by a resistance-heating method.

The layer 111 includes mPCCzPTzn-02, PCCP, and Ir(L)₃ at a weight ratio of 0.5:0.5:e and has a thickness of 40 nm. Table 13 shows the substances represented by Ir(L)₃ and the values e of the comparative devices.

TABLE 13

| | Ir(L)3 | Weight ratio e |
|---|---|---|
| Comparative device 30(20) | Ir(4tBuppy)3 | 0.1 |
| Comparative device 20(20) | Ir(5tBuppy)3 | 0.1 |
| Comparative device 10(20) | Ir(ppy)3 | 0.1 |
| Comparative device 30(10) | Ir(4tBuppy)3 | 0.05 |
| Comparative device 20(10) | Ir(5tBuppy)3 | 0.05 |
| Comparative device 10(10) | Ir(ppy)3 | 0.05 |

### <<Operation Characteristics of Comparative Devices 10(10) to 30(20)>>

The operation characteristics of the comparative devices 10(10) to 30(20) were measured (see FIG. 51 to FIG. 57). Note that the measurement was performed at room temperature.

Table 7 shows initial characteristics of the comparative devices 10(10) to 30(20).

### Example 2

This example shows structural formulae and synthesis methods of the organic compounds of one embodiment of the present invention. The structural formulae of the synthesized organic compounds of one embodiment of the present invention are shown below.

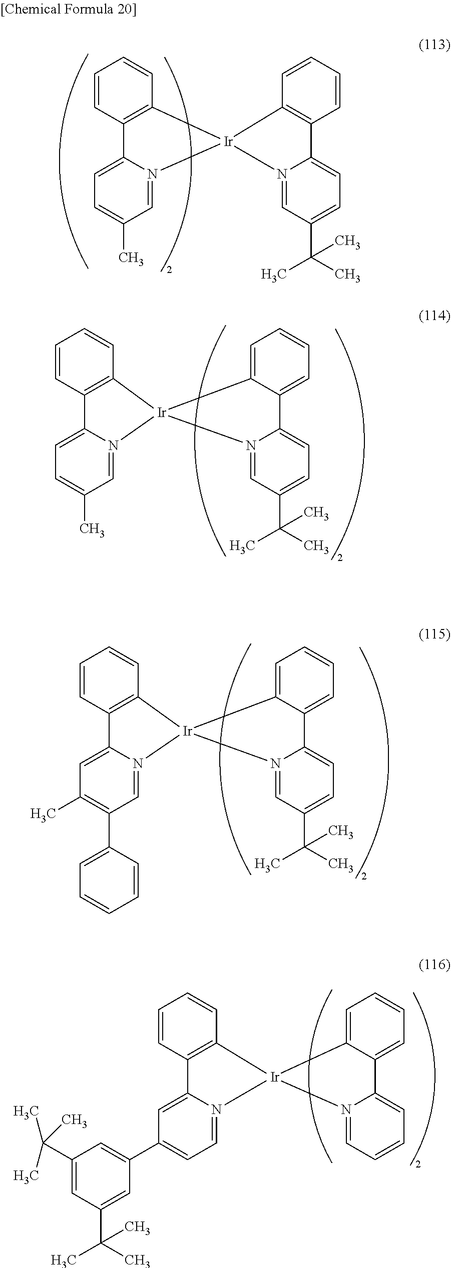

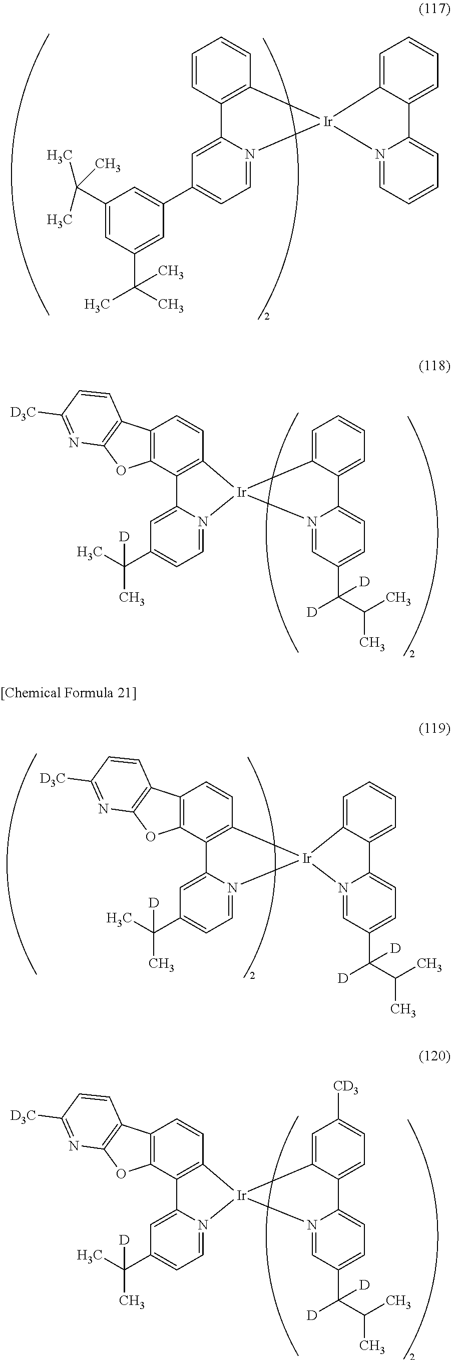

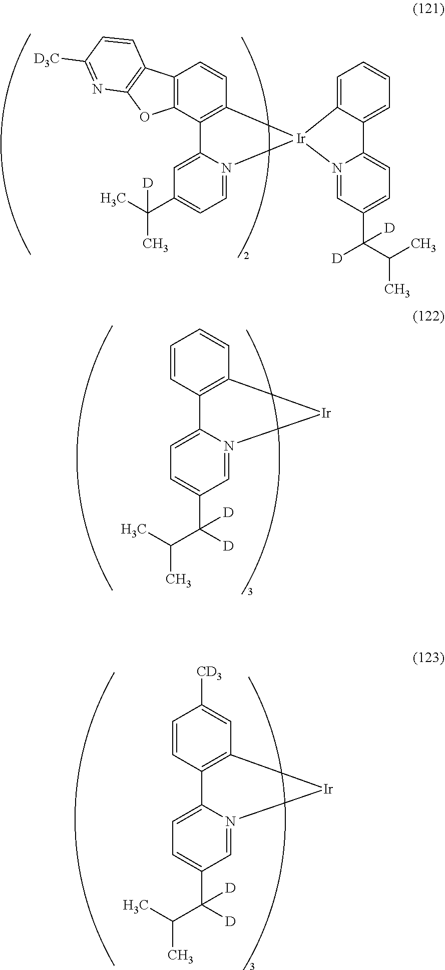

### Synthesis Example 1

This synthesis example shows a method of synthesizing bis[2-(5-methyl-2-pyridinyl-κN)phenyl-κC][2-[5-(tert-butyl)-2-pyridinyl-κN]phenyl-κC]iridium(III) (abbreviation. [Ir(5mppy)₂(5tBuppy)]), which is represented by Structural Formula (113).

### Procedure: Synthesis of bis[2-(5-methyl-2-pyridinyl-κN)phenyl-κC][2-[5-(tert-butyl)-2-pyridinyl-κN]phenyl-κC]iridium(III) (abbreviation: [Ir(5mppy)₂(5tBuppy)])

First, 2.2 g (1.7 mmol) of di-μ-chloro-tetrakis[2-[5-(tert-butyl)-2-pyridinyl-κN]phenyl-κC]diiridium(III) (abbreviation: [Ir(5tBuppy)₂Cl]₂) and 500 mL of dichloromethane were put into a 1000 mL three-neck flask and stirred under a nitrogen stream. Into this mixture was dripped a mixed solvent of 1.3 g (5.2 mmol) of silver trifluoromethanesulfonate and 130 mL of methanol, and the mixture was stirred in a dark environment for 22 hours. After the reaction for a predetermined time, the reaction mixture was filtered through Celite.

The obtained filtrate was concentrated to give 3.0 g of a yellow solid. Then, 3.0 g of the obtained solid, 40 mL of 2-ethoxyethanol, 40 mL of N,N-dimethylformamide (DMF), and 0.59 g (3.5 mmol) of 5-methyl-2-phenylpyridine (abbreviation: H5mppy) were put into a 200 mL three-neck flask. The mixture was heated and refluxed under a nitrogen stream for 24 hours. After the reaction for a predetermined time, the reaction mixture was concentrated to give a solid.

The obtained solid was purified by silica column chromatography. As a developing solvent, a 2:1 hexane-toluene mixed solvent was used. The obtained fraction was concentrated to give 2.0 g of a solid. Then, 2.0 g of the obtained solid was purified by high performance liquid chromatography (mobile phase: chloroform) to give 0.22 g of a yellow solid, which was the object of the synthesis, in a yield of 9%.

Then, 0.21 g of the obtained solid was purified by a train sublimation method. The purification by sublimation was conducted by heating at 245° C. under a pressure of 2.8 Pa with a flow rate of argon gas of 10 mL/min for 27 hours. After the purification by sublimation, 0.14 g of the object of the synthesis was obtained at a collection rate of 67%.

The synthesis scheme of the above procedure is shown in (a-0).

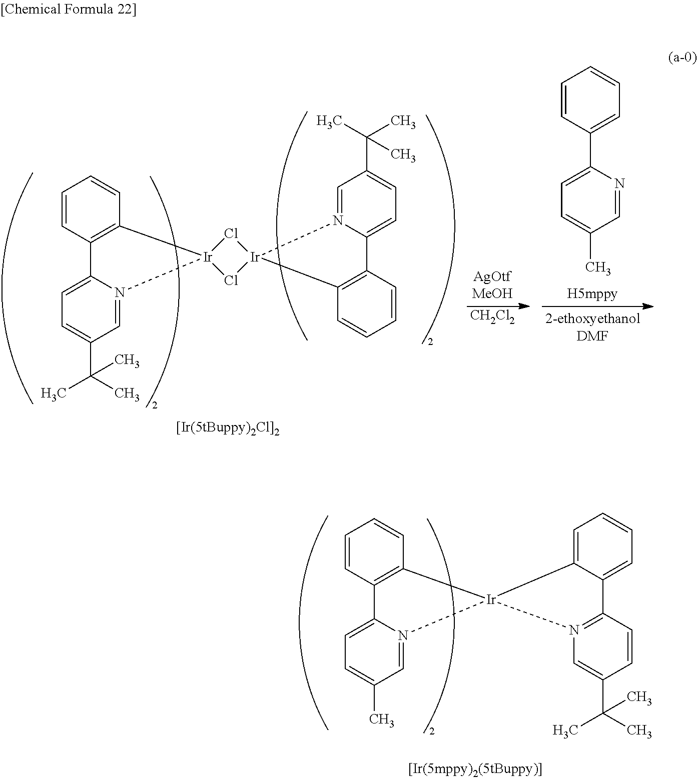

The protons (¹H) of the yellow solid obtained in the above procedure was measured by a nuclear magnetic resonance (NMR) spectroscopy. The obtained values are shown below. These results reveal that [Ir(5mppy)₂(5tBuppy)] represented by Structural Formula (113) above was obtained in this synthesis example.

[¹H-NMR]

¹H-NMR. δ(CDCl₃): 1.09 (s, 9H), 2.08 (s, 3H), 2.14 (s, 3H), 6.83-6.92 (m, 9H), 7.16 (s, 1H), 7.35 (s, 1H), 7.40 (d, 1H), 7.43 (d, 1H), 7.46 (d, 1H), 7.58-7.63 (m, 4H), 7.76 (t, 3H).

### Synthesis Example 2

This synthesis example shows a method of synthesizing [2-(5-methyl-2-pyridinyl-κN)phenyl-κC]bis[2-[5-(tert-butyl)-2-pyridinyl-κN]phenyl-κC]iridium(III) (abbreviation: [Ir(5tBuppy)₂(5mppy)]), which is represented by Structural Formula (114).

Protons (¹H) of the yellow solid obtained by the procedure similar to that described in Synthesis Example 1 were measured by nuclear magnetic resonance (NMR) spectroscopy. The obtained values are shown below. These results reveal that [Ir(5tBuppy)₂(5mppy)] represented by Structural Formula (114) above was obtained in this synthesis example.

[¹H-NMR]

¹H-NMR. δ(CD₂Cl₂):1.10 (s, 9H), 1.12 (s, 9H), 2.12 (s, 3H), 6.80-6.90 (m, 9H), 7.29 (s, 1H), 7.39 (d, 1H), 7.46 (s, 1H), 7.52 (s, 1H), 7.61-7.72 (m, 5H), 7.82-7.85 (m, 3H).

### Synthesis Example 3

This synthesis example shows a method of synthesizing [2-(4-methyl-5-phenyl-2-pyridinyl-κN2)phenyl-κC]bis[2-[5-(tert-butyl)-2-pyridinyl-K]phenyl-κC]iridium(III) (abbreviation: [Ir(5tBuppy)₂(mdppy)]), which is represented by Structural Formula (115).

Protons (¹H) of the yellow solid obtained by the procedure similar to that described in Synthesis Example 1 were measured by nuclear magnetic resonance (NMR) spectroscopy. The obtained values are shown below. These results reveal that [Ir(5tBuppy)₂(mdppy)] represented by Structural Formula (115) above was obtained in this synthesis example.

[¹H-NMR]

¹H-NMR. δ(CDCl₃):1.00 (s, 9H), 1.13 (s, 9H), 2.39 (s, 3H), 6.88-7.08 (s, 12H), 7.30-7.31 (m, 2H), 7.71-7.42 (m, 9H), 7.76-7.79 (m, 2H).

### Synthesis Example 4

This synthesis example shows a method of synthesizing {2-[4-(3,5-di-tert-butylphenyl)-2-pyridinyl-κN]phenyl-κC}bis[2-(2-pyridinyl-κN)phenyl-κC]iridium(III) (abbreviation: [Ir(ppy)₂(4mmtBupppy)]), which is represented by Structural Formula (116).

Protons (¹H) of the red solid obtained by the procedure similar to that described in Synthesis Example 1 were measured by nuclear magnetic resonance (NMR) spectroscopy. The obtained values are shown below. These results reveal that [Ir(ppy)₂(4mmtBupppy)] represented by Structural Formula (116) above was obtained in this synthesis example.

[¹H-NMR]

¹H-NMR. δ(CD₂Cl₂): 1.37 (s, 18H), 6.76-6.82 (m, 6H), 6.88-6.98 (m, 5H), 7.15 (dd, 1H), 7.48 (d, 2H), 7.52-7.54 (m, 1H), 7.58-7.61 (m, 2H), 7.65-7.70 (m, 5H), 7.78 (d, 1H), 7.94 (d, 2H), 8.09 (d, 1H).

### Synthesis Example 5

This synthesis example shows a method of synthesizing bis{2-[4-(3,5-di-tert-butylphenyl)-2-pyridinyl-κN]phenyl-κC}[2-(2-pyridinyl-K]phenyl-κC]iridium(III) (abbreviation: [Ir(4mmtBupppy)₂(ppy)]), which is represented by Structural Formula (117).

Protons (¹H) of the yellow orange solid obtained by the procedure similar to that described in Synthesis Example 1 were measured by nuclear magnetic resonance (NMR) spectroscopy. The obtained values are shown below. These results reveal that [Ir(4mmtBupppy)₂(ppy)] represented by Structural Formula (117) above was obtained in this synthesis example.

[¹H-NMR]

¹H-NMR. δ(CD₂Cl₂): 1.37 (d, 36H), 6.79-6.85 (m, 6H), 6.89-6.94 (m, 3H), 6.98 (t, 1H), 7.15-7.19 (m, 2H), 7.49 (s, 4H), 7.53-7.54 (m, 2H), 7.62 (d, 1H), 7.67-7.73 (m, 4H), 7.80 (d, 2H), 7.96 (d, 1H), 8.10 (s, 2H).

### Synthesis Example 6

This synthesis example shows a method of synthesizing {2-(methyl-d3)-8-[4-(1-methylethyl-1-d)-2-pyridinyl-κN]benzofuro[2,3-b]pyridin-7-yl-κC}bis{2-[5-(2-methylpropyl-1,1-d2)-2-pyridinyl-κN]phenyl-κC}iridium(III) (abbreviation: [Ir(5iBuppy-d2)₂(mbfpypy-iPr-d4]), which is represented by Structural Formula (118).

Protons (¹H) of the yellow solid obtained by the procedure similar to that described in Synthesis Example 1 were measured by nuclear magnetic resonance (NMR) spectroscopy. The obtained values are shown below. These results reveal that [Ir(5iBuppy-d2)₂(mbfpypy-iPr-d₄)] represented by Structural Formula (118) above was obtained in this synthesis example.

[¹H-NMR]

¹H-NMR. δ(CD₂Cl₂): 0.74-0.78 (m, 12H), 1.35 (s, 3H), 1.37 (s, 3H), 1.60-1.68 (m, 2H), 6.73-6.83 (m, 4H), 6.86-6.92 (m, 4H), 7.12-7.14 (m, 1H), 7.22 (s, 1H), 7.27 (s, 1H), 7.34 (d, 1H), 7.47 (d, 1H), 7.48 (d, 1H), 7.51 (d, 1H), 7.64 (t, 2H), 7.81-7.86 (m, 2H), 8.01 (d, 1H), 8.85 (s, 1H).

### Synthesis Example 7

This synthesis example shows a method of synthesizing bis{2-(methyl-d3)-8-[4-(1-methylethyl-1-d)-2-pyridinyl-κN]benzofuro[2,3-b]pyridin-7-yl-KC}{2-[5-(2-methylpropyl-1,1-d₂)-2-pyridinyl-κN]phenyl-κC}iridium(III) (abbreviation: [Ir(mbfpypy-iPr-d4)₂(5iBuppy-d₂]), which is represented by Structural Formula (119).

Protons (¹H) of the yellow solid obtained by the procedure similar to that described in Synthesis Example 1 were measured by nuclear magnetic resonance (NMR) spectroscopy. The obtained values are shown below. These results reveal that [Ir(mbfpypy-iPr-d4)₂(5iBuppy-d₂)] represented by Structural Formula (119) above was obtained in this synthesis example.

[¹H-NMR]

¹H-NMR. δ(Acetone-d₆): 0.64 (d, 3H), 0.70 (d, 3H), 1.34-1.38 (m, 12H), 1.55-1.60 (m, 1H), 6.71 (t, 1H), 6.80-6.85 (m, 2H), 6.99 (t, 2H), 7.11 (d, 2H), 7.20-7.24 (m, 2H), 7.31 (s, 1H), 7.37 (d, 1H), 7.42 (d, 1H), 7.60 (d, 1H), 7.66-7.67 (m, 2H), 7.73 (d, 1H), 8.01 (d, 1H), 8.14-8.18 (m, 2H), 8.89 (d, 2H).

### Synthesis Example 8

This synthesis example shows a method of synthesizing {2-(methyl-d3)-8-[4-(1-methylethyl-1-d)-2-pyridinyl-κN]benzofuro[2,3-b]pyridin-7-yl-κC}bis{2-[5-(2-methylpropyl-1,1-d₂)-2-pyridinyl-κN]-5-(methyl-d3)phenyl-κC}iridium(III) (abbreviation: [Ir(5iButpy-d5)₂(mbfpypy-iPr-d4)]), which is represented by Structural Formula (120).

Protons (¹H) of the yellow solid obtained by the procedure similar to that described in Synthesis Example 1 were measured by nuclear magnetic resonance (NMR) spectroscopy. The obtained values are shown below. These results reveal that [Ir(5iButpy-d₅)₂(mbfpypy-iPr-d₄)] represented by Structural Formula (120) above was obtained in this synthesis example.

[¹H-NMR]

¹H-NMR. δ(CD₂Cl₂): 0.72-0.78 (m, 12H), 1.35 (s, 3H), 1.37 (s, 3H), 1.57-1.67 (m, 2H), 6.62 (s, 1H), 6.67 (s, 1H), 6.71 (t, 2H), 6.90 (d, 1H), 6.95 (d, 1H), 7.12-7.14 (m, 2H), 7.21 (s, 1H), 7.34 (d, 1H), 7.40 (d, 1H), 7.44-7.47 (m, 2H), 7.51-7.55 (m, 2H), 7.74-7.76 (m, 1H), 7.79-7.81 (m, 1H), 8.02 (d, 1H), 8.84 (s, 1H).

### Synthesis Example 9

This synthesis example shows a method of synthesizing {2-(methyl-d3)-8-[4-(1-methylethyl-1-d)-2-pyridinyl-κN]benzofuro[2,3-b]pyridin-7-yl-κC}{2-[5-(2-methylpropyl-1,1-d2)-2-pyridinyl-κN]-5-(methyl-d₃)phenyl-κC}iridium(III) (abbreviation: [Ir(mbfpypy-iPr-d4)₂(5iButpy-d₅)]), which is represented by Structural Formula (121).

Protons (¹H) of the yellow solid obtained by the procedure similar to that described in Synthesis Example 1 were measured by nuclear magnetic resonance (NMR) spectroscopy. The obtained values are shown below. These results reveal that [Ir(mbfpypy-iPr-d4)₂(5iButpy-d₅)] represented by Structural Formula (121) above was obtained in this synthesis example.

[¹H-NMR]

¹H-NMR. δ(Acetone-d₆): 0.63 (d, 3H), 0.70 (d, 3H), 1.33 (s, 3H), 1.36-1.39 (m, 9H), 1.54-1.59 (m, 1H), 6.66-6.69 (m, 2H), 6.99 (d, 1H), 7.04 (d, 1H), 7.09-7.13 (m, 2H), 7.20-7.23 (m, 2H), 7.26 (s, 1H), 7.36 (d, 1H), 7.43 (d, 1H), 7.55-7.57 (m, 1H), 7.62 (d, 2H), 7.65 (d, 1H), 7.94-7.96 (m, 1H), 8.13-8.17 (m, 2H), 8.88 (d, 2H).

### Synthesis Example 10

This synthesis example shows a method of synthesizing tris{2-[5-(2-methylpropyl-1,1-d2)-2-pyridinyl-κN]-phenyl-κC}iridium(III) (abbreviation: [Ir(5iBuppy-d2)₃]), which is represented by Structural Formula (122).

Protons (¹H) of the yellow solid obtained by the procedure similar to that described in Synthesis Example 1 were measured by nuclear magnetic resonance (NMR) spectroscopy. The obtained values are shown below. These results reveal that [Ir(5iBuppy-d₂)₃] represented by Structural Formula (122) above was obtained in this synthesis example.

[¹H-NMR]

¹H-NMR. δ(CD₂Cl₂): 0.79 (d, 9H), 0.83 (d, 9H), 1.65-1.72 (m, 3H), 6.74-6.80 (m, 6H), 6.87 (t, 3H), 7.32 (s, 3H), 7.47 (d, 3H), 7.63 (d, 3H), 7.84 (d, 3H).

### Synthesis Example 11

This synthesis example shows a method of synthesizing {2-[5-(2-methylpropyl-1,1-d₂)-2-pyridinyl-κN]-5-(methyl-d3)phenyl-κC}iridium(III) (abbreviation: [Ir(5iButpy-d₅)₃]), which is represented by Structural Formula (123).

Protons (¹H) of the yellow solid obtained by the procedure similar to that described in Synthesis Example 1 were measured by nuclear magnetic resonance (NMR) spectroscopy. The obtained values are shown below. These results reveal that [Ir(5iButpy-d₅)₃] represented by Structural Formula (123) above was obtained in this synthesis example.

[¹H-NMR]

¹H-NMR. δ(CD₂Cl₂): 0.77 (d, 9H), 0.81 (d, 9H), 1.62-1.70 (m, 3H), 6.62 (s, 3H), 6.69 (d, 3H), 7.23 (s, 3H), 7.43 (d, 3H), 7.52 (d, 3H), 7.78 (d, 3H).

This application is based on Japanese Patent Application Serial No. 2020-167444 filed with Japan Patent Office on Oct. 2, 2020, the entire contents of which are hereby incorporated by reference.

What is claimed is:

1. A light-emitting device comprising:
a first electrode;
a second electrode; and
a light-emitting layer positioned between the first electrode and the second electrode,
wherein the light-emitting layer comprises an organometallic complex that emits phosphorescence at room temperature and a light-emitting material that emits fluorescence,
wherein the organometallic complex comprises a ligand comprising at least one first substituent selected from a branched alkyl group having 3 to 12 carbon atoms, a substituted or unsubstituted cycloalkyl group having 3 to 10 carbon atoms in a ring, and a trialkylsilyl group having 3 to 12 carbon atoms,
wherein an absorption spectrum of the light-emitting material comprises a longest-wavelength edge at a first wavelength λabs (nm),
wherein a phosphorescence spectrum of the organometallic complex comprises a shortest-wavelength edge at a second wavelength λp (nm), and
wherein the first wavelength λabs (nm) is longer than the second wavelength λp (nm).

2. The light-emitting device according to claim 1:
wherein the organometallic complex further comprises:
a transition metal,
wherein the ligand comprises:
a first ring that is a six-membered ring comprising an atom covalently bonded to the transition metal as a constituent atom; and
a second ring that is a five-membered ring or a six-membered ring comprising an atom coordinated to the transition metal as a constituent atom, and
wherein the at least one first substituent is bonded to at least one of the first ring and the second ring.

3. The light-emitting device according to claim 1,
wherein the ligand is a phenylpyridine skeleton, and
wherein the first substituent is bonded to carbon of the phenylpyridine skeleton.

4. The light-emitting device according to claim 1,
wherein the organometallic complex does not comprise an n-alkyl group having two or more carbon atoms.

5. The light-emitting device according to claim 1,
wherein a relationship between the first wavelength λabs (nm) and the second wavelength λp (nm) is represented by formula (1).
$$0.05 < 1240 \times ( \frac{1}{{λ}_{p}} - \frac{1}{{λ}_{abs}} ) \leq 0.30 . \qquad ( 1 )$$

6. The light-emitting device according to claim 1,
wherein a fluorescence spectrum of the light-emitting material comprises a shortest-wavelength edge at a third wavelength λf (nm), and
wherein a relationship between the third wavelength λf (nm) and the second wavelength λp (nm) is represented by formula (2).
$$0 \leq 1240 \times ( \frac{1}{{λ}_{p}} - \frac{1}{{λ}_{f}} ) \leq 0.1 . \qquad ( 2 )$$

7. A light-emitting device comprising:
a first electrode;
a second electrode; and
a light-emitting layer positioned between the first electrode and the second electrode,
wherein the light-emitting layer comprises an organometallic complex that emits phosphorescence at room temperature and a light-emitting material that emits fluorescence,
wherein the organometallic complex comprises a ligand comprising at least one first substituent selected from a branched alkyl group having 3 to 12 carbon atoms, a substituted or unsubstituted cycloalkyl group having 3 to 10 carbon atoms in a ring, and a trialkylsilyl group having 3 to 12 carbon atoms,
wherein the organometallic complex does not comprise an n-alkyl group having two or more carbon atoms,
wherein the light-emitting material comprises at least one second substituent selected from a methyl group, a branched alkyl group having 3 to 12 carbon atoms, a substituted or unsubstituted cycloalkyl group having 3 to 10 carbon atoms in a ring, and a trialkylsilyl group having 3 to 12 carbon atoms, and
wherein a phosphorescent spectrum of the organometallic complex overlaps with an absorption spectrum of the light-emitting material.

8. The light-emitting device according to claim 7,
wherein the organometallic complex further comprises:
a transition metal,
wherein the ligand comprises:
a first ring that is a six-membered ring comprising an atom covalently bonded to the transition metal as a constituent atom; and
a second ring that is a five-membered ring or a six-membered ring comprising an atom coordinated to the transition metal as a constituent atom, and
wherein the at least one first substituent is bonded to at least one of the first ring and the second ring.

9. The light-emitting device according to claim 7,
wherein the light-emitting material further comprises:
a condensed aromatic ring comprising 3 to 10 rings or a condensed heteroaromatic ring comprising 3 to 10 rings; and
the five or more second substituents, and
wherein at least five second substituents of the five or more second substituents are each independently any one of a branched alkyl group having 3 to 12 carbon atoms, a substituted or unsubstituted cycloalkyl group having 3 to 10 carbon atoms in a ring, and a trialkylsilyl group having 3 to 12 carbon atoms.

10. The light-emitting device according to claim 7,
wherein the light-emitting material further comprises:
a condensed aromatic ring comprising 3 to 10 rings or a condensed heteroaromatic ring comprising 3 to 10 rings; and
the three or more second substituents, and
wherein at least three second substituents of the three or more second substituents are not directly bonded to the condensed aromatic ring or the condensed heteroaromatic ring and are each independently any one of a branched alkyl group having 3 to 12 carbon atoms, a substituted or unsubstituted cycloalkyl group having 3 to 10 carbon atoms in a ring, and a trialkylsilyl group having 3 to 12 carbon atoms.

11. The light-emitting device according to claim 7,
wherein the light-emitting material comprises:
a condensed aromatic ring comprising 3 to 10 rings or a condensed heteroaromatic ring comprising 3 to 10 rings; and
a diarylamino group,
wherein the condensed aromatic ring comprising 3 to 10 rings or the condensed heteroaromatic ring comprising 3 to 10 rings is bonded to a nitrogen atom of the diarylamino group, and
wherein the second substituent is bonded to an aryl group of the diarylamino group.

12. The light-emitting device according to claim 7,
wherein the branched alkyl group of the second substituent is a secondary alkyl group or a tertiary alkyl group.

13. The light-emitting device according to claim 7,
wherein the branched alkyl group of the second substituent comprises 3 or 4 carbon atoms.

14. The light-emitting device according to claim 7,
wherein the cycloalkyl alkyl group of the second substituent comprises 3 to 6 carbon atoms.

15. The light-emitting device according to claim 7,
wherein the trialkylsilyl group of the second substituent is a trimethylsilyl group.

16. The light-emitting device according to claim 7,
wherein the second substituent comprises deuterium.

17. The light-emitting device according to claim 1,
wherein the branched alkyl group of the first substituent is a secondary alkyl group or a tertiary alkyl group.

18. The light-emitting device according to claim 1,
wherein the first substituent comprises deuterium.

19. The light-emitting device according to claim 1,
wherein the light-emitting layer further comprises a host material and the light-emitting material is a guest material.

20. An energy donor material represented by General Formula (G0), 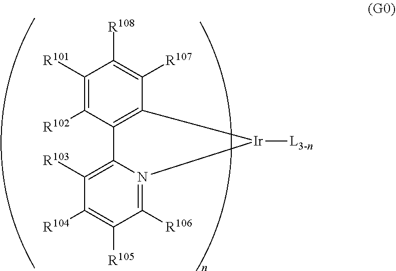
wherein:
L is a ligand;
n is an integer greater than or equal to 1 and less than or equal to 3;
R¹⁰¹ to R¹⁰⁸ are each independently hydrogen or a substituent; and
R¹⁰¹ to R¹⁰⁸ each independently comprise any one or more of a secondary or tertiary alkyl group having 3 to 12 carbon atoms, a cycloalkyl group having 3 to 10 carbon atoms and a trialkylsilyl group having 3 to 12 carbon atoms.

21. A light-emitting apparatus comprising:
the light-emitting device according to claim 1; and
a transistor or a substrate.

22. A display device comprising:
the light-emitting device according to claim 1; and
a transistor or a substrate.

23. A lighting device comprising:
the light-emitting apparatus according to claim 21; and
a housing.

24. An electronic device comprising:
the display device according to claim 22; and
at least one of a sensor, an operation button, a speaker, and a microphone.
